(19) United States
(12) Patent Application Publication
(10) Pub. No.: US 2026/0068384 A1
(43) Pub. Date: Mar. 5, 2026

(54) DISPLAY DEVICE AND ELECTRONIC DEVICE INCLUDING THE SAME

(71) Applicant: Samsung Display Co., LTD., Yongin-si (KR)

(72) Inventors: JUCHAN PARK, Yongin-si (KR); SUNHO KIM, Yongin-si (KR); YOOMIN KO, Yongin-si (KR); PILSUK LEE, Yongin-si (KR); CHUNG SOCK CHOI, Yongin-si (KR)

(73) Assignee: Samsung Display Co., LTD., Yongin-si (KR)

(21) Appl. No.: 19/291,755

(22) Filed: Aug. 6, 2025

(30) Foreign Application Priority Data
Aug. 29, 2024 (KR) 10-2024-0116329

(51) Int. Cl. H10H 29/37; H10H 29/39; H10K 59/122; H10K 59/123; H10K 59/88

(52) U.S. Cl. CPC H10H 29/37; H10H 29/39; H10K 59/122; H10K 59/123; H10K 59/88

(57) ABSTRACT

A display device includes a substrate including a display area and a peripheral area adjacent to the display area, a first electrode arranged in the display area on the substrate, an auxiliary electrode arranged in the display area on the substrate and spaced apart from the first electrode, a pixel defining layer arranged on the substrate and defining an opening which exposes the first electrode, an electrode layer arranged on the first electrode and electrically connected to the auxiliary electrode, a separator arranged on the pixel defining layer and separating the electrode layer into second electrodes spaced apart from each other in the display area, and an organic film pattern arranged between the pixel defining layer and the separator in the display area and in the peripheral area and overlapping at least a portion of the separator in a plan view in the display area and in the peripheral area.

### CROSS-REFERENCE TO RELATED APPLICATION(S)

This application claims priority to and the benefits of Korean Patent Application No. 10-2024-0116329 under 35 USC § 119, filed on Aug. 29, 2024, in the Korean Intellectual Property Office (KIPO), the entire contents of which are incorporated herein by reference.

### BACKGROUND

### 1. Technical Field

The disclosure relates generally to a display device that provides visual information and an electronic device including the same.

### 2. Description of the Related Art

With the development of information technology, the importance of a display device, which is a connection medium between a user and information, has been highlighted. For example, the use of display devices such as liquid crystal display (LCD) device, organic light emitting diode (OLED) display device, plasma display panel (PDP) device, quantum dot display device or the like is increasing.

The display device includes a light emitting element and a pixel driving circuit for driving the light emitting element. The light emitting element may include a pixel electrode, an intermediate layer disposed on the pixel electrode, and an opposing electrode disposed on the intermediate layer. The intermediate layer may be provided in common for a plurality of light emitting elements. In this case, when a current is supplied to one light emitting element, a problem may occur in which the current is also supplied to other adjacent light emitting elements through the intermediate layer commonly provided for the plurality of light emitting elements, resulting in a deterioration of the color purity of the display device. To solve such a problem, the display device may further include a separator that separates (or disconnects) the intermediate layer.

### SUMMARY

Embodiments provide a display device in which a phenomenon of scratching (i.e., being stamped) by a mask used in a process of forming a light emitting element is suppressed.

Embodiments provide an electronic device including the display device.

A display device according to an embodiment of the disclosure may include a substrate including a display area and a peripheral area adjacent to the display area, a first electrode arranged in the display area on the substrate, an auxiliary electrode arranged in the display area on the substrate and spaced apart from the first electrode. a pixel defining layer arranged on the substrate and defining an opening which exposes the first electrode, an electrode layer arranged on the first electrode and electrically connected to the auxiliary electrode, a separator arranged on the pixel defining layer and separating the electrode layer into a plurality of second electrodes spaced apart from each other in the display area, and an organic film pattern arranged between the pixel defining layer and the separator in the display area and in the peripheral area and overlapping at least a portion of the separator in a plan view in the display area and in the peripheral area.

In an embodiment, the separator may include a first portion overlapping the organic film pattern in the plan view and a second portion which is spaced apart from the first portion and does not overlap the organic film pattern in the plan view.

In an embodiment, a level of an upper surface of the first portion of the separator may be higher than a level of an upper surface of the second portion of the separator.

In an embodiment, a first portion of the separator may cover the organic film pattern in the display area. A first side surface and a second side surface opposite to the first side surface of the first portion of the separator may contact the pixel defining layer in the display area.

In an embodiment, the separator may include a first extension portion extending in a first direction, a second extension portion extending in a second direction intersecting the first direction, and an intersection portion where the first extension portion and the second extension portion meet. The organic film pattern may overlap the intersection portion of the separator in the plan view.

In an embodiment, the organic film pattern and the pixel defining layer may include different materials.

In an embodiment, a cross-sectional shape of a portion of the separator may be asymmetrical in the peripheral area.

In an embodiment, the organic film pattern may overlap a first side surface of the portion of the separator in the plan view in the peripheral area.

In an embodiment, the first side surface of the portion of the separator may contact the organic film pattern in the peripheral area. A second side surface opposite to the first side surface of the portion of the separator may contact the pixel defining layer in the peripheral area.

In an embodiment, the display device may further include a connection pattern arranged on the auxiliary electrode and the pixel defining layer and electrically connected to the auxiliary electrode. The separator may overlap the connection pattern in the plan view.

In an embodiment, a portion of the connection pattern may be arranged along profiles of the pixel defining layer and the organic film pattern in the display area.

In an embodiment, the connection pattern may be arranged on the pixel defining layer in the peripheral area. A cross-sectional shape of a portion of the separator may be asymmetrical in the peripheral area. A first side surface of the portion of the separator may contact the organic film pattern in the peripheral area. A second side surface opposite to the first side surface of the portion of the separator may contact the connection pattern in the peripheral area.

In an embodiment, the organic film pattern may overlap an entire area of the separator in the plan view in the peripheral area.

In an embodiment, the display area may include first to third emission areas from which light is emitted, and the separator may surround at least a portion of each of the first to third emission areas in the plan view.

A display device according to an embodiment of the disclosure may include a substrate including a display area and a peripheral area adjacent to the display area, a first electrode arranged in the display area on the substrate, an auxiliary electrode arranged in the peripheral area on the substrate, a pixel defining layer arranged on the substrate and defining an opening which exposes the first electrode, an electrode layer arranged on the first electrode and electrically connected to the auxiliary electrode, a separator arranged on the pixel defining layer and separating the electrode layer into a second electrode arranged in the display area and a dummy electrode which is electrically connected to the auxiliary electrode and is arranged in the peripheral area, a connection pattern arranged between the pixel defining layer and the separator and electrically connecting the second electrode and the dummy electrode, and an organic film pattern arranged between the pixel defining layer and the connection pattern and overlapping at least a portion of the separator in a plan view.

In an embodiment, the separator may include a first portion overlapping the organic film pattern in the plan view and a second portion which is spaced apart from the first portion and does not overlap the organic film pattern in the plan view.

In an embodiment, a level of an upper surface of the first portion of the separator may be higher than a level of an upper surface of the second portion of the separator.

In an embodiment, a first side surface and a second side surface opposite to the first side surface of the separator may contact the connection pattern.

In an embodiment, a portion of the connection pattern may be arranged along profiles of the pixel defining layer and the organic film pattern.

In an embodiment, each of the second electrode and the dummy electrode may contact the connection pattern in an area overlapping the separator in the plan view.

In an embodiment, the display device may further include an auxiliary connection electrode arranged in the peripheral area on the auxiliary electrode and electrically connected to the auxiliary electrode. The auxiliary connection electrode may contact the dummy electrode in the peripheral area.

A display device according to an embodiment of the disclosure may include a substrate including a display area and a peripheral area adjacent to the display area, a pixel driving circuit arranged on the substrate and including a transistor, a first electrode arranged in the display area on the substrate, a connection electrode arranged in the display area on the substrate, spaced apart from the first electrode, and electrically connected to the pixel driving circuit, a pixel defining layer arranged on the substrate and defining an opening which exposes the first electrode, an electrode layer arranged on the first electrode and electrically connected to the connection electrode, a separator arranged on the pixel defining layer and separating the electrode layer into a plurality of second electrodes spaced apart from each other in the display area, and an organic film pattern arranged between the pixel defining layer and the separator in the display area and in the peripheral area and overlapping at least a portion of the separator in a plan view in the display area and in the peripheral area.

In an embodiment, the separator may include a first portion overlapping the organic film pattern in the plan view and a second portion which is spaced apart from the first portion and does not overlap the organic film pattern in the plan view.

In an embodiment, a level of an upper surface of the first portion of the separator may be higher than a level of an upper surface of the second portion of the separator.

In an embodiment, the first portion of the separator may cover the organic film pattern in the display area. A first side surface and a second side surface opposite to the first side surface of the first portion of the separator may contact the pixel defining layer in the display area.

In an embodiment, the separator may include a first extension portion extending in a first direction, a second extension portion extending in a second direction intersecting the first direction, and an intersection portion where the first extension portion and the second extension portion meet. The organic film pattern may overlap the intersection portion of the separator in the plan view.

In an embodiment, the organic film pattern and the pixel defining layer may include different materials.

In an embodiment, a cross-sectional shape of a portion of the separator may be asymmetrical in the peripheral area.

In an embodiment, the organic film pattern may overlap a first side surface of the portion of the separator in the plan view in the peripheral area.

In an embodiment, the first side surface of the portion of the separator may contact the organic film pattern in the peripheral area. A second side surface opposite to the first side surface of the portion of the separator may contact the pixel defining layer in the peripheral area.

In an embodiment, the display device may further include a connection pattern arranged on the connection electrode and the pixel defining layer and electrically connected to the connection electrode. The separator may overlap the connection pattern in the plan view.

In an embodiment, the connection pattern may expose at least a portion of the organic film pattern in the display area.

In an embodiment, the connection pattern may be arranged on the pixel defining layer in the peripheral area. A cross-sectional shape of a portion of the separator may be asymmetrical in the peripheral area. A first side surface of the portion of the separator may contact the organic film pattern in the peripheral area. A second side surface opposite to the first side surface of the portion of the separator may contact the connection pattern in the peripheral area.

In an embodiment, the organic film pattern may overlap an entire area of the separator in the plan view in the peripheral area.

In an embodiment, the display area may include first to third emission areas from which light is emitted, and the separator may entirely surround each of the first to third emission areas in the plan view.

An electronic device according to an embodiment of the disclosure may include a display device including a pixel, and a processor which transmits an image data signal and an input control signal to the display device and is communicationally connected to the display device. The display device may include a substrate including a display area and a peripheral area adjacent to the display area, a first electrode arranged in the display area on the substrate, an auxiliary electrode arranged in the display area on the substrate and spaced apart from the first electrode, a pixel defining layer arranged on the substrate and defining an opening which exposes the first electrode, an electrode layer arranged on the first electrode and electrically connected to the auxiliary electrode, a separator arranged on the pixel defining layer and separating the electrode layer into a plurality of second electrodes spaced apart from each other in the display area, and an organic film pattern arranged between the pixel defining layer and the separator in the display area and in the peripheral area and overlapping at least a portion of the separator in a plan view in the display area and in the peripheral area.

An electronic device according to an embodiment of the disclosure may include a display device including a pixel, and a processor which transmits an image data signal and an input control signal to the display device and is communicationally connected to the display device. The display device may include a substrate including a display area and a peripheral area adjacent to the display area, a pixel driving circuit arranged on the substrate and including a transistor, a first electrode arranged in the display area on the substrate, a connection electrode arranged in the display area on the substrate, spaced apart from the first electrode, and electrically connected to the pixel driving circuit, a pixel defining layer arranged on the substrate and defining an opening which exposes the first electrode, an electrode layer arranged on the first electrode and electrically connected to the connection electrode, a separator arranged on the pixel defining layer and separating the electrode layer into a plurality of second electrodes spaced apart from each other in the display area, and an organic film pattern arranged between the pixel defining layer and the separator in the display area and in the peripheral area and overlapping at least a portion of the separator in a plan view in the display area and in the peripheral area.

A display device according to an embodiment of the disclosure may include a separator arranged on a pixel defining layer in a display area and separating an electrode layer into a plurality of second electrodes spaced apart from each other, and an organic film pattern arranged between the pixel defining layer and the separator and overlapping at least a portion of the separator in a plan view in the display area. The separator may include a first portion overlapping the organic film pattern in a plan view and a second portion spaced apart from the first portion and non-overlapping the organic film pattern in a plan view.

A level of an upper surface of the first portion of the separator may be higher than a level of an upper surface of the second portion of the separator. Accordingly, a mask used in the process of forming a light emitting element (for example, an intermediate layer) may contact the first portion of the separator and may not contact the second portion of the separator. As a result, the phenomenon of being stamped by the mask, which may occur in case that an area of the separator contacting the mask is large, may be suppressed.

The organic film pattern may be arranged between the pixel defining layer and the separator in a peripheral area and may overlap at least a portion of the separator in a plan view in the peripheral area. The cross-sectional shape of a portion of the separator may be asymmetrical in the peripheral area. For example, a first side surface of the portion of the separator that contacts the organic film pattern may not have a reverse tapered slope, and a second side surface opposite to the first side surface that does not contact the organic film pattern may have a reverse tapered slope. As the first side surface of the separator does not have a reverse tapered slope, the electrode layer may be formed to extend without being disconnected in the peripheral area.

### BRIEF DESCRIPTION OF THE DRAWINGS

Illustrative, non-limiting embodiments will be more clearly understood from the following detailed description in conjunction with the accompanying drawings.

FIG. 1A is a plan view illustrating a display device according to an embodiment of the disclosure.

FIG. 1B is a plan view illustrating a display device according to an embodiment of the disclosure.

FIG. 2 is a schematic diagram illustrating a circuit structure of a pixel included in the display device of FIGS. 1A and 1B.

FIG. 3 is a plan view illustrating a portion of an area of the display device of FIGS. 1A and 1B.

FIG. 4 is an enlarged plan view illustrating one unit emission area among the unit emission areas of FIG. 3.

FIG. 5 is a schematic cross-sectional view taken along line II-II′ of FIG. 4.

FIG. 6 is a schematic cross-sectional view taken along line I-I′ of FIG. 1A.

FIG. 7 is a plan view illustrating a display device according to an embodiment of the disclosure.

FIG. 8 is a plan view illustrating a portion of an area of the display device of FIG. 7.

FIG. 9 is an enlarged plan view illustrating one unit emission area among the unit emission areas of FIG. 8.

FIG. 10 is a schematic cross-sectional view taken along line IV-IV′ of FIG. 9.

FIG. 11 is a schematic cross-sectional view taken along line III-III′ of FIG. 7 according to an embodiment.

FIG. 12 is a schematic cross-sectional view taken along line III-III′ of FIG. 7 according to an embodiment.

FIG. 13 is a schematic cross-sectional view illustrating a display device according to an embodiment of the disclosure.

FIG. 14 is a schematic cross-sectional view illustrating the display device of FIG. 13.

FIG. 15 is a schematic cross-sectional view illustrating a display device according to an embodiment of the disclosure.

FIG. 16 is a plan view illustrating a display device according to an embodiment of the disclosure.

FIG. 17A is a schematic diagram illustrating an embodiment of a circuit structure of a pixel included in the display device of FIG. 16.

FIG. 17B is a schematic diagram illustrating another embodiment of a circuit structure of a pixel included in the display device of FIG. 16.

FIG. 18 is a plan view illustrating a portion of an area of the display device of FIG. 16.

FIG. 19 is an enlarged plan view illustrating one unit emission area among the unit emission areas of FIG. 18.

FIG. 20 is a schematic cross-sectional view taken along line VI-VI′ of FIG. 19.

FIG. 21 is a schematic cross-sectional view taken along line V-V′ of FIG. 16.

FIG. 22 is a plan view illustrating a display device according to an embodiment of the disclosure.

FIG. 23 is a plan view illustrating a portion of an area of the display device of FIG. 22.

FIG. 24 is an enlarged plan view illustrating one unit emission area among the unit emission areas of FIG. 23.

FIG. 25 is a schematic cross-sectional view taken along line VIII-VIII′ of FIG. 24.

FIG. 26 is a schematic cross-sectional view taken along line VII-VII′ of FIG. 22 according to an embodiment.

FIG. 27 is a schematic cross-sectional view taken along line VII-VII′ of FIG. 22 according to an embodiment.

FIG. 28 is a schematic block diagram of an electronic device according to an embodiment of the disclosure.

FIG. 29 is a schematic diagram of an electronic device according to various embodiments.

### DETAILED DESCRIPTION OF THE EMBODIMENTS

Various example embodiments will be described more fully hereinafter with reference to the accompanying drawings, in which some example embodiments are shown. The disclosure may, however, be embodied in many different forms and should not be construed as limited to the example embodiments set forth herein. Rather, these example embodiments are provided so that this disclosure will be thorough and complete, and will fully convey the scope of the disclosure to those skilled in the art. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the disclosure. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would be oriented “above” the other elements. The terms “below” or “beneath” can, therefore, encompass both an orientation of above and below.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

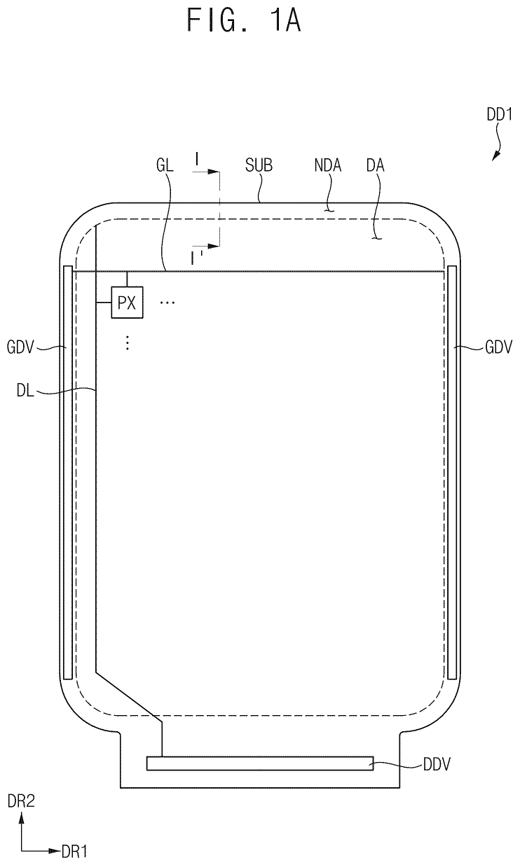

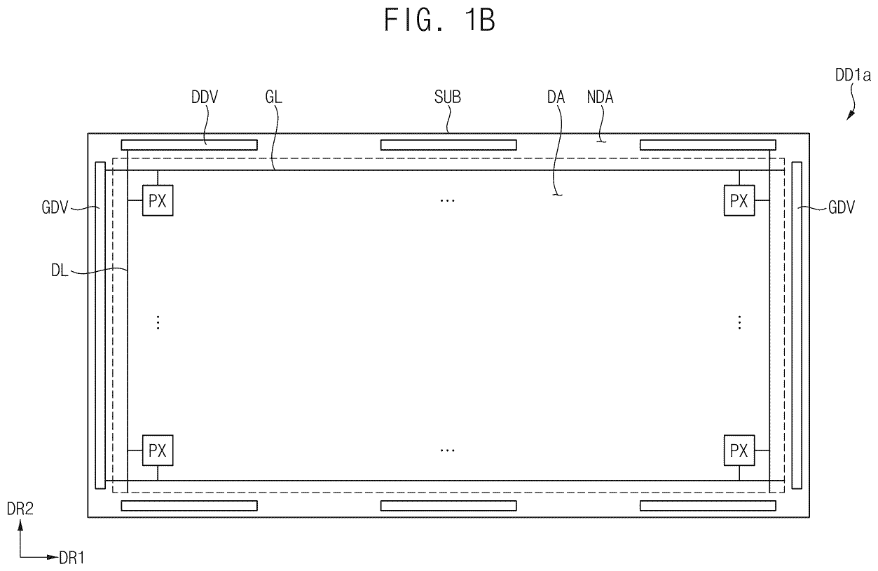

FIG. 1A is a plan view illustrating a display device according to an embodiment of the disclosure. FIG. 1B is a plan view illustrating a display device according to an embodiment of the disclosure.

In this specification, a plane may be defined by a first direction DR1 and a second direction DR2 intersecting the first direction DR1. For example, the first direction DR1 and the second direction DR2 may be perpendicular to each other. A display device and various components or layers thereof may have a thickness extended along a third direction which crosses or intersects the plane, for example, each of the first direction DR1 and the second direction DR2 may be perpendicular to the third direction.

Referring to FIGS. 1A and 1i, a display device DD1 (or DD1a) may be a device activated according to an electrical signal. For example, the display device DD1 may be a small-sized display device used in a small-sized electronic device such as a smart phone, a mobile phone, a smart watch, a game console, a camera, or the like. For example, the display device DD1a may be a medium and large-sized display device used in medium and large-sized electronic devices such as a laptop, a tablet PC, a television, a computer monitor, a vehicle monitor, an external billboard, or the like. FIG. 1A illustrates the display device DD1 as an embodiment of the small-sized display device, and FIG. 1B illustrates the display device DD1a as an embodiment of the medium and large-sized display device.

The display device DD1 (or DD1a) may include a display area DA and a peripheral area NDA. The display area DA may be an area that displays an image by generating light or controlling a transmittance of light provided from an external light source. The peripheral area NDA may be located adjacent to the display area DA. For example, the peripheral area NDA may surround at least a portion of the display area DA. In an embodiment, the peripheral area NDA may be an area that does not display an image. However, the disclosure is not limited thereto, and an image may be displayed in at least a portion of the peripheral area NDA. For example, a light emitting element that emits light may be arranged in at least a portion of the peripheral area NDA.

The display device DD1 (or DD1a) may include a substrate SUB, pixels PX, gate lines GL, data lines DL, a data driver DDV, and a gate driver GDV

The substrate SUB may serve as a base of the display device DD1 (or DD1a). In an embodiment, the substrate SUB may include glass, quartz, silicon, a polymer, or the like. These may be used alone or in combination with each other. The substrate SUB may have a single-layer structure or a multi-layer structure in which multiple layers including different materials are stacked each other.

The pixels PX may be arranged in the display area DA on the substrate SUB. The pixels PX may be electrically connected to the gate lines GL and the data lines DL. For example, the pixels PX may be arranged in a matrix form in the first direction DR1 and the second direction DR2. Each of the pixels PX may include a pixel driving circuit and a light emitting element. The light emitting element may emit light. The light emitting element may be an organic light emitting diode or an inorganic light emitting diode.

Each of the gate lines GL and each of the data lines DL may cross each other. For example, each of the gate lines GL may generally extend in the first direction DR1, and the gate lines GL may be arranged in the second direction DR2. Each of the data lines DL may generally extend in the second direction DR2, and the data lines DL may be arranged in the first direction DR1. However, the disclosure is not limited thereto.

The data driver DDV may be arranged in the peripheral area NDA on the substrate SUB. The data driver DDV may generate a data voltage. The data driver DDV may output the data voltage to the data lines DL. The data voltage may be applied to the pixels PX through the data lines DL.

In an embodiment, the data driver DDV may be mounted on the substrate SUB. However, the disclosure is not limited thereto, and in another embodiment, the data driver DDV may be arranged on a flexible film coupled to the substrate SUB in the form of a chip on film (COF).

In an embodiment, the display device DD1a of FIG. 1B may include multiple data drivers DDV. For example, the data drivers DDV may be arranged on opposite sides of the display area DA in the second direction DR2. For example, the data drivers DDV may be arranged along each of long sides of the display device DD1a. However, the disclosure is not limited thereto.

The gate driver GDV may be arranged in the peripheral area NDA on the substrate SUB. The gate driver GDV may generate a gate signal. The gate driver GDV may output the gate signal to the gate lines GL. The gate signal may be applied to the pixels PX through the gate lines GL. In an embodiment, the gate drivers GDV may be arranged on opposite sides of the display area DA in the first direction DR1. However, the disclosure is not limited thereto.

In an embodiment, an emission driver (not illustrated in FIGS. 1A and 1B) generating an emission control signal may be further arranged in the peripheral area NDA. The emission control signal may be applied to the pixels PX through emission control lines (not illustrated in FIGS. 1A and 1i).

The number or arrangement of the data drivers DDV and the number or arrangement of the gate drivers GDV illustrated in FIGS. 1A and 1B are merely examples, and the disclosure is not limited thereto.

Although FIG. 1A illustrates that the display device DD1 has a substantially rectangular planar shape having short sides each extending in the first direction DR1 and long sides each extending in the second direction DR2, the disclosure is not limited thereto. Although FIG. 1B illustrates that the display device DD1a has a substantially rectangular planar shape having long sides each extending in the first direction DR1 and short sides each extending in the second direction DR2, the disclosure is not limited thereto. For example, the planar shape of each of the display devices DD1 and DD1a may be variously changed according to embodiments.

The descriptions below with the drawings may be substantially equally applied to the display device DD1 of FIG. 1A and the display device DD1a of FIG. 1B. Therefore, for the convenience of description, the display devices DD1 and DD1a are both referred to as the display device DD1 below.

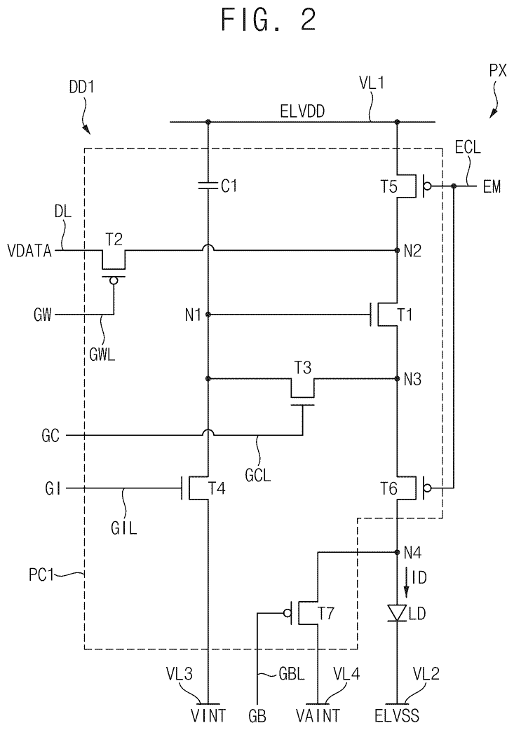

FIG. 2 is a schematic diagram illustrating a circuit structure of a pixel included in the display device of FIGS. 1A and 1B.

Referring to FIG. 2, the pixel PX may include a light emitting element LD and a pixel driving circuit PC1 connected to the light emitting element LD. In an embodiment, the pixel driving circuit PC1 may include first to seventh transistors T1, T2, T3, T4, T5, T6, and T7, and a first capacitor C1. However, the disclosure is not limited thereto, and some of the components of the pixel driving circuit PC1 may be omitted, and other components may be added. In other words, the circuit structure (i.e., the number or arrangement of the transistors, the number or arrangement of the capacitor, etc.) of the pixel PX illustrated in FIG. 2 is only an embodiment, and may be varied according to embodiments.

In FIG. 2, the first transistor T1, the third transistor T3, and the fourth transistor T4 are illustrated as n-type transistors, and the second transistor T2, the fifth transistor T5, the sixth transistor T6, and the seventh transistor T7 are illustrated as p-type transistors. However, the disclosure is not limited thereto, and in another embodiment, some of the first to seventh transistors T1, T2, T3, T4, T5, T6, and T7 may be n-type transistors and others may be p-type transistors. For example, the first transistor T1 may be an n-type transistor, and the second to seventh transistors T2, T3, T4, T5, T6, and T7 may be p-type transistors.

In case that the pixel PX includes the n-type transistor and the p-type transistor, an active pattern of the n-type transistor may include an oxide semiconductor material, and an active pattern of the p-type transistor may include a silicon semiconductor material. However, the disclosure is not limited thereto, and both the active pattern of the n-type transistor and the active pattern of the p-type transistor may include a silicon semiconductor material.

The pixel driving circuit PC1 may be connected to first to fourth gate lines GWL, GCL, GIL, and GBL, the data line DL, first to fourth voltage lines VL1, VL2, VL3, and VL4, and an emission control line ECL. The first gate line GWL may transfer a first gate signal GW. The second gate line GCL may transfer a second gate signal GC. The third gate line GIL may transfer a third gate signal GI. The fourth gate line GBL may transfer a fourth gate signal GB. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level. The third voltage line VL3 may transfer a gate initialization voltage VINT. The fourth voltage line VL4 may transfer an anode initialization voltage VAINT.

The first transistor T1 may include a gate terminal, a first terminal, and a second terminal. The gate terminal of the first transistor T1 may be connected to a first node N1. The first terminal of the first transistor T1 may be connected to a second node N2. The second terminal of the first transistor T1 may be connected to a third node N3. The first transistor T1 may provide a driving current ID to the light emitting element LD.

The second transistor T2 may include a gate terminal, a first terminal, and a second terminal. The gate terminal of the second transistor T2 may receive the first gate signal GW through the first gate line GWL. The first terminal of the second transistor T2 may receive the data voltage VDATA through the data line DL. The second terminal of the second transistor T2 may be connected to the second node N2.

The second transistor T2 may be turned on or off in response to the first gate signal GW. For example, in case that the second transistor T2 is a p-type transistor, the second transistor T2 may be turned off in case that the first gate signal GW has a positive voltage level, and the second transistor T2 may be turned on in case that the first gate signal GW has a negative voltage level. In case that the second transistor T2 is an n-type transistor, the second transistor T2 may be turned off in case that the first gate signal GW has a negative voltage level, and the second transistor T2 may be turned on in case that the first gate signal GW has a positive voltage level. While the second transistor T2 is turned on, the second transistor T2 may provide the data voltage VDATA to the second node N2.

The third transistor T3 may include a gate terminal, a first terminal, and a second terminal. The gate terminal of the third transistor T3 may receive the second gate signal GC through the second gate line GCL. The first terminal of the third transistor T3 may be connected to the first node N1. The second terminal of the third transistor T3 may be connected to the third node N3.

The third transistor T3 may be turned on or off in response to the second gate signal GC. For example, in case that the third transistor T3 is an n-type transistor, the third transistor T3 may be turned off in case that the second gate signal GC has a negative voltage level, and the third transistor T3 may be turned on when the second gate signal GC has a positive voltage level. In case that the third transistor T3 is a p-type transistor, the third transistor T3 may be turned off in case that the second gate signal GC has a positive voltage level, and the third transistor T3 may be turned on in case that the second gate signal GC has a negative voltage level. While the third transistor T3 is turned on, the third transistor T3 may diode-connect the first transistor T1. For example, the third transistor T3 may compensate for a threshold voltage of the first transistor T1.

The fourth transistor T4 may include a gate terminal, a first terminal, and a second terminal. The gate terminal of the fourth transistor T4 may receive the third gate signal GI through the third gate line GIL. The first terminal of the fourth transistor T4 may receive the gate initialization voltage VINT through the third voltage line VL3. The second terminal of the fourth transistor T4 may be connected to the first node N1.

The fourth transistor T4 may be turned on or off in response to the third gate signal GI. For example, in case that the fourth transistor T4 is an n-type transistor, the fourth transistor T4 may be turned off in case that the third gate signal GI has a negative voltage level, and the fourth transistor T4 may be turned on in case that the third gate signal GI has a positive voltage level. In case that the fourth transistor T4 is a p-type transistor, the fourth transistor T4 may be turned off in case that the third gate signal GI has a positive voltage level, and the fourth transistor T4 may be turned on in case that the third gate signal GI has a negative voltage level. While the fourth transistor T4 is turned on, the fourth transistor T4 may provide the gate initialization voltage VINT to the first node N1. Accordingly, the fourth transistor T4 may initialize a voltage of the gate terminal of the first transistor T1.

The fifth transistor T5 may include a gate terminal, a first terminal, and a second terminal. The gate terminal of the fifth transistor T5 may receive the emission control signal EM through the emission control line ECL. The first terminal of the fifth transistor T5 may receive the first power voltage ELVDD through the first voltage line VL1. The second terminal of the fifth transistor T5 may be connected to the second node N2.

The fifth transistor T5 may be turned on or off in response to the emission control signal EM. For example, in case that the fifth transistor T5 is a p-type transistor, the fifth transistor T5 may be turned off in case that the emission control signal EM has a positive voltage level, and the fifth transistor T5 may be turned on in case that the emission control signal EM has a negative voltage level. In case that the fifth transistor T5 is an n-type transistor, the fifth transistor T5 may be turned off in case that the emission control signal EM has a negative voltage level, and the fifth transistor T5 may be turned on in case that the emission control signal EM has a positive voltage level. While the fifth transistor T5 is turned on, the fifth transistor T5 may provide the first power voltage ELVDD to the first terminal of the first transistor T1.

The sixth transistor T6 may include a gate terminal, a first terminal, and a second terminal. The gate terminal of the sixth transistor T6 may receive the emission control signal EM through the emission control line ECL. The first terminal of the sixth transistor T6 may be connected to the third node N3. The second terminal of the sixth transistor T6 may be connected to a fourth node N4.

The sixth transistor T6 may be turned on or off in response to the emission control signal EM. For example, in case that the sixth transistor T6 is a p-type transistor, the sixth transistor T6 may be turned off in case that the emission control signal EM has a positive voltage level, and the sixth transistor T6 may be turned on in case that the emission control signal EM has a negative voltage level. In case that the sixth transistor T6 is an n-type transistor, the sixth transistor T6 may be turned off in case that the emission control signal EM has a negative voltage level, and the sixth transistor T6 may be turned on in case that the emission control signal EM has a positive voltage level. While the sixth transistor T6 is turned on, the sixth transistor T6 may provide the driving current ID to the light emitting element LD.

The seventh transistor T7 may include a gate terminal, a first terminal, and a second terminal. The gate terminal of the seventh transistor T7 may receive the fourth gate signal GB through the fourth gate line GBL. The first terminal of the seventh transistor T7 may receive the anode initialization voltage VAINT through the fourth voltage line VL4. The second terminal of the seventh transistor T7 may be connected to the fourth node N4.

The seventh transistor T7 may be turned on or off in response to the fourth gate signal GB. For example, in case that the seventh transistor T7 is a p-type transistor, the seventh transistor T7 may be turned off in case that the fourth gate signal GB has a positive voltage level, and the seventh transistor T7 may be turned on in case that the fourth gate signal GB has a negative voltage level. In case that the seventh transistor T7 is an n-type transistor, the seventh transistor T7 may be turned off in case that the fourth gate signal GB has a negative voltage level, and the seventh transistor T7 may be turned on in case that the fourth gate signal GB has a positive voltage level. While the seventh transistor T7 is turned on, the seventh transistor T7 may provide the anode initialization voltage VAINT to the fourth node N4. Accordingly, the seventh transistor T7 may initialize a voltage of an anode of the light emitting element LD.

The first capacitor C1 may include a first terminal and a second terminal. The first terminal of the first capacitor C1 may receive the first power voltage ELVDD through the first voltage line VL1. The second terminal of the first capacitor C1 may be connected to the first node N1. The first capacitor C1 may maintain a voltage level of the gate terminal of the first transistor T1 in case that the second transistor T2 is turned off.

Although not illustrated, in another embodiment, the pixel driving circuit PC1 may further include a second capacitor. The second capacitor may include a first terminal to which the first power voltage ELVDD is provided and a second terminal connected to the first terminal of the first transistor T1.

The light emitting element LD may include the anode and a cathode. The anode of the light emitting element LD may be connected to the fourth node N4. The cathode of the light emitting element LD may receive the second power voltage ELVSS through the second voltage line VL2. The light emitting element LD may generate light having a luminance corresponding to the driving current ID.

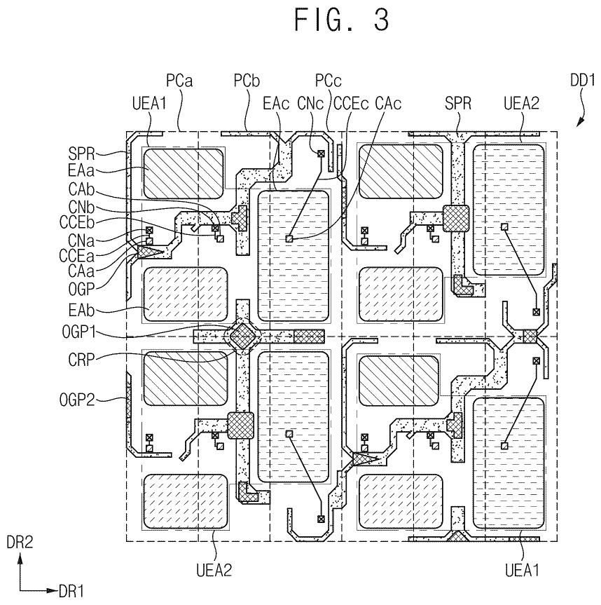

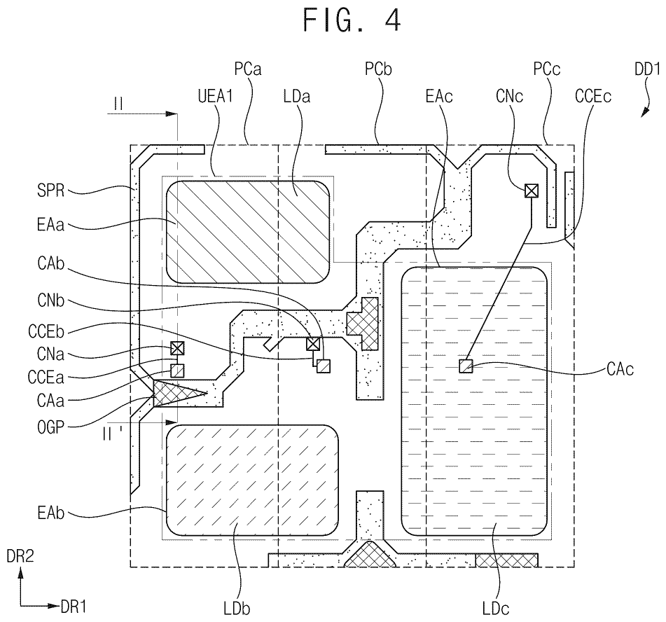

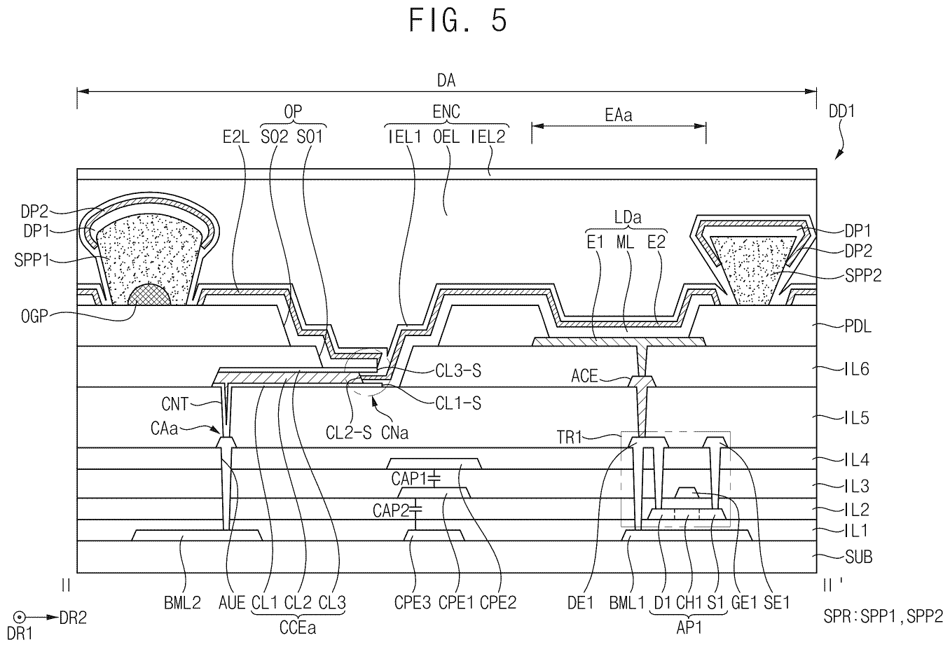

FIG. 3 is a plan view illustrating a portion of an area of the display device of FIGS. 1A and 1B. FIG. 4 is an enlarged plan view illustrating one unit emission area among the unit emission areas of FIG. 3. FIG. 5 is a schematic cross-sectional view taken along line II-II′ of FIG. 4.

Specifically, FIG. 3 schematically illustrates an area in which four unit emission areas UEA1 and UEA2 forming a matrix of two rows and two columns are arranged, and FIG. 4 schematically illustrates an enlarged view of a first unit emission area UEA1 among the unit emission areas UEA1 and UEA2. For convenience of description, some of components illustrated in FIG. 5 are omitted or emphasized in FIGS. 3 and 4.

Referring to FIGS. 3 and 4, the display device DD1 may include first to third pixel driving circuits PCa, PCb, and PCc, first to third light emitting elements LDa, LDb, and LDc, first to third auxiliary connection electrodes CCEa, CCEb, and CCEc, a separator SPR, and multiple organic film patterns OGP.

Each of the first to third pixel driving circuits PCa, PCb, and PCc may correspond to the pixel driving circuit PC1 described above with reference to FIG. 2. For example, each of the first to third pixel driving circuits PCa, PCb, and PCc may include at least one transistor and at least one capacitor. For example, each of the first to third pixel driving circuits PCa, PCb, and PCc may include a first transistor TR1, a first capacitor CAP1, and a second capacitor CAP2 illustrated in FIG. 5.

The first transistor TR1 of FIG. 5 may be a transistor connected to the light emitting element through an anode connection electrode (ACE, refer to FIG. 5). For example, in case that each of the first to third pixel driving circuits PCa, PCb, and PCc is the pixel driving circuit PC1 of FIG. 2, the first transistor TR1 may be the sixth transistor T6 of FIG. 2. The first capacitor CAP1 of FIG. 5 may correspond to the first capacitor C1 of FIG. 2, and the second capacitor CAP2 of FIG. 5 may be omitted. However, the disclosure is not limited thereto, and the second capacitor CAP2 of FIG. 5 may correspond to the first capacitor C1 of FIG. 2, and the first capacitor CAP1 of FIG. 5 may be omitted. The first transistor TR1, the first capacitor CAP1, and the second capacitor CAP2 will be described in more detail with reference to FIG. 5.

FIGS. 3 and 4 schematically illustrate that the first to third pixel driving circuits PCa, PCb, and PCc each has a rectangular shape and are sequentially arranged along the first direction DR1 in a plan view. However, the disclosure is not limited thereto, and the shape and arrangement of the first to third pixel driving circuits PCa, PCb, and PCc may be variously changed according to embodiments.

Each of the first to third light emitting elements LDa, LDb, and LDc may correspond to the light emitting element LD described above with reference to FIG. 2. For example, each of the first to third light emitting elements LDa, LDb, and LDc may include a first electrode (E1, refer to FIG. 5), an intermediate layer (ML, refer to FIG. 5) arranged on the first electrode, and an electrode layer (E2L, refer to FIG. 5) arranged on the intermediate layer. In an embodiment, the first electrode may function as the anode of FIG. 2 and the electrode layer may function as the cathode of FIG. 2.

In an embodiment, the electrode layer may be separated (or disconnected) into multiple second electrodes by the separator SPR. For example, the electrode layer may be separated (or disconnected) into a second electrode (E2, refer to FIG. 5) of the first light emitting element LDa, a second electrode of the second light emitting element LDb, and a second electrode of the third light emitting element LDc.

The first to third light emitting elements LDa, LDb, and LDc may be connected to the first to third pixel driving circuits PCa, PCb, and PCc, respectively. For example, the first light emitting element LDa may be connected to the first pixel driving circuit PCa, the second light emitting element LDb may be connected to the second pixel driving circuit PCb, and the third light emitting element LDc may be connected to the third pixel driving circuit PCc. Accordingly, the first pixel driving circuit PCa and the first light emitting element LDa may form one pixel, the second pixel driving circuit PCb and the second light emitting element LDb may form one pixel, and the third pixel driving circuit PCc and the third light emitting element LDc may form one pixel.

The first to third light emitting elements LDa, LDb, and LDc may emit light of different colors. For example, the first light emitting element LDa may emit red light, the second light emitting element LDb may emit green light, and the third light emitting element LDc may emit blue light. However, the disclosure is not limited thereto.

In an embodiment, as illustrated in FIG. 3, the display device DD1 may include the first unit emission area UEA1 and the second unit emission area UEA2. The first unit emission area UEA1 and the second unit emission area UEA2 may be defined in a matrix form in the first direction DR1 and the second direction DR2. Although FIG. 3 illustrates only four unit emission areas, multiple unit emission areas may be defined in a matrix form along the first direction DR1 and the second direction DR2 in the entire display area (DA, see FIGS. 1A and 1B).

The first to third light emitting elements LDa, LDb, and LDc adjacent to each other may be arranged in each of the first unit emission area UEA1 and the second unit emission area UEA2. For example, first to third emission areas EAa, EAb, and EAc adjacent to each other may be defined in each of the first unit emission area UEA1 and the second unit emission area UEA2, and the first to third light emitting elements LDa, LDb, and LDc may be arranged in the first to third emission areas EAa, EAb, and EAc, respectively.

The first to third emission areas EAa, EAb, and EAc may be defined by pixel openings of a pixel defining layer (PDL, refer to FIG. 5) described hereinafter. For example, each of the first to third emission areas EAa, EAb, and EAc may be an area where light is emitted from the light emitting element. For example, the first light emitting element LDa may be arranged in the first emission area EAa, and the first emission area EAa may be an area where light is emitted from the first light emitting element LDa. The second light emitting element LDb may be arranged in the second emission area EAb, and the second emission area EAb may be an area where light is emitted from the second light emitting element LDb. The third light emitting element LDc may be arranged in the third emission area EAc, and the third emission area EAc may be an area where light is emitted from the third light emitting element LDc.

In an embodiment, the first unit emission area UEA1 and the second unit emission area UEA2 may be distinguished based on the arrangement relationship between the first to third light emitting elements LDa, LDb, and LDc (or the arrangement relationship between the first to third emission areas EAa, EAb, and EAc). For example, the arrangement relationship between the first to third light emitting elements LDa, LDb, and LDc (or the first to third emission areas EAa, EAb, and EAc) may be the same for each first unit emission area UEA1, and the arrangement relationship between the first to third light emitting elements LDa, LDb, and LDc (or the first to third emission areas EAa, EAb, and EAc) may be the same for each second unit emission area UEA2.

In an embodiment, as illustrated in FIG. 3, the first unit emission areas UEA1 and the second unit emission areas UEA2 may be alternately arranged along the first direction DR1 (i.e., a row direction) and the second direction DR2 (i.e., a column direction). However, the disclosure is not limited thereto, and the number of different unit emission areas included in the display device DD1 or the arrangement relationship between the unit emission areas may be variously changed according to embodiments.

FIGS. 3 and 4 schematically illustrate that the first to third emission areas EAa, EAb, and EAc are arranged in an S-stripe structure. However, the disclosure is not limited thereto, and the arrangement of the first to third emission areas EAa, EAb, and EAc may be variously changed according to embodiments.

The separator SPR may be arranged between the first to third emission areas EAa, EAb, and EAc in a plan view. For example, the separator SPR may be arranged between the first emission area EAa and the second emission area EAb, between the second emission area EAb and the third emission area EAc, and between the first emission area EAa and the third emission area EAc in a plan view. The separator SPR may surround at least a portion of each of the first to third emission areas EAa, EAb, and EAc in a plan view. In an embodiment, as illustrated in FIGS. 3 and 4, in a plan view, the separator SPR may surround a portion of each of the first to third emission areas EAa, EAb, and EAc and may not surround another portion of each of the first to third emission areas EAa, EAb, and EAc. However, the disclosure is not limited thereto, and in another embodiment, the separator SPR may entirely surround each of the first to third emission areas EAa, EAb, and EAc in a plan view.

The separator SPR may separate (or disconnect) the electrode layer (E2L, refer to FIG. 5) into the second electrode of the first light emitting element LDa, the second electrode of the second light emitting element LDb, and the second electrode of the third light emitting element LDc in the display area. Accordingly, the second electrode of the first light emitting element LDa, the second electrode of the second light emitting element LDb, and the second electrode of the third light emitting element LDc may be spaced apart from each other.

In an embodiment, the separator SPR may include an organic insulating material. For example, the separator SPR may include a photosensitive resin (e.g., a photoresist), but the disclosure is not limited thereto.

The organic film patterns OGP may overlap at least a portion of the separator SPR in a plan view in the display area. In a plan view, the organic film patterns OGP may be arranged in a portion of an area where the separator SPR is arranged. In other words, a portion of the separator SPR (e.g., a first portion SPP1 of the separator SPR of FIG. 5) may overlap the organic film pattern OGP in a plan view, and other portions of the separator SPR (e.g., a second portion SPP2 of the separator SPR of FIG. 5) may not overlap the organic film pattern OGP in a plan view. The organic film pattern OGP may include an organic material.

The organic film patterns OGP may have various planar shapes. For example, as illustrated in FIG. 3, each of the organic film patterns OGP may have at least one of a triangular planar shape, a rectangular planar shape, a square planar shape, a cross planar shape, a rhombus planar shape, and the like in a plan view. However, the disclosure is not limited thereto, and the organic film patterns OGP may have a same planar shape as each other.

In an embodiment, the organic film patterns OGP may have different sizes (or areas) from each other. However, the disclosure is not limited thereto, and the organic film patterns OGP may have a same size as each other.

In an embodiment, the organic film patterns OGP may overlap an intersection portion CRP of the separator SPR in a plan view. The intersection portion CRP of the separator SPR may be a portion where a first extension portion of the separator SPR extending in the first direction DR1 and a second extension portion of the separator SPR extending in the second direction DR2 meet. For example, as illustrated in FIG. 3, a first organic film pattern OGP1 among the organic film patterns OGP may overlap the intersection portion CRP of the separator SPR in a plan view. Compared to the first extension portion of the separator SPR and the second extension portion of the separator SPR, the intersection portion CRP of the separator SPR may provide a relatively large space to cover the organic film pattern OGP. However, the disclosure is not limited thereto, and the organic film patterns OGP may overlap the first extension portion of the separator SPR and the second extension portion of the separator SPR in a plan view. For example, as illustrated in FIG. 3, a second organic film pattern OGP2 among the organic film patterns OGP may overlap the first extension portion of the separator SPR or the second extension portion of the separator SPR in a plan view.

In an embodiment, the organic film pattern OGP may be arranged inside an area where the separator SPR is arranged in a plan view, and the separator SPR may cover the organic film pattern OGP in a cross-sectional view and may contact the pixel defining layer (PDL, refer to FIG. 5). However, the disclosure is not limited thereto. For example, as illustrated in FIG. 3, some of the organic film patterns OGP may be arranged inside the area where the separator SPR is arranged in a plan view, and others of the organic film patterns OGP may overlap both the area where the separator SPR is arranged and an area where the separator SPR is not arranged in a plan view.

Hereinafter, a connection relationship between the first to third light emitting elements LDa, LDb, and LDc and the first to third auxiliary connection electrodes CCEa, CCEb, and CCEc will be described in more detail, focusing on the first unit emission area UEA1 of FIG. 4. The following description of the connection relationship between the first to third light emitting elements LDa, LDb, and LDc and the first to third auxiliary connection electrodes CCEa, CCEb, and CCEc may be substantially equally applied to all unit emission areas.

As described above, the display device DD1 may include the first to third auxiliary connection electrodes CCEa, CCEb, and CCEc. The first auxiliary connection electrode CCEa may electrically connect the first light emitting element LDa and an auxiliary electrode (AUE, refer to FIG. 5). The second auxiliary connection electrode CCEb may electrically connect the second light emitting element LDb and the auxiliary electrode. The third auxiliary connection electrode CCEc may electrically connect the third light emitting element LDc and the auxiliary electrode. The second power voltage (ELVSS, refer to FIG. 2) may be applied to the auxiliary electrode.

The first to third auxiliary connection electrodes CCEa, CCEb, and CCEc may include a conductive material such as a metal, an alloy, a conductive metal oxide, a conductive metal nitride, a transparent conductive oxide, or the like. Examples of the conductive material that may be used as the first to third auxiliary connection electrodes CCEa, CCEb, and CCEc may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing Al, an alloy containing Ag, an alloy containing Cu, an alloy containing Mo, aluminum nitride (AlₓN_{y}), tungsten nitride (WₓN_{y}), titanium nitride (TiₓN_{y}), chromium nitride (CrₓN_{y}), tantalum nitride (TaₓN_{y}), tin oxide (SnOₓ), gallium oxide (GaOₓ), indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InOₓ), aluminum zinc oxide (AZO), or the like. These may be used alone or in combination with each other. In an embodiment, the first to third auxiliary connection electrodes CCEa, CCEb, and CCEc may have a multi-layer structure in which multiple conductive layers are stacked each other. A detailed description thereof will be described below with reference to FIG. 5.

The first auxiliary connection electrode CCEa may include a first auxiliary electrode connection portion CAa and a first light emitting connection portion CNa.

The first auxiliary electrode connection portion CAa may be a portion, which is connected to the auxiliary electrode (AUE, refer to FIG. 5), of the first auxiliary connection electrode CCEa. For example, a position of the first auxiliary electrode connection portion CAa may correspond to a position of a contact hole (CNT, refer to FIG. 5) that exposes the auxiliary electrode and penetrates a fifth insulating layer (IL5, refer to FIG. 5).

The first light emitting connection portion CNa may be a portion, which is connected to the second electrode (E2, refer to FIG. 5) of the first light emitting element LDa, of the first auxiliary connection electrode CCEa. For example, the first light emitting connection portion CNa may be a portion, which is exposed by a sixth insulating layer (IL6, refer to FIG. 5) and the pixel defining layer (PDL, refer to FIG. 5) for being connected to the second electrode of the first light emitting element LDa, of the first auxiliary connection electrode CCEa. Accordingly, a position of the first light emitting connection portion CNa may correspond to a position of a sub-opening (OP, refer to FIG. 5) that exposes the first auxiliary connection electrode CCEa and penetrates the pixel defining layer and the sixth insulating layer.

The second electrode of the first light emitting element LDa may be connected to the first auxiliary connection electrode CCEa. For example, the second electrode of the first light emitting element LDa may contact the first auxiliary connection electrode CCEa. As a result, the second electrode of the first light emitting element LDa may be electrically connected to the auxiliary electrode (AUE, refer to FIG. 5) through the first auxiliary connection electrode CCEa.

In an embodiment, the first light emitting connection portion CNa may be arranged at a position that does not overlap the first emission area EAa in a plan view. For example, the second electrode of the first light emitting element LDa may contact the first auxiliary connection electrode CCEa at a position that does not overlap the first emission area EAa in a plan view. For example, in a plan view, the first light emitting connection portion CNa may be arranged between the first emission area EAa and the separator SPR. Accordingly, the second electrode of the first light emitting element LDa and the auxiliary electrode may be electrically connected to each other through the first auxiliary connection electrode CCEa without reducing the size of the first emission area EAa.

The second auxiliary connection electrode CCEb may include a second auxiliary electrode connection portion CAb and a second light emitting connection portion CNb.

The second auxiliary electrode connection portion CAb may be a portion, which is connected to the auxiliary electrode, of the second auxiliary connection electrode CCEb. For example, a position of the second auxiliary electrode connection portion CAb may correspond to a position of a contact hole that exposes the auxiliary electrode and penetrates the fifth insulating layer.

The second light emitting connection portion CNb may be a portion, which is connected to the second electrode of the second light emitting element LDb, of the second auxiliary connection electrode CCEb. For example, the second light emitting connection portion CNb may be a portion, which is exposed by the sixth insulating layer and the pixel defining layer for being connected to the second electrode of the second light emitting element LDb, of the second auxiliary connection electrode CCEb. Accordingly, a position of the second light emitting connection portion CNb may correspond to a position of a sub-opening that exposes the second auxiliary connection electrode CCEb and penetrates the pixel defining layer and the sixth insulating layer.

In an embodiment, the second auxiliary connection electrode CCEb may be spaced apart from the first auxiliary connection electrode CCEa in a plan view. In other words, the first auxiliary connection electrode CCEa and the second auxiliary connection electrode CCEb may be electrodes that are distinct from each other.

The second electrode of the second light emitting element LDb may be connected to the second auxiliary connection electrode CCEb. For example, the second electrode of the second light emitting element LDb may contact the second auxiliary connection electrode CCEb. As a result, the second electrode of the second light emitting element LDb may be electrically connected to the auxiliary electrode through the second auxiliary connection electrode CCEb.

In an embodiment, the second light emitting connection portion CNb may be arranged at a position that does not overlap the second emission area EAb in a plan view. For example, the second electrode of the second light emitting element LDb may contact the second auxiliary connection electrode CCEb at a position that does not overlap the second emission area EAb in a plan view. For example, in a plan view, the second light emitting connection portion CNb may be arranged between the second emission area EAb and the separator SPR. Accordingly, the second electrode of the second light emitting element LDb and the auxiliary electrode may be electrically connected to each other through the second auxiliary connection electrode CCEb without reducing the size of the second emission area EAb.

The third auxiliary connection electrode CCEc may include a third auxiliary electrode connection portion CAc and a third light emitting connection portion CNc.

The third auxiliary electrode connection portion CAc may be a portion, which is connected to the auxiliary electrode, of the third auxiliary connection electrode CCEc. For example, a position of the third auxiliary electrode connection portion CAc may correspond to a position of a contact hole that exposes the auxiliary electrode and penetrates the fifth insulating layer.

The third light emitting connection portion CNc may be a portion, which is connected to the second electrode of the third light emitting element LDc, of the third auxiliary connection electrode CCEc. For example, the third light emitting connection portion CNc may be a portion, which is exposed by the sixth insulating layer and the pixel defining layer for being connected to the second electrode of the third light emitting element LDc, of the third auxiliary connection electrode CCEc. Accordingly, a position of the third light emitting connection portion CNc may correspond to a position of a sub-opening that exposes the third auxiliary connection electrode CCEc and penetrates the pixel defining layer and the sixth insulating layer.

In an embodiment, the third auxiliary connection electrode CCEc may be spaced apart from the first auxiliary connection electrode CCEa and the second auxiliary connection electrode CCEb in a plan view. In other words, the first auxiliary connection electrode CCEa, the second auxiliary connection electrode CCEb, and the third auxiliary connection electrode CCEc may be electrodes that are distinct from each other.

The second electrode of the third light emitting element LDc may be connected to the third auxiliary connection electrode CCEc. For example, the second electrode of the third light emitting element LDc may contact the third auxiliary connection electrode CCEc. As a result, the second electrode of the third light emitting element LDc may be electrically connected to the auxiliary electrode through the third auxiliary connection electrode CCEc.

In an embodiment, the third light emitting connection portion CNc may be arranged at a position that does not overlap the third emission area EAc in a plan view. For example, the second electrode of the third light emitting element LDc may contact the third auxiliary connection electrode CCEc at a position that does not overlap the third emission area EAc in a plan view. For example, in a plan view, the third light emitting connection portion CNc may be arranged between the third emission area EAc and the separator SPR. Accordingly, the second electrode of the third light emitting element LDc and the auxiliary electrode may be electrically connected to each other through the third auxiliary connection electrode CCEc without reducing the size of the third emission area EAc.

As illustrated in FIG. 3, the shape or arrangement of each of the first to third auxiliary connection electrodes CCEa, CCEb, and CCEc and the arrangement relationship between the first to third auxiliary connection electrodes CCEa, CCEb, and CCEc may be the same for each first unit emission area UEA1. The shape or arrangement of each of the first to third auxiliary connection electrodes CCEa, CCEb, and CCEc and the arrangement relationship between the first to third auxiliary connection electrodes CCEa, CCEb, and CCEc may be the same for each second unit emission area UEA2.

Hereinafter, the cross-sectional structure of the display device DD1 will be described in more detail with reference to FIG. 5, focusing on the first emission area EAa. The following description of the cross-sectional structure of the display device DD1 may be substantially equally applied to all emission areas.

Referring further to FIG. 5, the display device DD1 may include a substrate SUB, a first bottom conductive layer BML1, a second bottom conductive layer BML2, a first transistor TR1, a first capacitor CAP1, a second capacitor CAP2, an auxiliary electrode AUE, an anode connection electrode ACE, a first auxiliary connection electrode CCEa, first to six insulating layers IL1, IL2, IL3, IL4, IL5, and IL6, a pixel defining layer PDL, a first light emitting element LDa, an organic film pattern OGP, a separator SPR, a first dummy layer DP1, a second dummy layer DP2, and an encapsulation layer ENC. The separator SPR may include a first portion SPP1 and a second portion SPP2 spaced apart from the first portion SPP1.

The first transistor TR1 may include a first active pattern AP1, a first gate electrode GE1, a first contact electrode SE1, and a second contact electrode DE1. The first capacitor CAP1 may include a first capacitor electrode CPE1 and a second capacitor electrode CPE2. The second capacitor CAP2 may include the first capacitor electrode CPE1 and a third capacitor electrode CPE3. The first light emitting element LDa may include a first electrode E1, an intermediate layer ML, and a second electrode E2.

As described above, the first transistor TR1, the first capacitor CAP1, and the second capacitor CAP2 may be components included in the first pixel driving circuit PCa.

The substrate SUB may serve as abase of the display device DD1. In an embodiment, the substrate SUB may include glass, quartz, silicon, a polymer, or the like. These may be used alone or in combination with each other. The substrate SUB may have a single-layer structure or a multi-layer structure in which multiple layers including different materials are stacked each other.

The first bottom conductive layer BML1, the second bottom conductive layer BML2, and the third capacitor electrode CPE3 may be arranged on the substrate SUB. In an embodiment, the first bottom conductive layer BML1 and the second bottom conductive layer BML2 may be subjected to different electrical signals. The first bottom conductive layer BML1, the second bottom conductive layer BML2, and the third capacitor electrode CPE3 may include a conductive material such as a metal, an alloy, a conductive metal oxide, a conductive metal nitride, a transparent conductive oxide, or the like.

The first insulating layer IL1 may cover the first bottom conductive layer BML1, the second bottom conductive layer BML2, and the third capacitor electrode CPE3 and may be arranged on the substrate SUB. The first insulating layer IL1 may prevent or reduce metal atoms or impurities from diffusing from the substrate SUB to the first active pattern AP1. The first insulating layer IL1 may include an insulating material. Examples of the insulating material that may be used as the first insulating layer IL1 may include silicon oxide (SiOₓ), silicon nitride (SiNₓ), silicon oxynitride (SiOₓN_{y}), or the like. These may be used alone or in combination with each other.

The first active pattern AP1 may be arranged on the first insulating layer IL1. In an embodiment, the first active pattern AP1 may overlap the first bottom conductive layer BML1 in a plan view. The first active pattern AP1 may include an oxide semiconductor material, a silicon semiconductor material, and/or an organic semiconductor material. The first active pattern AP1 may include a first contact area S1, a second contact area D1, and a first channel area CH1 between the first contact area S1 and the second contact area D1. The first contact area S1 and the second contact area D1 may have higher conductivity than the first channel area CH1.

In an embodiment, the first active pattern AP1 may include an oxide semiconductor material. Examples of the oxide semiconductor material that may be used as the first active pattern AP1 may include indium gallium zinc oxide (IGZO), zinc tin oxide (ZTO), indium tin zinc oxide (ITZO), or the like. These may be used alone or in combination with each other. However, the disclosure is not limited thereto, and in another embodiment, the first active pattern AP1 may include a silicon semiconductor material.

The second insulating layer IL2 may cover the first active pattern AP1 and may be arranged on the first insulating layer IL1. The second insulating layer IL2 may include an insulating material. For example, the second insulating layer IL2 may include silicon oxide (SiOₓ), silicon nitride (SiNₓ), silicon oxynitride (SiOₓN_{y}), or the like. These may be used alone or in combination with each other.

The first gate electrode GE1 may be arranged on the second insulating layer IL2. The first gate electrode GE1 may overlap the first channel area CH1 of the first active pattern AP1 in a plan view. The first gate electrode GE1 may include a conductive material such as a metal, an alloy, a conductive metal oxide, a conductive metal nitride, a transparent conductive oxide, or the like. Although not illustrated in FIG. 5, in an embodiment, the first gate electrode GE1 may contact the first bottom conductive layer BML1.

The first capacitor electrode CPE1 may be arranged on the second insulating layer IL2. The first capacitor electrode CPE1 may overlap the third capacitor electrode CPE3 in a plan view. The first capacitor electrode CPE1 and the third capacitor electrode CPE3 may form the second capacitor CAP2. The first capacitor electrode CPE1 may include a conductive material such as a metal, an alloy, a conductive metal oxide, a conductive metal nitride, a transparent conductive oxide, or the like.

The third insulating layer IL3 may cover the first gate electrode GE1 and the first capacitor electrode CPE1 and may be arranged on the second insulating layer IL2. The third insulating layer IL3 may include an insulating material. For example, the third insulating layer IL3 may include silicon oxide (SiOₓ), silicon nitride (SiNₓ), silicon oxynitride (SiOₓN_{y}), or the like. These may be used alone or in combination with each other.

The second capacitor electrode CPE2 may be arranged on the third insulating layer IL3. The second capacitor electrode CPE2 may overlap the first capacitor electrode CPE1 in a plan view. The first capacitor electrode CPE1 and the second capacitor electrode CPE2 may form the first capacitor CAP1. The second capacitor electrode CPE2 may include a conductive material such as a metal, an alloy, a conductive metal oxide, a conductive metal nitride, a transparent conductive oxide, or the like.

The fourth insulating layer IL4 may cover the second capacitor electrode CPE2 and may be arranged on the third insulating layer IL3. The fourth insulating layer IL4 may include an insulating material. For example, the fourth insulating layer IL4 may include silicon oxide (SiOₓ), silicon nitride (SiNₓ), silicon oxynitride (SiOₓN_{y}), or the like. These may be used alone or in combination with each other.

The first and second contact electrodes SE1 and DE1 may be arranged on the fourth insulating layer IL4. The first contact electrode SE1 may contact the first contact area S1 of the first active pattern AP1, and the second contact electrode DE1 may contact the second contact area D1 of the first active pattern AP1. The first and second contact electrodes SE1 and DE1 may include a conductive material such as a metal, an alloy, a conductive metal oxide, a conductive metal nitride, a transparent conductive oxide, or the like.

In an embodiment, the second contact electrode DE1 may contact the first bottom conductive layer BML1. However, the disclosure is not limited thereto. For example, in case that the first gate electrode GE1 contacts the first bottom conductive layer BML1, the second contact electrode DE1 may not contact the first bottom conductive layer BML1.

Accordingly, the first transistor TR1 including the first active pattern AP1, the first gate electrode GE1, the first contact electrode SE1, and the second contact electrode DE1 may be formed. As described above, the first transistor TR1 may be a transistor that is connected to the light emitting element through the anode connection electrode ACE.

The auxiliary electrode AUE may be arranged in the display area DA on the substrate SUB. For example, the auxiliary electrode AUE may be arranged on the fourth insulating layer IL4 in the display area DA. The auxiliary electrode AUE may contact the second bottom conductive layer BML2. The auxiliary electrode AUE may be spaced apart from the first electrode E1. The second power voltage (ELVSS, refer to FIG. 2) may be applied to the auxiliary electrode AUE. The auxiliary electrode AUE may include a conductive material such as a metal, an alloy, a conductive metal oxide, a conductive metal nitride, a transparent conductive oxide, or the like.

The fifth insulating layer IL5 may cover the first contact electrode SE1, the second contact electrode DE1, and the auxiliary electrode AUE and may be arranged on the fourth insulating layer IL4. The fifth insulating layer IL5 may include an insulating material. For example, the fifth insulating layer IL5 may include an organic insulating material. For example, the fifth insulating layer IL5 may include a photoresist, a polyacryl-based resin, a polyimide-based resin, a polyamide-based resin, a siloxane-based resin, an acrylic-based resin, an epoxy-based resin, or the like. These may be used alone or in combination with each other.

The first auxiliary connection electrode CCEa may be arranged on the auxiliary electrode AUE. For example, the first auxiliary connection electrode CCEa may be arranged on the fifth insulating layer IL5 in the display area DA. As described above, the first auxiliary connection electrode CCEa may be electrically connected to the auxiliary electrode AUE. For example, the first auxiliary connection electrode CCEa may contact the auxiliary electrode AUE through a contact hole CNT that penetrates the fifth insulating layer IL5. Accordingly, the position of the first auxiliary electrode connection portion CAa may correspond to a position of the contact hole CNT.

The first auxiliary connection electrode CCEa may include a conductive material such as a metal, an alloy, a conductive metal oxide, a conductive metal nitride, a transparent conductive oxide, or the like. In an embodiment, the first auxiliary connection electrode CCEa may have a multi-layer structure in which multiple conductive layers are stacked each other. For example, the first auxiliary connection electrode CCEa may include a first conductive layer CL1, a second conductive layer CL2, and a third conductive layer CL3 that are sequentially stacked.

In an embodiment, the first conductive layer CL1 may include a metal and/or a transparent conductive oxide. Examples of the metal that may be used as the first conductive layer CL1 may include titanium (Ti), molybdenum (Mo), or the like. Examples of the transparent conductive oxide that may be used as the first conductive layer CL1 may include indium tin oxide (ITO), indium zinc oxide (IZO), zinc oxide (ZnO), indium oxide (InO), indium gallium oxide (IGO), aluminum zinc oxide (AZO), or the like. The first conductive layer CL1 may have a relatively small thickness compared to the second conductive layer CL2.

The second conductive layer CL2 and the first conductive layer CL1 may include different materials. For example, the second conductive layer CL2 and the first conductive layer CL1 may include different metals. For example, the second conductive layer CL2 may include aluminum (Al), copper (Cu), or the like. The second conductive layer CL2 may have a thickness greater than the first conductive layer CL1.

The third conductive layer CL3 and the second conductive layer CL2 may include different materials. For example, the third conductive layer CL3 may include a metal and/or a transparent conductive oxide different from the second conductive layer CL2. Examples of the metal that may be used as the third conductive layer CL3 may include titanium (Ti), molybdenum (Mo), or the like. Examples of the transparent conductive oxide that may be used as the third conductive layer CL3 may include indium tin oxide (ITO), indium zinc oxide (IZO), zinc oxide (ZnO), indium oxide (InO), indium gallium oxide (IGO), aluminum zinc oxide (AZO), or the like. The third conductive layer CL3 may have a thickness less than the second conductive layer CL2.

In an embodiment, the first conductive layer CL1 and the third conductive layer CL3 may include a same material. However, the disclosure is not limited thereto.

A side surface CL2-S of the second conductive layer CL2 may be more depressed toward a center of the first auxiliary connection electrode CCEa than a side surface CL1-S of the first conductive layer CL1 and a side surface CL3-S of the third conductive layer CL3. In other words, the side surface CL1-S of the first conductive layer CL1 and the side surface CL3-S of the third conductive layer CL3 may protrude over the side surface CL2-S of the second conductive layer CL2. Accordingly, the first auxiliary connection electrode CCEa may have a tip structure due to a protruding portion of the third conductive layer CL3 over the second conductive layer CL2. For example, in case that the second conductive layer CL2 is etched using an etching material having a higher etching rate for the second conductive layer CL2 than for the first conductive layer CL1 and the third conductive layer CL3, the first auxiliary connection electrode CCEa may be formed to have the tip structure.

In FIG. 5, the first auxiliary connection electrode CCEa is illustrated as having a three-layer structure in which the first to third conductive layers CL1, CL2, and CL3 are stacked. However, the disclosure is not limited thereto, and in another embodiment, the first auxiliary connection electrode CCEa may have a two-layer structure in which the second conductive layer CL2 and the third conductive layer CL3 are stacked. For example, the first conductive layer CL1 may be omitted.

The anode connection electrode ACE may be arranged on the fifth insulating layer IL5. The anode connection electrode ACE may contact the second contact electrode DE1 and the first electrode E1. Accordingly, the anode connection electrode ACE may electrically connect the first transistor TR1 and the first light emitting element LDa. The anode connection electrode ACE may include a conductive material such as a metal, an alloy, a conductive metal oxide, a conductive metal nitride, a transparent conductive oxide, or the like.

The sixth insulating layer IL6 may cover the anode connection electrode ACE and may be arranged on the fifth insulating layer IL5. The sixth insulating layer IL6 may partially cover the first auxiliary connection electrode CCEa and may be arranged on the fifth insulating layer IL5. The sixth insulating layer IL6 may define a first sub-opening SO1 that exposes at least a portion of the first auxiliary connection electrode CCEa. For example, the first sub-opening SO1 may expose the tip structure of the first auxiliary connection electrode CCEa. The sixth insulating layer IL6 may include an insulating material. For example, the sixth insulating layer IL6 may include an organic insulating material. For example, the sixth insulating layer IL6 may include a photoresist, a polyacryl-based resin, a polyimide-based resin, a polyamide-based resin, a siloxane-based resin, an acrylic-based resin, an epoxy-based resin, or the like. These may be used alone or in combination with each other.

The first electrode E1 may be arranged in the display area DA on the substrate SUB. For example, the first electrode E1 may be arranged on the sixth insulating layer IL6. The first electrode E1 may contact the anode connection electrode ACE. Accordingly, the first electrode E1 may be electrically connected to the first transistor TR1 through the anode connection electrode ACE. The first electrode E1 may include a conductive material such as a metal, an alloy, a conductive metal oxide, a conductive metal nitride, a transparent conductive oxide, or the like. As described above, the first electrode E1 may function as the anode of FIG. 2.

The pixel defining layer PDL may be arranged on the substrate SUB and may define a pixel opening that exposes the first electrode E1. For example, the pixel defining layer PDL may be arranged on the sixth insulating layer IL6 and the first electrode E1 and may define the pixel opening that exposes at least a portion of the first electrode E1. The first emission area EAa may be defined by the pixel opening.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. For example, the first sub-opening SO1 and the second sub-opening SO2 may be connected to define a sub-opening OP, and the sub-opening OP may expose at least a portion of the first auxiliary connection electrode CCEa. For example, the sub-opening OP may expose the tip structure of the first auxiliary connection electrode CCEa.

The pixel defining layer PDL may include an insulating material. For example, the pixel defining layer PDL may include an organic insulating material. For example, the pixel defining layer PDL may include a photoresist, a polyacryl-based resin, a polyimide-based resin, a polyamide-based resin, a siloxane-based resin, an acrylic-based resin, an epoxy-based resin, or the like. These may be used alone or in combination with each other. In an embodiment, the pixel defining layer PDL may further include an inorganic material or an organic material including a light blocking material having a black color.

The organic film pattern OGP may be arranged on the pixel defining layer PDL in the display area DA. For example, the organic film pattern OGP may be arranged between the pixel defining layer PDL and the separator SPR in the display area DA. In an embodiment, an upper surface of the organic film pattern OGP may be a curved surface that is convex upward.

The organic film pattern OGP may include an organic material. For example, the organic film pattern OGP may include a photoresist, a polyacryl-based resin, a polyimide-based resin, a polyamide-based resin, a siloxane-based resin, an acrylic-based resin, an epoxy-based resin, or the like. These may be used alone or in combination with each other. In an embodiment, the organic film pattern OGP and the pixel defining layer PDL may include different materials.

The separator SPR may be arranged on the pixel defining layer PDL. A width of an upper portion of the separator SPR may be greater than a width of a lower portion of the separator SPR. For example, a side surface of the separator SPR connecting an upper surface of the separator SPR and a lower surface of the separator SPR may have a reverse tapered slope. In other words, the separator SPR may have a cross-sectional shape of an inverted trapezoid.

In FIG. 5, the side surface of the separator SPR is illustrated as having a single reverse tapered slope. However, the disclosure is not limited thereto, and in another embodiment, the side surface of the separator SPR may have multiple reverse tapered slopes. For example, the separator SPR may have a double reverse tapered structure.

The separator SPR may include the first portion SPP1 and the second portion SPP2 spaced apart from the first portion SPP1. The first portion SPP1 of the separator SPR may overlap the organic film pattern OGP in a plan view, and the second portion SPP2 of the separator SPR may be spaced apart from the organic film pattern OGP in a plan view. In other words, the second portion SPP2 of the separator SPR may not overlap the organic film pattern OGP in a plan view. In an embodiment, the first portion SPP1 of the separator SPR may contact the organic film pattern OGP and the pixel defining layer PDL and may cover the organic film pattern OGP. In other words, a first side surface of the first portion SPP1 of the separator SPR and a second side surface opposite to the first side surface may contact the pixel defining layer PDL in the display area DA. The first side surface and the second side surface of the first portion SPP1 of the separator SPR may have a reverse tapered slope, and separation (or disconnection) of the electrode layer E2L (or the second electrode E2) by the separator SPR may be readily implemented.

As the organic film pattern OGP is arranged between the pixel defining layer PDL and the first portion SPP1 of the separator SPR, an upper surface of the first portion SPP1 of the separator SPR may be a curved surface that is convex upward. In an embodiment, a level of the upper surface of the first portion SPP1 of the separator SPR may be higher than a level of an upper surface of the second portion SPP2 of the separator SPR. Here, the level of the upper surface of the separator SPR may be a level of the highest portion of the upper surface of the separator SPR.

The intermediate layer ML may be arranged on the first electrode E1 and the pixel defining layer PDL. A portion of the intermediate layer ML may be arranged in the pixel opening of the pixel defining layer PDL. In an embodiment, the intermediate layer ML may include a first functional layer including an organic material, a light emitting layer arranged on the first functional layer and including a light emitting material, and a second functional layer arranged on the light emitting layer and including an organic material. For example, the first functional layer may include a hole injection layer, a hole transport layer, or the like, and the second functional layer may include an electron transport layer, an electron injection layer, or the like.

A shadow area where it is difficult to deposit the intermediate layer ML may exist around the separator SPR having the reverse tapered slope. Accordingly, in the shadow area and/or around the shadow area, the intermediate layer ML may be separated (or disconnected) by the separator SPR. For example, the first functional layer and the second functional layer included in the intermediate layer ML may be separated (or disconnected) by the separator SPR. Accordingly, current leakage to other light emitting elements (e.g., the second light emitting element LDb and the third light emitting element LDc) adjacent to the first light emitting element LDa may be reduced. For example, color mixing phenomenon due to unnecessary emission of other light emitting elements may be prevented.

The first dummy layer DP1 may be arranged on the separator SPR. The first dummy layer DP1 may be formed because the intermediate layer ML has a structure separated (or disconnected) by the separator SPR. For example, the first dummy layer DP1 and the intermediate layer ML may be formed in a same process. In an embodiment, the first dummy layer DP1 may be omitted.

The intermediate layer ML may also be separated (or disconnected) by the tip structure of the first auxiliary connection electrode CCEa. As the intermediate layer ML is separated (or disconnected) by the tip structure of the first auxiliary connection electrode CCEa, the intermediate layer ML may expose at least a portion of the side surface CL2-S of the second conductive layer CL2. Accordingly, the second electrode E2 of the first light emitting element LDa may contact the side surface CL2-S of the second conductive layer CL2.

The electrode layer E2L (for example, the second electrode E2 in FIG. 5) may be arranged on the intermediate layer ML. The electrode layer E2L may include a conductive material such as a metal, an alloy, a conductive metal oxide, a conductive metal nitride, a transparent conductive oxide, or the like. In an embodiment, the electrode layer E2L may have a single-layer structure. However, the disclosure is not limited thereto. In another embodiment, the electrode layer E2L may have a multi-layer structure in which multiple conductive layers are stacked each other. For example, the electrode layer E2L may have a two-layer structure including a first sub-electrode layer including a metal and a second sub-electrode layer arranged on the first sub-electrode layer and including a transparent conductive oxide.

The shadow area where it is difficult to deposit the electrode layer E2L may exist around the separator SPR having the reverse tapered slope. In the shadow area and/or around the shadow area, the electrode layer E2L may be separated (or disconnected) by the separator SPR. For example, the electrode layer E2L may be separated (or disconnected) into the second electrode E2 of the first light emitting element LDa, the second electrode of the second light emitting element LDb, and the second electrode of the third light emitting element LDc.

The second electrode E2 of the first light emitting element LDa may be connected to the first auxiliary connection electrode CCEa. For example, the second electrode E2 may contact the side surface CL2-S of the second conductive layer CL2. For example, in case that a deposition angle of a deposition process for forming the electrode layer E2L is greater than a deposition angle of a deposition process for forming the intermediate layer ML, the electrode layer E2L (for example, the second electrode E2) may be formed to contact the side surface CL2-S of the second conductive layer CL2 while covering the intermediate layer ML disconnected by the tip structure. As a result, the second electrode E2 may be electrically connected to the auxiliary electrode AUE through the first auxiliary connection electrode CCEa. Accordingly, the second electrode E2 may receive the second power voltage (ELVSS, refer to FIG. 2) from the auxiliary electrode AUE.

In an embodiment, the electrode layer E2L (specifically, the second electrode E2) may be separated (or disconnected) by the tip structure of the first auxiliary connection electrode CCEa. However, the disclosure is not limited thereto, and the electrode layer E2L (for example, the second electrode E2) may be formed to extend without being disconnected by the tip structure.

The second dummy layer DP2 may be arranged on the separator SPR. For example, the second dummy layer DP2 may be arranged on the first dummy layer DP1. The second dummy layer DP2 may be formed because the electrode layer E2L has a structure separated (or disconnected) by the separator SPR. For example, the second dummy layer DP2 and the electrode layer E2L may be formed in a same process. In an embodiment, the second dummy layer DP2 may be omitted.

The encapsulation layer ENC may be arranged on the electrode layer E2L. The encapsulation layer ENC may entirely cover the electrode layer E2L, the separator SPR, the first dummy layer DP1, and the second dummy layer DP2. In an embodiment, the encapsulation layer ENC may include a first inorganic encapsulation layer IEL1 including an inorganic insulating material, an organic encapsulation layer OEL arranged on the first inorganic encapsulation layer IEL1 and including an organic insulating material, and a second inorganic encapsulation layer IEL2 arranged on the organic encapsulation layer OEL and including an inorganic insulating material.

Although not illustrated in FIG. 5, in an embodiment, a touch sensing layer may be arranged on the encapsulation layer ENC. For example, the touch sensing layer may include multiple touch electrode arrays for detecting a user's touch in a capacitive manner, a touch pad portion, and multiple touch lines electrically connecting the touch pad portion and the touch electrode arrays. However, the disclosure is not limited thereto. In an embodiment, the touch sensing layer may be omitted.

According to embodiments, the display device DD1 may include the auxiliary electrode AUE to which the second power voltage (ELVSS, refer to FIG. 2) is applied, and the auxiliary connection electrodes CCEa, CCEb, and CCEc each contacting the auxiliary electrode AUE and having the tip structure. Since each of the auxiliary connection electrodes CCEa, CCEb, and CCEc has the tip structure, the electrode layer E2L (e.g., the cathode) may be readily connected to the auxiliary connection electrodes CCEa, CCEb, and CCEc. The electrode layer E2L may be electrically connected to the auxiliary electrode AUE through the auxiliary connection electrodes CCEa, CCEb, and CCEc. Accordingly, the electrode layer E2L may receive the second power voltage from the auxiliary electrode AUE, and a voltage drop phenomenon of a voltage provided to the electrode layer E2L may be suppressed.

As described above, the level of the upper surface of the first portion SPP1 of the separator SPR may be higher than the level of the upper surface of the second portion SPP2 of the separator SPR. Accordingly, a mask used in the process of forming the intermediate layer ML may contact the first portion SPP1 of the separator SPR and may not contact the second portion SPP2 of the separator SPR. In other words, an area of the separator SPR contacting the mask may be relatively reduced. As a result, the phenomenon of being stamped by the mask, which may occur in case that the area of the separator SPR contacting the mask is large, may be suppressed.

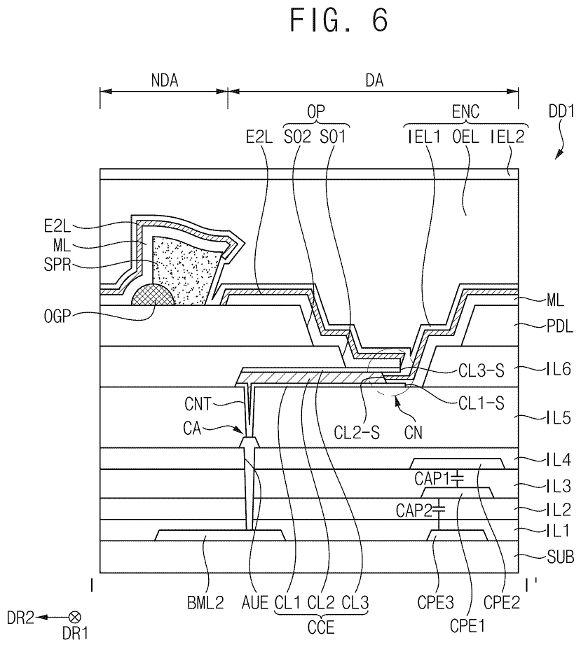

FIG. 6 is a schematic cross-sectional view taken along line I-I′ of FIG. 1A.

Referring to FIG. 6, the display device DD1 according to an embodiment of the disclosure may include the substrate SUB, the second bottom conductive layer BML2, the first capacitor CAP1, the second capacitor CAP2, the auxiliary electrode AUE, the auxiliary connection electrode CCE, the first to six insulating layers IL1, IL2, IL3, IL4, IL5, and IL6, the pixel defining layer PDL, the intermediate layer ML, the electrode layer E2L, the organic film pattern OGP, the separator SPR, and the encapsulation layer ENC. Hereinafter, redundant descriptions of the structure of the display device DD1 described above with reference to FIG. 5 may be omitted or may be summarized.

The organic film pattern OGP may be arranged on the pixel defining layer PDL in the peripheral area NDA. For example, the organic film pattern OGP may be arranged between the pixel defining layer PDL and the separator SPR in the peripheral area NDA. In an embodiment, an upper surface of the organic film pattern OGP may be a curved surface that is convex upward. The organic film pattern OGP may include an organic material. In an embodiment, the organic film pattern OGP and the pixel defining layer PDL may include different materials.

The separator SPR may be arranged on the pixel defining layer PDL. The separator SPR may contact the organic film pattern OGP and the pixel defining layer PDL in the peripheral area NDA. In an embodiment, the organic film pattern OGP may overlap a portion of the separator SPR in a plan view in the peripheral area NDA. For example, the organic film pattern OGP may overlap a portion of the separator SPR in a plan view in the peripheral area NDA. As the upper surface of the organic film pattern OGP includes a curved surface that is convex upwardly, an upper surface of the separator SPR may include a curved surface that is convex upwardly.

In an embodiment, as illustrated in FIG. 6, the cross-sectional shape of a portion of the separator SPR may be asymmetrical in the peripheral area NDA. For example, a first side surface of the portion of the separator SPR may contact the organic film pattern OGP in the peripheral area NDA, and a second side surface opposite to the first side surface may contact the pixel defining layer PDL without contacting the organic film pattern OGP. Accordingly, in the process of forming the separator SPR, a difference in the degree of inclination of the first side surface and the second side surface may be caused due to a difference in the characteristics between the organic film pattern OGP and the pixel defining layer PDL.

The second side surface of the separator SPR may have a reverse tapered slope. As the second side surface of the separator SPR has a reverse tapered slope, the intermediate layer ML and the electrode layer E2L may have a separated (or disconnected) structure in the display area DA.

In contrast, the first side surface of the separator SPR may not have a reverse tapered slope. For example, by forming the organic film pattern OGP that overlaps the first side surface of the separator SPR in a plan view in the peripheral area NDA, the first side surface of the separator SPR may not have a reverse tapered slope. As the first side surface of the separator SPR does not have a reverse tapered slope, the intermediate layer ML and the electrode layer E2L may be formed to extend without being disconnected in the peripheral area NDA.

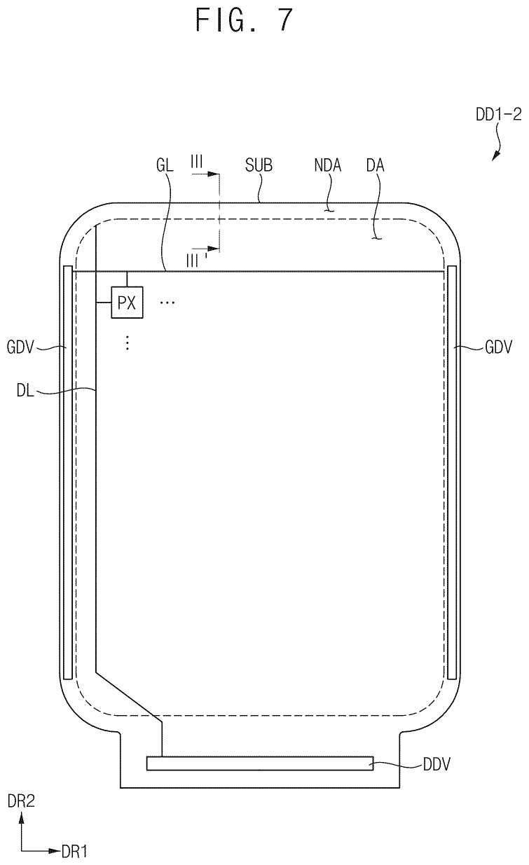

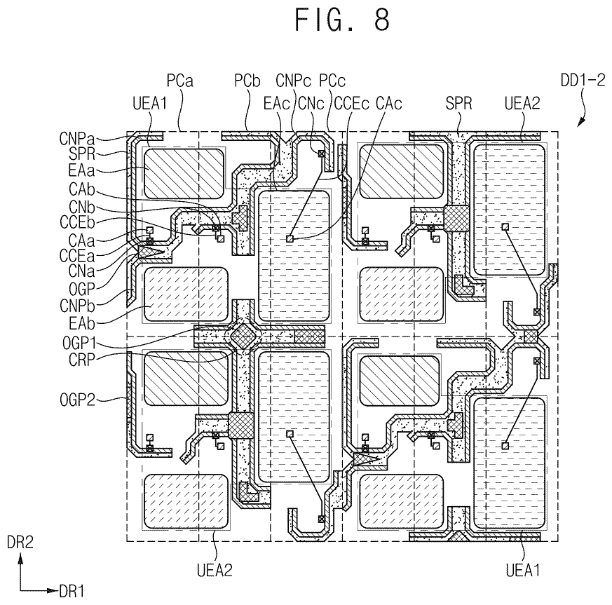

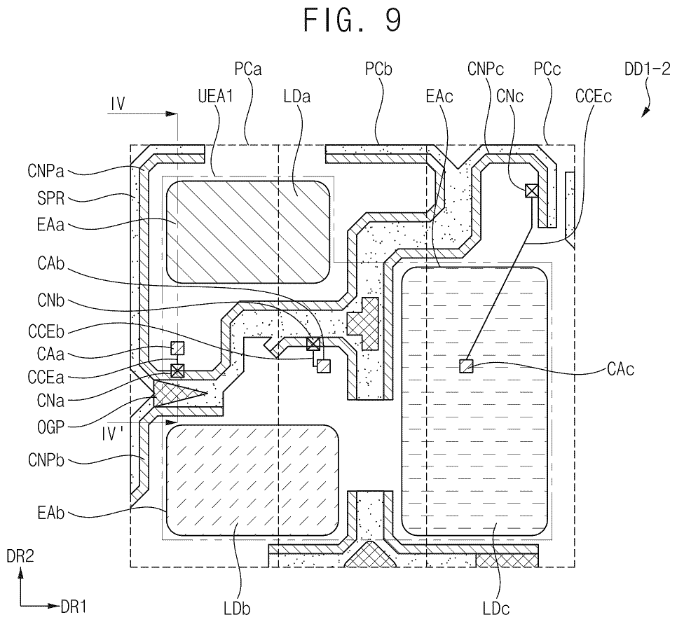

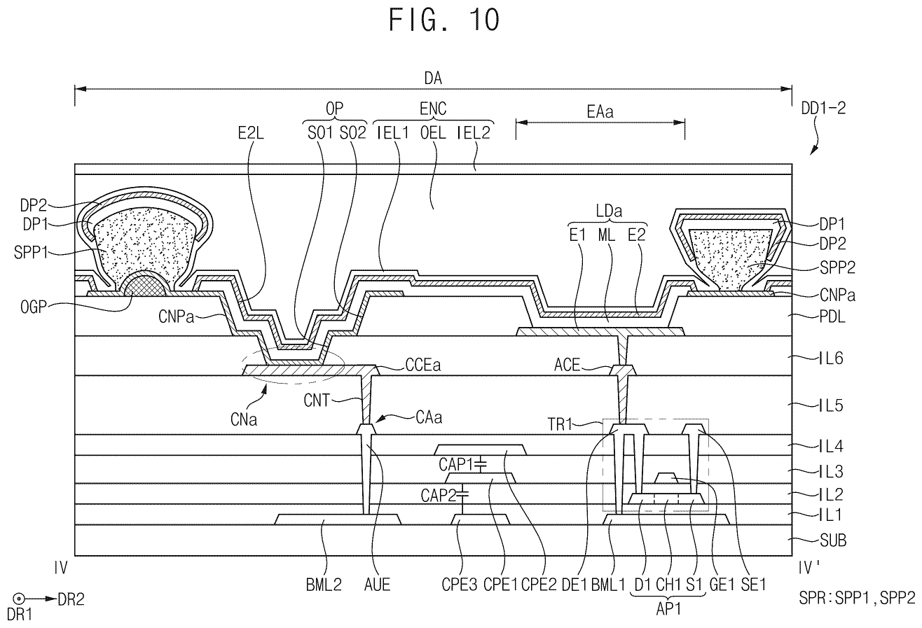

FIG. 7 is a plan view illustrating a display device according to an embodiment of the disclosure. FIG. 8 is a plan view illustrating a portion of an area of the display device of FIG. 7. FIG. 9 is an enlarged plan view illustrating one unit emission area among the unit emission areas of FIG. 8. FIG. 10 is a schematic cross-sectional view taken along line IV-IV′ of FIG. 9.

For example, FIG. 8 schematically illustrates an area in which four unit emission areas UEA1 and UEA2 forming a matrix of two rows and two columns are arranged, and FIG. 9 schematically illustrates an enlarged view of a first unit emission area UEA1 among the unit emission areas UEA1 and UEA2. For convenience of description, some of components illustrated in FIG. 10 are omitted or emphasized in FIGS. 8 and 9.

Referring to FIGS. 7, 8, 9, and 10, a display device DD1-2 may be a device activated according to an electrical signal. For example, as illustrated in FIG. 7, the display device DD1-2 may be a small-sized display device used in a small-sized electronic device such as a smart phone, a mobile phone, a smart watch, a game console, a camera, or the like. However, the disclosure is not limited thereto, and the display device DD1-2 may be a medium and large-sized display device used in medium and large-sized electronic devices such as a laptop, a tablet PC, a television, a computer monitor, a vehicle monitor, an external billboard, or the like.

Compared to the display device DD1 described above with reference to FIGS. 1A, 1, 2, 3, 4, and 5, the display device DD1-2 may further include a connection pattern (e.g., a first connection pattern CNPa of FIG. 10) that electrically connects an auxiliary connection electrode (e.g., a first auxiliary connection electrode CCEa of FIG. 10) and a second electrode (e.g., a second electrode E2 of FIG. 10). Hereinafter, redundant descriptions of the display device DD1 described with reference to FIGS. 1A, 1B, 2, 3, 4, and 5 may be omitted or may be summarized.

As illustrated in FIGS. 8 and 9, the display device DD1-2 may include first to third pixel driving circuits PCa, PCb, and PCc, first to third light emitting elements LDa, LDb, and LDc, first to third auxiliary connection electrodes CCEa, CCEb, and CCEc, first to third connection patterns CNPa, CNPb, and CNPc, a separator SPR, and multiple organic film patterns OGP.

Each of the first to third pixel driving circuits PCa, PCb, and PCc may correspond to the pixel driving circuit PC1 described above with reference to FIG. 2. For example, each of the first to third pixel driving circuits PCa, PCb, and PCc may include at least one transistor and at least one capacitor. For example, each of the first to third pixel driving circuits PCa, PCb, and PCc may include a first transistor TR1, a first capacitor CAP1, and a second capacitor CAP2 illustrated in FIG. 10.

The first transistor TR1 of FIG. 10 may be a transistor that is connected to the light emitting element through an anode connection electrode (ACE, refer to FIG. 10). For example, in case that the first to third pixel driving circuits PCa, PCb, and PCc are the pixel driving circuit PC1 of FIG. 2, the first transistor TR1 may be the sixth transistor T6 of FIG. 2.

Each of the first to third light emitting elements LDa, LDb, and LDc may correspond to the light emitting element LD described above with reference to FIG. 2. For example, each of the first to third light emitting elements LDa, LDb, and LDc may include a first electrode (E1, refer to FIG. 10), an intermediate layer (ML, refer to FIG. 10) arranged on the first electrode, and an electrode layer (E2L, refer to FIG. 10) arranged on the intermediate layer. In an embodiment, the first electrode E1 may function as the anode of FIG. 2, and the electrode layer E2L may function as the cathode of FIG. 2.

In an embodiment, the electrode layer E2L may be separated (or disconnected) into multiple second electrodes that are spaced apart from each other by the separator SPR. For example, the electrode layer E2L may be separated (or disconnected) into a second electrode (E2, refer to FIG. 10) of the first light emitting element LDa, a second electrode of the second light emitting element LDb, and a second electrode of the third light emitting element LDc.

The first to third light emitting elements LDa, LDb, and LDc may be connected to the first to third pixel driving circuits PCa, PCb, and PCc, respectively. For example, the first light emitting element LDa may be connected to the first pixel driving circuit PCa, the second light emitting element LDb may be connected to the second pixel driving circuit PCb, and the third light emitting element LDc may be connected to the third pixel driving circuit PCc.

The separator SPR may be arranged between first to third emission areas EAa, EAb, and EAc in a plan view. For example, the separator SPR may be arranged between the first emission area EAa and the second emission area EAb, between the second emission area EAb and the third emission area EAc, and between the first emission area EAa and the third emission area EAc in a plan view. The separator SPR may surround at least a portion of each of the first to third emission areas EAa, EAb, and EAc in a plan view. In an embodiment, as illustrated in FIGS. 8 and 9, in a plan view, the separator SPR may surround a portion of each of the first to third emission areas EAa, EAb, and EAc and may not surround another portion of each of the first to third emission areas EAa, EAb, and EAc. However, the disclosure is not limited thereto, and the separator SPR may entirely surround each of the first to third emission areas EAa, EAb, and EAc in a plan view. In an embodiment, the separator SPR may include an organic insulating material.

The separator SPR may separate (or disconnect) the electrode layer E2L into the second electrode E2 of the first light emitting element LDa, the second electrode of the second light emitting element LDb, and the second electrode of the third light emitting element LDc in the display area DA. Accordingly, the second electrode E2 of the first light emitting element LDa, the second electrode of the second light emitting element LDb, and the second electrode of the third light emitting element LDc may be spaced apart from each other.

The organic film patterns OGP may overlap at least a portion of the separator SPR in a plan view. The organic film patterns OGP may be arranged in a portion of an area where the separator SPR is arranged in a plan view. In other words, a portion of the separator SPR (e.g., a first portion SPP1 of the separator SPR of FIG. 10) may overlap the organic film pattern OGP in a plan view, and other portions of the separator SPR (e.g., a second portion SPP2 of the separator SPR of FIG. 10) may not overlap the organic film pattern OGP in a plan view. The organic film pattern OGP may include an organic material.

In an embodiment, the organic film patterns OGP may overlap an intersection portion CRP of the separator SPR in a plan view. The intersection portion CRP of the separator SPR may be a portion where a first extension portion of the separator SPR extending in the first direction DR1 and a second extension portion of the separator SPR extending in the second direction DR2 meet. For example, as illustrated in FIG. 8, a first organic film pattern OGP1 among the organic film patterns OGP may overlap the intersection portion CRP of the separator SPR in a plan view. However, the disclosure is not limited thereto, and the organic film patterns OGP may overlap the first extension portion of the separator SPR and the second extension portion of the separator SPR in a plan view. For example, as illustrated in FIG. 8, a second organic film pattern OGP2 among the organic film patterns OGP may overlap the first extension portion of the separator SPR or the second extension portion of the separator SPR in a plan view.

In an embodiment, the organic film pattern OGP may be arranged in an area where the separator SPR is arranged in a plan view. However, the disclosure is not limited thereto, and some of the organic film patterns OGP may be arranged in the area where the separator SPR is arranged in a plan view, and other of the organic film patterns OGP may overlap both the area where the separator SPR is arranged and an area where the separator SPR is not arranged in a plan view.

Hereinafter, a connection relationship between the first to third light emitting elements LDa, LDb, and LDc and the first to third auxiliary connection electrodes CCEa, CCEb, and CCEc will be described in more detail, focusing on the first unit emission area UEA1 of FIG. 9. The following description of the connection relationship between the first to third light emitting elements LDa, LDb, and LDc and the first to third auxiliary connection electrodes CCEa, CCEb, and CCEc may be substantially equally applied to all unit emission areas.

As described above, the display device DD1-2 may include the first to third auxiliary connection electrodes CCEa, CCEb, and CCEc and the first to third connection patterns CNPa, CNPb, and CNPc. The first auxiliary connection electrode CCEa and the first connection pattern CNPa may electrically connect the first light emitting element LDa and an auxiliary electrode (AUE, refer to FIG. 10). The second auxiliary connection electrode CCEb and the second connection pattern CNPb may electrically connect the second light emitting element LDb and the auxiliary electrode AUE. The third auxiliary connection electrode CCEc and the third connection pattern CNPc may electrically connect the third light emitting element LDc and the auxiliary electrode AUE. The second power voltage (ELVSS, refer to FIG. 2) may be applied to the auxiliary electrode AUE.

The first to third auxiliary connection electrodes CCEa, CCEb, and CCEc may include a conductive material such as a metal, an alloy, a conductive metal oxide, a conductive metal nitride, a transparent conductive oxide, or the like. In an embodiment, the first to third auxiliary connection electrodes CCEa, CCEb, and CCEc may have a single-layer structure or a multi-layer structure in which multiple conductive layers are stacked each other.

In an embodiment, the first to third connection patterns CNPa, CNPb, and CNPc may include a transparent conductive oxide. For example, the first to third connection patterns CNPa, CNPb, and CNPc may include indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InOₓ), tin oxide (SnOₓ), gallium oxide (GaOₓ), aluminum zinc oxide (AZO), or the like. These may be used alone or in combination with each other. However, the disclosure is not limited thereto, and in another embodiment, the first to third connection patterns CNPa, CNPb, and CNPc may include a conductive material such as a metal, an alloy, a conductive metal nitride, or the like. In an embodiment, the first to third connection patterns CNPa, CNPb, and CNPc may have a single-layer structure or a multi-layer structure in which multiple conductive layers are stacked each other.

The first auxiliary connection electrode CCEa may include a first auxiliary electrode connection portion CAa and a first light emitting connection portion CNa.

The first auxiliary electrode connection portion CAa may be a portion, which is connected to the auxiliary electrode AUE, of the first auxiliary connection electrode CCEa. For example, a position of the first auxiliary electrode connection portion CAa may correspond to a position of a contact hole (CNT, refer to FIG. 10) that exposes the auxiliary electrode AUE and penetrates a fifth insulating layer (IL5, refer to FIG. 10).

The first light emitting connection portion CNa may be a portion, which is connected to the first connection pattern CNPa, of the first auxiliary connection electrode CCEa. For example, the first light emitting connection portion CNa may be a portion, which is exposed by a sixth insulating layer (IL6, refer to FIG. 10) and a pixel defining layer (PDL, refer to FIG. 10) for being connected to the first connection pattern CNPa, of the first auxiliary connection electrode CCEa. Accordingly, a position of the first light emitting connection portion CNa may correspond to a position of a sub-opening (OP, refer to FIG. 10) that exposes the first auxiliary connection electrode CCEa and penetrates the pixel defining layer PDL and the sixth insulating layer IL6. In a plan view, the first light emitting connection portion CNa may not overlap the first emission area EAa. For example, in a plan view, the first light emitting connection portion CNa may be arranged between the first emission area EAa and the separator SPR.

The first connection pattern CNPa may be connected to the first auxiliary connection electrode CCEa. For example, the first connection pattern CNPa may contact the first light emitting connection portion CNa of the first auxiliary connection electrode CCEa. However, the disclosure is not limited thereto, and the first connection pattern CNPa may not directly contact the first auxiliary connection electrode CCEa. For example, the first connection pattern CNPa may contact a capping layer that contacts the first light emitting connection portion CNa of the first auxiliary connection electrode CCEa, and may be electrically connected to the first light emitting connection portion CNa of the first auxiliary connection electrode CCEa through the capping layer. The capping layer may include a conductive material. For example, the capping layer and the first electrode E1 may be substantially simultaneously formed and may include a same material.

The first connection pattern CNPa may not overlap the first emission area EAa in a plan view. In an embodiment, the first connection pattern CNPa may surround at least a portion of the first emission area EAa in a plan view. For example, as illustrated in FIG. 9, the first connection pattern CNPa may surround a portion of the first emission area EAa and may not surround other portions of the first emission area EAa in a plan view. However, the disclosure is not limited thereto. In another embodiment, the first connection pattern CNPa may entirely surround the first emission area EAa in a plan view, and the first connection pattern CNPa may have a closed ring shape that entirely surrounds the first emission area EAa in a plan view.

The second electrode E2 of the first light emitting element LDa may be connected to the first connection pattern CNPa. For example, the second electrode E2 of the first light emitting element LDa may contact the first connection pattern CNPa. Accordingly, the first connection pattern CNPa may electrically connect the first auxiliary connection electrode CCEa and the second electrode E2 of the first light emitting element LDa. As a result, the second electrode E2 of the first light emitting element LDa may be electrically connected to the auxiliary electrode AUE through the first auxiliary connection electrode CCEa and the first connection pattern CNPa.

In an embodiment, the second electrode E2 of the first light emitting element LDa and the first connection pattern CNPa may contact each other at a position not overlapping the first emission area EAa in a plan view. Accordingly, the second electrode E2 of the first light emitting element LDa may be electrically connected to the auxiliary electrode AUE through the first connection pattern CNPa and the first auxiliary connection electrode CCEa without reducing the size of the first emission area EAa.

The second auxiliary connection electrode CCEb may include a second auxiliary electrode connection portion CAb and a second light emitting connection portion CNb.

The second auxiliary electrode connection portion CAb may be a portion, which is connected to the auxiliary electrode AUE, of the second auxiliary connection electrode CCEb. For example, a position of the second auxiliary electrode connection portion CAb may correspond to a position of a contact hole that exposes the auxiliary electrode AUE and penetrates the fifth insulating layer IL5.

The second light emitting connection portion CNb may be a portion, which is connected to the second connection pattern CNPb, of the second auxiliary connection electrode CCEb. For example, the second light emitting connection portion CNb may be a portion, which is exposed by the sixth insulating layer IL6 and the pixel defining layer PDL for being connected to the second connection pattern CNPb, of the second auxiliary connection electrode CCEb. Accordingly, a position of the second light emitting connection portion CNb may correspond to a position of a sub-opening that exposes the second auxiliary connection electrode CCEb and penetrates the pixel defining layer PDL and the sixth insulating layer IL6. In a plan view, the second light emitting connection portion CNb may not overlap the second emission area EAb. For example, in a plan view, the second light emitting connection portion CNb may be arranged between the second emission area EAb and the separator SPR.

In an embodiment, the second auxiliary connection electrode CCEb may be spaced apart from the first auxiliary connection electrode CCEa in a plan view. In other words, the first auxiliary connection electrode CCEa and the second auxiliary connection electrode CCEb may be electrodes that are distinct from each other.

The second connection pattern CNPb may be connected to the second auxiliary connection electrode CCEb. For example, the second connection pattern CNPb may contact the second light emitting connection portion CNb of the second auxiliary connection electrode CCEb. However, the disclosure is not limited thereto, and the second connection pattern CNPb may not directly contact the second auxiliary connection electrode CCEb. For example, the second connection pattern CNPb may contact a capping layer that contacts the second light emitting connection portion CNb of the second auxiliary connection electrode CCEb, and may be electrically connected to the second light emitting connection portion CNb of the second auxiliary connection electrode CCEb through the capping layer. The capping layer may include a conductive material. For example, the capping layer and the first electrode E1 may be substantially simultaneously formed and may include a same material.

The second connection pattern CNPb may not overlap the second emission area EAb in a plan view. In an embodiment, the second connection pattern CNPb may surround at least a portion of the second emission area EAb in a plan view. For example, as illustrated in FIG. 9, the second connection pattern CNPb may surround a portion of the second emission area EAb and may not surround another portion of the second emission area EAb. However, the disclosure is not limited thereto, and in another embodiment, the second connection pattern CNPb may have a closed ring shape that entirely surrounds the second emission area EAb in a plan view.

In an embodiment, the second connection pattern CNPb may be connected to the first connection pattern CNPa. For example, although not illustrated in FIG. 8, a connection pattern may be arranged in an area where the separator SPR is arranged between the first connection pattern CNPa and the second connection pattern CNPb, and the first connection pattern CNPa and the second connection pattern CNPb may be connected to each other. However, the disclosure is not limited thereto. In another embodiment, the second connection pattern CNPb may be spaced apart from the first connection pattern CNPa. In other words, the first connection pattern CNPa and the second connection pattern CNPb may be patterns that are distinct from each other.

The second electrode of the second light emitting element LDb may be connected to the second connection pattern CNPb. For example, the second electrode of the second light emitting element LDb may contact the second connection pattern CNPb. Accordingly, the second connection pattern CNPb may electrically connect the second auxiliary connection electrode CCEb and the second electrode of the second light emitting element LDb. As a result, the second electrode of the second light emitting element LDb may be electrically connected to the auxiliary electrode AUE through the second auxiliary connection electrode CCEb and the second connection pattern CNPb.

In an embodiment, the second electrode of the second light emitting element LDb and the second connection pattern CNPb may contact each other at a position not overlapping the second emission area EAb in a plan view. Accordingly, the second electrode of the second light emitting element LDb may be electrically connected to the auxiliary electrode AUE through the second connection pattern CNPb and the second auxiliary connection electrode CCEb without reducing the size of the second emission area EAb.

The third auxiliary connection electrode CCEc may include a third auxiliary electrode connection portion CAc and a third light emitting connection portion CNc.

The third auxiliary electrode connection portion CAc may be a portion, which is connected to the auxiliary electrode AUE, of the third auxiliary connection electrode CCEc. For example, a position of the third auxiliary electrode connection portion CAc may correspond to a position of a contact hole that exposes the auxiliary electrode AUE and penetrates the fifth insulating layer IL5.

The third light emitting connection portion CNc may be a portion, which is connected to the third connection pattern CNPc, of the third auxiliary connection electrode CCEc. For example, the third light emitting connection portion CNc may be a portion, which is exposed by the sixth insulating layer IL6 and the pixel defining layer PDL for being connected to the third connection pattern CNPc, of the third auxiliary connection electrode CCEc. Accordingly, a position of the third light emitting connection portion CNc may correspond to a position of a sub-opening that exposes the third auxiliary connection electrode CCEc and penetrates the pixel defining layer PDL and the sixth insulating layer IL6. In a plan view, the third light emitting connection portion CNc may not overlap the third emission area EAc. For example, in a plan view, the third light emitting connection portion CNc may be arranged between the third emission area EAc and the separator SPR.

In an embodiment, the third auxiliary connection electrode CCEc may be spaced apart from the first auxiliary connection electrode CCEa and the second auxiliary connection electrode CCEb in a plan view. In other words, the first auxiliary connection electrode CCEa, the second auxiliary connection electrode CCEb, and the third auxiliary connection electrode CCEc may be electrodes that are distinct from each other.

The third connection pattern CNPc may be connected to the third auxiliary connection electrode CCEc. For example, the third connection pattern CNPc may contact the third light emitting connection portion CNc of the third auxiliary connection electrode CCEc. However, the disclosure is not limited thereto, and the third connection pattern CNPc may not directly contact the third auxiliary connection electrode CCEc. For example, the third connection pattern CNPc may contact a capping layer that contacts the third light emitting connection portion CNc of the third auxiliary connection electrode CCEc, and may be electrically connected to the third light emitting connection portion CNc of the third auxiliary connection electrode CCEc through the capping layer. The capping layer may include a conductive material. For example, the capping layer and the first electrode E1 may be substantially simultaneously formed and may include a same material.

The third connection pattern CNPc may not overlap the third emission area EAc in a plan view. In an embodiment, the third connection pattern CNPc may surround at least a portion of the third emission area EAc in a plan view. For example, as illustrated in FIG. 9, the third connection pattern CNPc may surround a portion of the third emission area EAc and may not surround another portion of the third emission area EAc. However, the disclosure is not limited thereto, and in another embodiment, the third connection pattern CNPc may have a closed ring shape that entirely surrounds the third emission area EAc in a plan view.

In an embodiment, the third connection pattern CNPc may be connected to the first connection pattern CNPa and/or the second connection pattern CNPb. For example, although not illustrated in FIG. 8, a connection pattern may be arranged in an area where the separator SPR is arranged between the first connection pattern CNPa and the third connection pattern CNPc and/or between the second connection pattern CNPb and the third connection pattern CNPc, and the third connection pattern CNPc may be connected to the first connection pattern CNPa and/or the second connection pattern CNPb. However, the disclosure is not limited thereto. In another embodiment, the third connection pattern CNPc may be spaced apart from the first connection pattern CNPa and the second connection pattern CNPb. In other words, the first connection pattern CNPa, the second connection pattern CNPb, and the third connection pattern CNPc may be patterns that are distinct from each other.

The second electrode of the third light emitting element LDc may be connected to the third connection pattern CNPc. For example, the second electrode of the third light emitting element LDc may contact the third connection pattern CNPc. Accordingly, the third connection pattern CNPc may electrically connect the third auxiliary connection electrode CCEc and the second electrode of the third light emitting element LDc. As a result, the second electrode of the third light emitting element LDc may be electrically connected to the auxiliary electrode AUE through the third auxiliary connection electrode CCEc and the third connection pattern CNPc.

In an embodiment, the second electrode of the third light emitting element LDc and the third connection pattern CNPc may contact each other at a position not overlapping the third emission area EAc in a plan view. Accordingly, the second electrode of the third light emitting element LDc may be electrically connected to the auxiliary electrode AUE through the third connection pattern CNPc and the third auxiliary connection electrode CCEc without reducing the size of the third emission area EAc.

As illustrated in FIG. 8, the shape or arrangement of each of the first to third auxiliary connection electrodes CCEa, CCEb, and CCEc and the arrangement relationship between the first to third auxiliary connection electrodes CCEa, CCEb, and CCEc may be the same for each first unit emission area UEA1. The shape or arrangement of each of the first to third auxiliary connection electrodes CCEa, CCEb, and CCEc and the arrangement relationship between the first to third auxiliary connection electrodes CCEa, CCEb, and CCEc may be the same for each second unit emission area UEA2.

The shape or arrangement of each of the first to third connection patterns CNPa, CNPb, and CNPc and the arrangement relationship between the first to third connection patterns CNPa, CNPb, and CNPc may be the same for each first unit emission area UEA1. The shape or arrangement of each of the first to third connection patterns CNPa, CNPb, and CNPc and the arrangement relationship between the first to third connection patterns CNPa, CNPb, and CNPc may be the same for each second unit emission area UEA2.

As described above, the display device DD1-2 may include the separator SPR. The separator SPR may overlap the first to third connection patterns CNPa, CNPb, and CNPc in a plan view. For example, the separator SPR may cover a portion of each of the first to third connection patterns CNPa, CNPb, and CNPc. For example, at least a portion of the separator SPR may extend along an edge of each of the first to third connection patterns CNPa, CNPb, and CNPc in a plan view. Accordingly, areas where the second electrodes of the first to third light emitting elements LDa, LDb, and LDc and the first to third connection patterns CNPa, CNPb, and CNPc contact may be adjacent to or overlap an area where the separator SPR is arranged in a plan view.

Hereinafter, the cross-sectional structure of the display device DD1-2 will be described in more detail focusing on the first emission area EAa. The following description of the cross-sectional structure of the display device DD1-2 may be substantially equally applied to all emission areas.

As illustrated in FIG. 10, the display device DD1-2 may include a substrate SUB, a first bottom conductive layer BML1, a second bottom conductive layer BML2, the first transistor TR1, the first capacitor CAP1, the second capacitor CAP2, the auxiliary electrode AUE, an anode connection electrode ACE, the first auxiliary connection electrode CCEa, first to six insulating layers IL1, IL2, IL3, IL4, IL5, and IL6, the pixel defining layer PDL, the first light emitting element LDa, the organic film pattern OGP, the first connection pattern CNPa, the separator SPR, a first dummy layer DP1, a second dummy layer DP2, and an encapsulation layer ENC. The first light emitting element LDa may include the first electrode E1, the intermediate layer ML, and the second electrode E2. Hereinafter, redundant descriptions of the display device DD1 described above with reference to FIG. 5 may be omitted or may be summarized.

The auxiliary electrode AUE may be arranged on the fourth insulating layer IL4 in the display area DA. The auxiliary electrode AUE may contact the second bottom conductive layer BML2. The auxiliary electrode AUE may be spaced apart from the first electrode E1. The second power voltage (ELVSS, refer to FIG. 2) may be applied to the auxiliary electrode AUE.

The first auxiliary connection electrode CCEa may be arranged on the fifth insulating layer IL5 in the display area DA. As described above, the first auxiliary connection electrode CCEa may be connected to the auxiliary electrode AUE. For example, the first auxiliary connection electrode CCEa may contact the auxiliary electrode AUE through a contact hole CNT that penetrates the fifth insulating layer IL5. Accordingly, the position of the first auxiliary electrode connection portion CAa may correspond to a position of the contact hole CNT. In an embodiment, the first auxiliary connection electrode CCEa may have a single-layer structure or a multi-layer structure in which multiple conductive layers are stacked each other.

The anode connection electrode ACE may be arranged on the fifth insulating layer IL5. The anode connection electrode ACE may contact the second contact electrode DE1 and the first electrode E1. Accordingly, the anode connection electrode ACE may electrically connect the first transistor TR1 and the first light emitting element LDa.

The sixth insulating layer IL6 may cover the anode connection electrode ACE and may be arranged on the fifth insulating layer IL5. The sixth insulating layer IL6 may partially cover the first auxiliary connection electrode CCEa and may be arranged on the fifth insulating layer IL5. The sixth insulating layer IL6 may define a first sub-opening SO1 that exposes at least a portion of the first auxiliary connection electrode CCEa.

The first electrode E1 may be arranged on the sixth insulating layer IL6. The first electrode E1 may contact the anode connection electrode ACE. Accordingly, the first electrode E1 may be electrically connected to the first transistor TR1 through the anode connection electrode ACE.

The pixel defining layer PDL may be arranged on the sixth insulating layer IL6 and the first electrode E1. The pixel defining layer PDL may define the pixel opening that exposes at least a portion of the first electrode E1. The first emission area EAa may be defined by the pixel opening.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. For example, the first sub-opening SO1 and the second sub-opening SO2 may be connected to define a sub-opening OP. The sub-opening OP may expose at least a portion of the first auxiliary connection electrode CCEa.

The organic film pattern OGP may be arranged on the pixel defining layer PDL in the display area DA. For example, the organic film pattern OGP may be arranged between the pixel defining layer PDL and the separator SPR in the display area DA. In an embodiment, an upper surface of the organic film pattern OGP may be a curved surface that is convex upwardly. The organic film pattern OGP may include an organic material. In an embodiment, the organic film pattern OGP and the pixel defining layer PDL may include different materials.

The first connection pattern CNPa may be arranged on the first auxiliary connection electrode CCEa, the sixth insulating layer IL6, and the pixel defining layer PDL. As described above, the first connection pattern CNPa may be connected to the first auxiliary connection electrode CCEa. The first connection pattern CNPa may be connected to the first auxiliary connection electrode CCEa through the sub-opening OP that penetrates the sixth insulating layer IL6 and the pixel defining layer PDL. Accordingly, the position of the first light emitting connection portion CNa may correspond to a position of the sub-opening OP.

In an embodiment, the first connection pattern CNPa may include a transparent conductive oxide. However, the disclosure is not limited thereto, and in another embodiment, the first connection pattern CNPa may include a conductive material such as a metal, an alloy, a conductive metal oxide, a conductive metal nitride, or the like. In an embodiment, the first connection pattern CNPa may have a single-layer structure or a multi-layer structure in which multiple conductive layers are stacked each other.

In an embodiment, a portion of the first connection pattern CNPa may be arranged along the profiles of the pixel defining layer PDL and the organic film pattern OGP, and the portion of the first connection pattern CNPa may cover the organic film pattern OGP. However, the disclosure is not limited thereto, and in another embodiment, the first connection pattern CNPa may expose at least a portion of the upper surface of the organic film pattern OGP.

In an embodiment, the first connection pattern CNPa may be arranged along the profile of the pixel defining layer PDL, and the organic film pattern OGP may be arranged on the first connection pattern CNPa. The first portion SPP1 of the separator SPR may contact the organic film pattern OGP and may cover the organic film pattern OGP, and a first side surface and a second side surface opposite to the first side surface of the first portion SPP1 of the separator SPR may contact the first connection pattern CNPa.

The separator SPR may be arranged on the pixel defining layer PDL and the first connection pattern CNPa. The separator SPR may overlap the first connection pattern CNPa in a plan view. For example, the separator SPR may cover a portion of the first connection pattern CNPa.

A side surface of the separator SPR connecting an upper surface of the separator SPR and a lower surface of the separator SPR may have a reverse tapered slope. In other words, a cross-section of at least a portion of the separator SPR may be an inverted trapezoid.

In an embodiment, as illustrated in FIG. 10, the side surface of the separator SPR may have multiple reverse tapered slopes. For example, the separator SPR may have a double reverse tapered structure. Accordingly, separation (or disconnection) of the electrode layer E2L by the separator SPR may be more readily implemented.

The separator SPR may include the first portion SPP1 and the second portion SPP2 spaced apart from the first portion SPP1. The first portion SPP1 of the separator SPR may overlap the organic film pattern OGP in a plan view, and the second portion SPP2 of the separator SPR may be spaced apart from the organic film pattern OGP in a plan view. In other words, the second portion SPP2 of the separator SPR may not overlap the organic film pattern OGP in a plan view. In an embodiment, the first portion SPP1 of the separator SPR may cover a portion of the first connection pattern CNPa, and the first side surface and the second side surface opposite to the first side surface of the first portion SPP1 of the separator SPR may contact the first connection pattern CNPa.

As the organic film pattern OGP is arranged between the pixel defining layer PDL and the first portion SPP1 of the separator SPR, an upper surface of the first portion SPP1 of the separator SPR may have a curved surface that is convex upwardly. In an embodiment, a level of the upper surface of the first portion SPP1 of the separator SPR may be higher than a level of an upper surface of the second portion SPP2 of the separator SPR. Accordingly, a mask used in the process of forming the intermediate layer ML may contact the first portion SPP1 of the separator SPR and may not contact the second portion SPP2 of the separator SPR. As a result, the phenomenon of being stamped by the mask, which may occur in case that an area of the separator SPR contacting the mask is large, may be suppressed.

The intermediate layer ML may be arranged on the first electrode E1, the pixel defining layer PDL, and the first connection pattern CNPa. A portion of the intermediate layer ML may be arranged in the pixel opening of the pixel defining layer PDL.

A shadow area where it is difficult to deposit the intermediate layer ML may exist around the separator SPR having the reverse tapered slope. Accordingly, in the shadow area and/or around the shadow area, the intermediate layer ML may be separated (or disconnected) by the separator SPR. As the intermediate layer ML is separated (or disconnected), the intermediate layer ML may expose a portion of the first connection pattern CNPa at a position adjacent to or overlapping the separator SPR. Accordingly, the second electrode E2 of the first light emitting element LDa may contact the first connection pattern CNPa.

The electrode layer E2L may be arranged on the intermediate layer ML. In an embodiment, the electrode layer E2L may have a single-layer structure. However, the disclosure is not limited thereto, and in another embodiment, the electrode layer E2L may have a multi-layer structure in which multiple conductive layers are stacked each other. For example, the electrode layer E2L may have a two-layer structure including a first sub-electrode layer including a metal and a second sub-electrode layer arranged on the first sub-electrode layer and including a transparent conductive oxide.

The shadow area where it is difficult to deposit the electrode layer E2L may exist around the separator SPR having the reverse tapered slope. In the shadow area and/or around the shadow area, the electrode layer E2L may be separated (or disconnected) by the separator SPR. For example, the electrode layer E2L may be separated (or disconnected) into the second electrode E2 of the first light emitting element LDa, the second electrode of the second light emitting element LDb, and the second electrode of the third light emitting element LDc. For example, the second electrode E2 of the first light emitting element LDa, the second electrode of the second light emitting element LDb, and the second electrode of the third light emitting element LDc may be electrically independent of each other.

As illustrated in FIG. 10, the electrode layer E2L (for example, the second electrode E2) may contact the first connection pattern CNPa. For example, the second electrode E2 may contact the first connection pattern CNPa at a position adjacent to or overlapping the separator SPR. In other words, the electrode layer E2L (for example, the second electrode E2) may contact the first connection pattern CNPa in an area overlapping the separator SPR in a plan view. For example, in case that a deposition angle of a deposition process for forming the electrode layer E2L is greater than a deposition angle of a deposition process for forming the intermediate layer ML, the electrode layer E2L (for example, the second electrode E2) may be formed to cover a side portion of the disconnected intermediate layer ML and to contact the first connection pattern CNPa. As a result, the second electrode E2 may be electrically connected to the auxiliary electrode AUE through the first connection pattern CNPa and the first auxiliary connection electrode CCEa. Accordingly, the second electrode E2 may receive the second power voltage (ELVSS, refer to FIG. 2) from the auxiliary electrode AUE.

The encapsulation layer ENC may be arranged on the electrode layer E2L. The encapsulation layer ENC may entirely cover the electrode layer E2L, the connection patterns CNPa, CNPb, and CNPc, the separator SPR, the first dummy layer DP1, and the second dummy layer DP2.

According to embodiments, the display device DD1-2 may include the auxiliary connection electrodes CCEa, CCEb, and CCEc, the connection patterns CNPa, CNPb, and CNPc, and the separator SPR. Accordingly, the electrode layer E2L (e.g., the cathode) may be readily electrically connected to the auxiliary electrode AUE through the auxiliary connection electrodes CCEa, CCEb, and CCEc and the connection patterns CNPa, CNPb, and CNPc. Accordingly, the electrode layer E2L may receive the second power voltage (ELVSS, refer to FIG. 2) from the auxiliary electrode AUE, and a voltage drop phenomenon of a voltage provided to the electrode layer E2L may be suppressed.

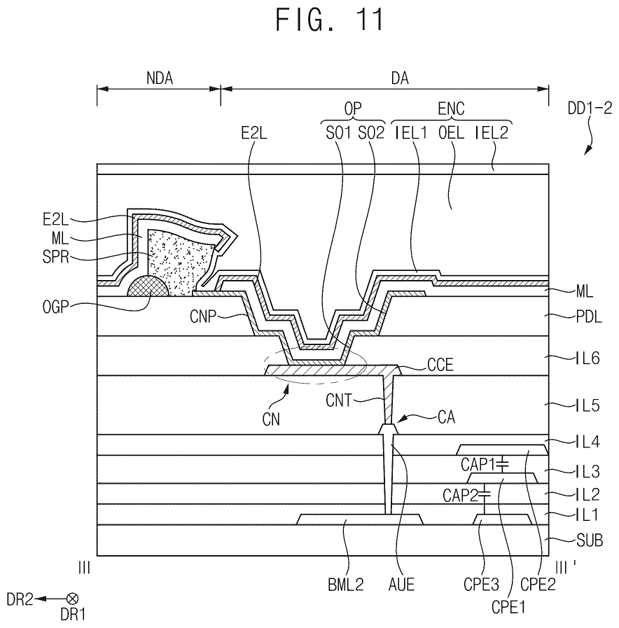

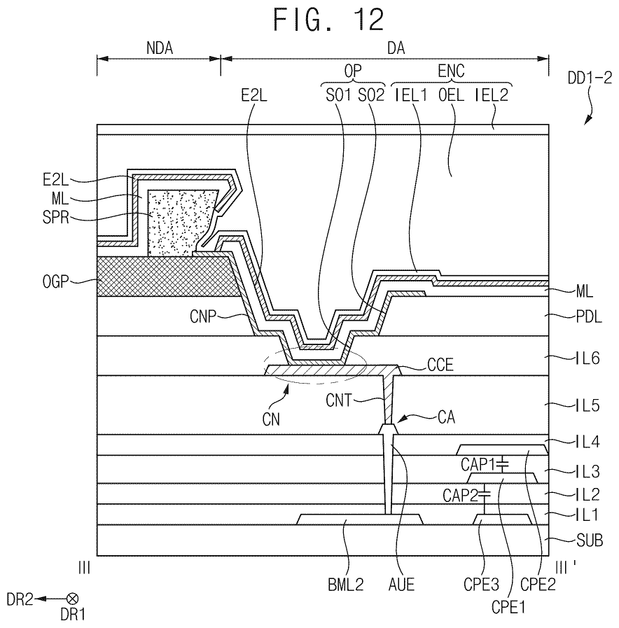

FIG. 11 is a schematic cross-sectional view taken along line III-III′ of FIG. 7 according to an embodiment. FIG. 12 is a schematic cross-sectional view taken along line III-III′ of FIG. 7 according to an embodiment.

Referring to FIGS. 11 and 12, the display device DD1-2 according to an embodiment of the disclosure may include the substrate SUB, the second bottom conductive layer BML2, the first capacitor CAP1, the second capacitor CAP2, the auxiliary electrode AUE, the auxiliary connection electrode CCE, the first to six insulating layers IL1, IL2, IL3, IL4, IL5, and IL6, the pixel defining layer PDL, the connection pattern CNP, the intermediate layer ML, the electrode layer E2L, the organic film pattern OGP, the separator SPR, and the encapsulation layer ENC.

The organic film pattern OGP may be arranged on the pixel defining layer PDL in the peripheral area NDA. For example, the organic film pattern OGP may be arranged between the pixel defining layer PDL and the separator SPR in the peripheral area NDA. In an embodiment, as illustrated in FIG. 11, an upper surface of the organic film pattern OGP may be a curved surface that is convex upwardly. However, the disclosure is not limited thereto, and in another embodiment, as illustrated in FIG. 12, the organic film pattern OGP may have a substantially flat upper surface. The organic film pattern OGP may include an organic material.

The connection pattern CNP may be arranged on the pixel defining layer PDL in the peripheral area NDA. In an embodiment, as illustrated in FIG. 11, the connection pattern CNP may be spaced apart from the organic film pattern OGP in the peripheral area NDA and may contact an upper surface of the pixel defining layer PDL. However, the disclosure is not limited thereto, and in another embodiment, as illustrated in FIG. 12, the connection pattern CNP may be arranged on the organic film pattern OGP and may contact the upper surface of the organic film pattern OGP.

The separator SPR may be arranged on the pixel defining layer PDL. The separator SPR may contact the organic film pattern OGP and the connection pattern CNP in the peripheral area NDA. In an embodiment, as illustrated in FIG. 11, the organic film pattern OGP may overlap a portion of the separator SPR in a plan view in the peripheral area NDA. For example, the organic film pattern OGP may overlap a first side surface of the separator SPR in a plan view in the peripheral area NDA. In case that the upper surface of the organic film pattern OGP includes a curved surface that is convex upwardly, an upper surface of the separator SPR may include a curved surface that is convex upwardly. However, the disclosure is not limited thereto. In an embodiment, as illustrated in FIG. 12, the organic film pattern OGP may overlap an entirety of the separator SPR in a plan view in the peripheral area NDA. In case that the organic film pattern OGP has a substantially flat upper surface, the separator SPR may have a substantially flat upper surface.

In an embodiment, as illustrated in FIGS. 11 and 12, the cross-sectional shape of a portion of the separator SPR may be asymmetrical in the peripheral area NDA. For example, a first side surface of the portion of the separator SPR may contact the organic film pattern OGP in the peripheral area NDA, and a second side surface opposite to the first side surface may contact the connection pattern CNP. Thus, in the process of forming the separator SPR, a difference in the degree of inclination of the first side surface and the second side surface may be caused due to a difference in the characteristics between the organic film pattern OGP and the connection pattern CNP.

The second side surface of the separator SPR may have a reverse tapered slope. For example, the second side surface of the separator SPR may have multiple reverse tapered slopes. As the second side surface of the separator SPR has the reverse tapered slopes, the intermediate layer ML and the electrode layer E2L may be separated (or disconnected) in the display area DA.

In contrast, the first side surface of the separator SPR may not have a reversed tapered slope.

As illustrated in FIG. 11, by forming the organic film pattern OGP that overlaps the first side surface of the separator SPR in a plan view in the peripheral area NDA, the first side surface of the separator SPR may not have a reverse tapered slope.

As illustrated in FIG. 12, in case that the first side surface of the separator SPR contacts the organic film pattern OGP having a substantially flat upper surface, the first side surface of the separator SPR may not have a reverse tapered slope. The organic film pattern OGP and the pixel defining layer PDL may include different materials. For example, the organic film pattern OGP may include a polystyrene-based resin and/or a polyimide-based resin. However, the disclosure is not limited thereto.

As the first side surface of the separator SPR does not have a reverse tapered slope, the intermediate layer ML and the electrode layer E2L may be formed to extend without being disconnected in the peripheral area NDA.

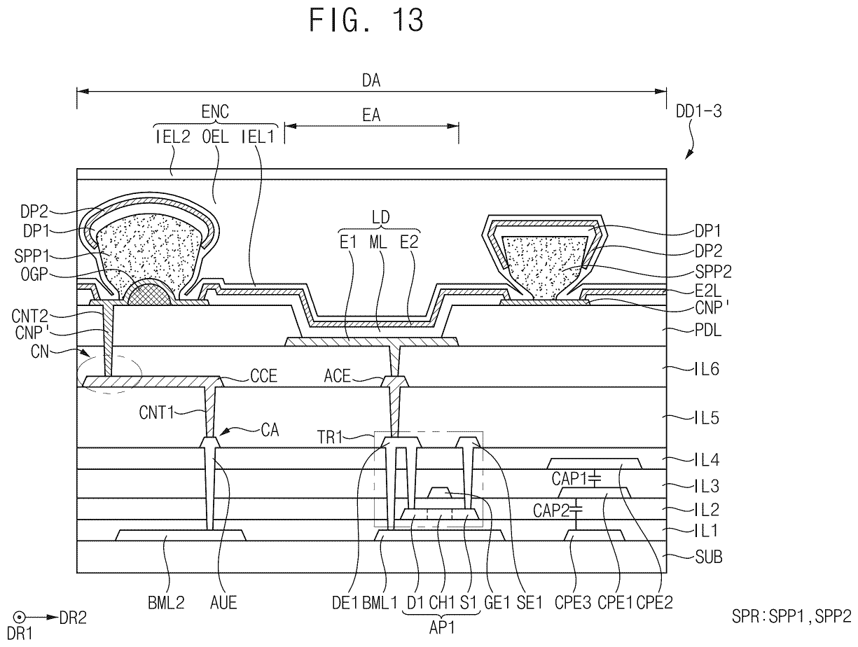

FIG. 13 is a schematic cross-sectional view illustrating a display device according to an embodiment of the disclosure. For example, FIG. 13 schematically illustrates the cross-sectional structure of a display device DD1-3 focusing on one emission area EA included in the display area DA. The following description of the cross-sectional structure of the display device DD1-3 may be substantially equally applied to all emission areas.

Referring to FIG. 13, the display device DD1-3 according to an embodiment of the disclosure may include a substrate SUB, a first bottom conductive layer BML1, a second bottom conductive layer BML2, a first transistor TR1, a first capacitor CAP1, a second capacitor CAP2, an auxiliary electrode AUE, an anode connection electrode ACE, an auxiliary connection electrode CCE, first to six insulating layers IL1, IL2, IL3, IL4, IL5, and IL6, a pixel defining layer PDL, a light emitting element LD, an organic film pattern OGP, a connection pattern CNP′, a separator SPR, a first dummy layer DP1, a second dummy layer DP2, and an encapsulation layer ENC. The light emitting element LD may include a first electrode E1, an intermediate layer ML, and a second electrode E2.

Compared to the display device DD1-2 described above with reference to FIGS. 7 to 12, the display device DD1-3 may include the connection pattern CNP′ that contacts the auxiliary connection electrode CCE in an area overlapping the separator SPR in a plan view. In other words, a light emitting connection portion CN of the auxiliary connection electrode CCE that contacts the connection pattern CNP′ may overlap the separator SPR in a plan view. Hereinafter, redundant descriptions of the display device DD1-2 described above with reference to FIGS. 7 to 12 may be omitted or may be summarized.

The auxiliary electrode AUE may be arranged on the fourth insulating layer IL4. The auxiliary electrode AUE may contact the second bottom conductive layer BML2. The auxiliary electrode AUE may be spaced apart from the first electrode E1. The second power voltage (ELVSS, refer to FIG. 2) may be applied to the auxiliary electrode AUE.

The auxiliary connection electrode CCE may be arranged on the fifth insulating layer IL5. The auxiliary connection electrode CCE may be connected to the auxiliary electrode AUE. For example, the auxiliary connection electrode CCE may contact the auxiliary electrode AUE through a first contact hole CNT1 that penetrates the fifth insulating layer IL5. Accordingly, a position of an auxiliary electrode connection portion CA may correspond to a position of the first contact hole CNT1. In an embodiment, the auxiliary connection electrode CCE may have a single-layer structure or a multi-layer structure in which multiple conductive layers are stacked each other.

The sixth insulating layer IL6 may cover the anode connection electrode ACE and the auxiliary connection electrode CCE, and may be arranged on the fifth insulating layer IL5.

The pixel defining layer PDL may be arranged on the sixth insulating layer IL6 and the first electrode E1. The pixel defining layer PDL may define a pixel opening that exposes at least a portion of the first electrode E1. The emission area EA may be defined by the pixel opening.

The organic film pattern OGP may be arranged on the pixel defining layer PDL in the display area DA. For example, the organic film pattern OGP may be arranged between the pixel defining layer PDL and the separator SPR in the display area DA. In an embodiment, an upper surface of the organic film pattern OGP may be a curved surface that is convex upwardly. In an embodiment, the organic film pattern OGP and the pixel defining layer PDL may include different materials.

The connection pattern CNP′ may be arranged on the pixel defining layer PDL. The connection pattern CNP′ may be connected to the auxiliary connection electrode CCE. For example, the connection pattern CNP′ may be connected to the auxiliary connection electrode CCE through a second contact hole CNT2 that penetrates the sixth insulating layer IL6 and the pixel defining layer PDL. Accordingly, a position of the light emitting connection portion CN may correspond to a position of the second contact hole CNT2.

In an embodiment, the connection pattern CNP′ may include a transparent conductive oxide. However, the disclosure is not limited thereto, and in another embodiment, the connection pattern CNP′ may include a conductive material such as a metal, an alloy, a conductive metal oxide, a conductive metal nitride, or the like.

In an embodiment, the connection pattern CNP′ may be arranged along the profiles of the pixel defining layer PDL and the organic film pattern OGP, and the connection pattern CNP′ may cover the organic film pattern OGP. However, the disclosure is not limited thereto.

In an embodiment, the organic film pattern OGP may be arranged on the connection pattern CNP′. A first portion SPP1 of the separator SPR may contact the organic film pattern OGP and may cover the organic film pattern OGP. A first side surface and a second side surface opposite to the first side surface of the first portion SPP1 of the separator SPR may contact the connection pattern CNP′.

The separator SPR may be arranged on the pixel defining layer PDL and the connection pattern CNP′. The separator SPR may overlap the connection pattern CNP′ in a plan view. For example, the separator SPR may cover a portion of the connection pattern CNP′.

A side surface of the separator SPR connecting an upper surface of the separator SPR and a lower surface of the separator SPR may have a reverse tapered slope. In an embodiment, as illustrated in FIG. 13, the side surface of the separator SPR may have multiple reverse tapered slopes. For example, the separator SPR may have a double reverse tapered structure. Accordingly, separation (or disconnection) of the electrode layer E2L by the separator SPR may be more readily implemented.

The separator SPR may include the first portion SPP1 and a second portion SPP2 spaced apart from the first portion SPP1. The first portion SPP1 of the separator SPR may overlap the organic film pattern OGP in a plan view, and the second portion SPP2 of the separator SPR may be spaced apart from the organic film pattern OGP in a plan view. In other words, the second portion SPP2 of the separator SPR may not overlap the organic film pattern OGP in a plan view. In an embodiment, the first portion SPP1 of the separator SPR may cover a portion of the connection pattern CNP′, and the first side surface and the second side surface opposite to the first side surface of the first portion SPP1 of the separator SPR may contact the connection pattern CNP′.

As the organic film pattern OGP is arranged between the pixel defining layer PDL and the first portion SPP1 of the separator SPR, an upper surface of the first portion SPP1 of the separator SPR may be a curved surface that is convex upwardly. In an embodiment, a level of the upper surface of the first portion SPP1 of the separator SPR may be higher than a level of an upper surface of the second portion SPP2 of the separator SPR. Accordingly, a mask used in the process of forming the intermediate layer ML may contact the first portion SPP1 of the separator SPR and may not contact the second portion SPP2 of the separator SPR. As a result, the phenomenon of being stamped by the mask, which may occur in case that an area of the separator SPR contacting the mask is large, may be suppressed.

In an embodiment, the connection pattern CNP′ may contact the auxiliary connection electrode CCE in an area overlapping the separator SPR in a plan view. In other words, the light emitting connection portion CN may overlap the separator SPR in a plan view. In the display device DD1-2 described above with reference to FIG. 10, the first light emitting connection portion CNa is spaced apart from the separator SPR in a plan view, whereas in the display device DD1-3 described with reference to FIG. 13, the light emitting connection portion CN may overlap the separator SPR in a plan view. For example, an area for contacting the auxiliary connection electrode CCE and the connection pattern CNP′ may not be required. Accordingly, the constraints on the design of the emission area EA due to the connection pattern CNP′ may be reduced. As a result, the degree of freedom in the design of the emission area EA may be improved, and a size of the emission area EA (i.e., an aperture ratio) may be further increased.

The electrode layer E2L may be arranged on the intermediate layer ML. A shadow area where it is difficult to deposit the electrode layer E2L may exist around the separator SPR having the reverse tapered slope. In the shadow area and/or around the shadow area, the electrode layer E2L may be separated (or disconnected) by the separator SPR.

The electrode layer E2L (for example, the second electrode E2) may contact the connection pattern CNP′. For example, the electrode layer E2L (for example, the second electrode E2) may contact the connection pattern CNP′ at a position adjacent to or overlapping the separator SPR. In other words, the electrode layer E2L (for example, the second electrode E2) may contact the connection pattern CNP′ in an area overlapping the separator SPR in a plan view. The electrode layer E2L (for example, the second electrode E2) may be formed to cover a side portion of the disconnected intermediate layer ML and to contact the connection pattern CNP′. As a result, the second electrode E2 may be electrically connected to the auxiliary electrode AUE through the connection pattern CNP′ and the auxiliary connection electrode CCE. Accordingly, the second electrode E2 may receive the second power voltage (ELVSS, refer to FIG. 2) from the auxiliary electrode AUE.

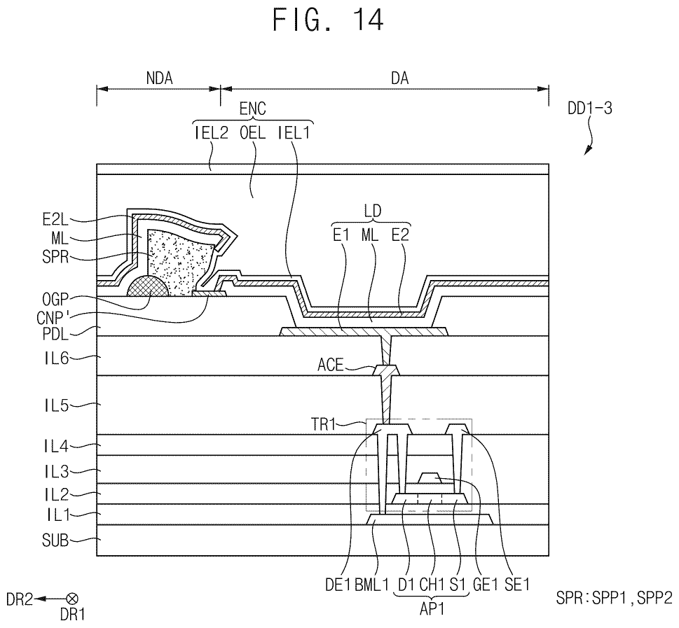

FIG. 14 is a schematic cross-sectional view illustrating the display device of FIG. 13. For example, FIG. 14 schematically illustrates the cross-sectional structure of the display device DD1-3 in the peripheral area NDA adjacent to the display area DA.

Referring to FIG. 14, the display device DD1-3 according to an embodiment of the disclosure may include the substrate SUB, the first bottom conductive layer BML1, the first transistor TR1, the anode connection electrode ACE, the first to six insulating layers IL1, IL2, IL3, IL4, IL5, and IL6, the pixel defining layer PDL, the light emitting element LD, the connection pattern CNP′, the electrode layer E2L, the organic film pattern OGP, the separator SPR, and the encapsulation layer ENC. The electrode layer E2L may include a second electrode E2. The light emitting element LD may include a first electrode E1, an intermediate layer ML, and the second electrode E2.

The cross-sectional structure in the peripheral area NDA of the display device DD1-3 may be substantially the same as the cross-sectional structure in the peripheral area NDA of the display device DD1-2 described above with reference to FIGS. 11 and 12.

In an embodiment, as illustrated in FIGS. 11 and 14, the organic film pattern OGP may be arranged between the pixel defining layer PDL and the separator SPR in the peripheral area NDA, and an upper surface of the organic film pattern OGP may be a curved surface that is convex upwardly. The connection pattern CNP′ may be spaced apart from the organic film pattern OGP in the peripheral area NDA and may contact an upper surface of the pixel defining layer PDL. The separator SPR may be arranged on the pixel defining layer PDL in the peripheral area NDA, and the organic film pattern OGP may overlap a portion of the separator SPR in a plan view. For example, the organic film pattern OGP may overlap a first side surface of the separator SPR in a plan view in the peripheral area NDA. As the upper surface of the organic film pattern OGP is the curved surface that is convex upwardly, an upper surface of the separator SPR may be a curved surface that is convex upwardly. However, the disclosure is not limited thereto.

In an embodiment, as illustrated in FIG. 12, the organic film pattern OGP may have a substantially flat upper surface in the peripheral area NDA. The connection pattern CNP′ may be arranged on the organic film pattern OGP and may contact the upper surface of the organic film pattern OGP. The separator SPR may be arranged on the pixel defining layer PDL in the peripheral area NDA, and the organic film pattern OGP may overlap an entirety of the separator SPR in a plan view. As the organic film pattern OGP has the substantially flat upper surface, the separator SPR may have a substantially flat upper surface.

The cross-sectional shape of a portion of the separator SPR may be asymmetrical in the peripheral area NDA. For example, a first side surface of the portion of the separator SPR may contact the organic film pattern OGP in the peripheral area NDA, and a second side surface opposite to the first side surface may contact the connection pattern CNP′. Thus, in the process of forming the separator SPR, a difference in the degree of inclination of the first side surface and the second side surface may be caused due to a difference in the characteristics between the organic film pattern OGP and the connection pattern CNP′.

The second side surface of the separator SPR may have a reverse tapered slope. For example, the second side surface of the separator SPR may have multiple reverse tapered slopes. As the second side surface of the separator SPR has the reverse tapered slopes, the intermediate layer ML and the electrode layer E2L may be separated (or disconnected) in the display area DA.

In contrast, the first side surface of the separator SPR may not have a reversed tapered slope. As the first side surface of the separator SPR does not have a reverse tapered slope, the intermediate layer ML and the electrode layer E2L may be formed to extend without being disconnected in the peripheral area NDA.

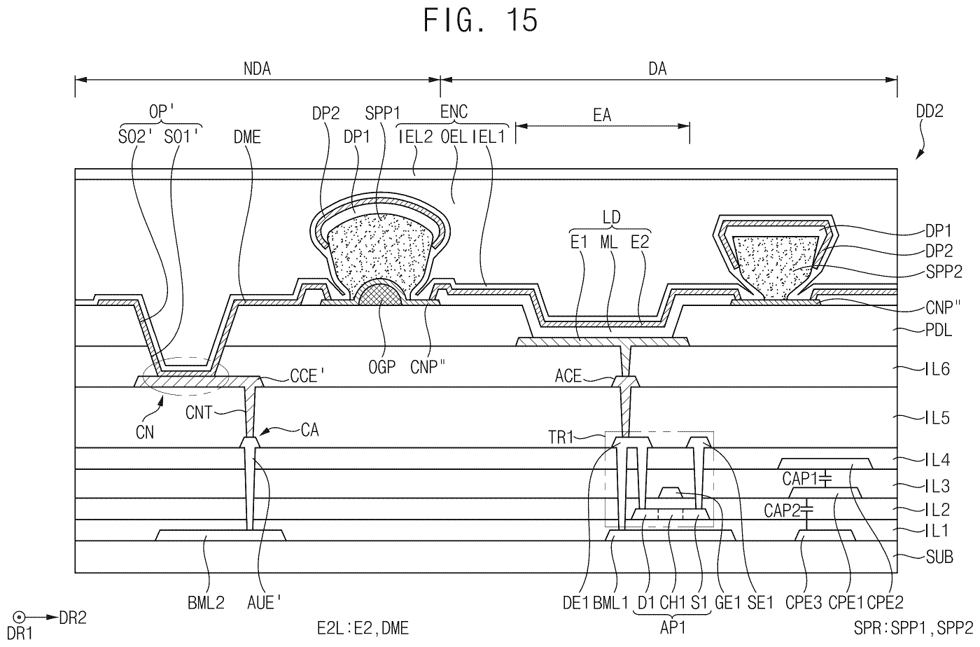

FIG. 15 is a schematic cross-sectional view illustrating a display device according to an embodiment of the disclosure. For example, FIG. 15 schematically illustrates the cross-sectional structure of a display device DD2 focusing on the peripheral area NDA adjacent to the display area DA.

Referring to FIG. 15, the display device DD2 according to an embodiment of the disclosure may include a substrate SUB, a first bottom conductive layer BML1, a second bottom conductive layer BML2, a first transistor TR1, a first capacitor CAP1, a second capacitor CAP2, an auxiliary electrode AUE′, an anode connection electrode ACE, an auxiliary connection electrode CCE′, first to six insulating layers IL1, IL2, IL3, IL4, IL5, and IL6, a pixel defining layer PDL, a light emitting element LD, an organic film pattern OGP, a connection pattern CNP″, a separator SPR, a first dummy layer DP1, an electrode layer E2L, a second dummy layer DP2, and an encapsulation layer ENC. The electrode layer E2L may include a second electrode E2 and a dummy electrode DME spaced apart from the second electrode E2. The light emitting element LD may include a first electrode E1, an intermediate layer ML, and the second electrode E2.

Unlike the display device DD1-2 described above with reference to FIGS. 7 to 10, the display device DD2 may include the auxiliary electrode AUE′ and the auxiliary connection electrode CCE′ arranged in the peripheral area NDA, and may further include the dummy electrode DME that contacts the auxiliary connection electrode CCE′ in the peripheral area NDA. Hereinafter, redundant descriptions of the display device DD1-2 described above with reference to FIGS. 7 to 10 may be omitted or may be summarized.

The auxiliary electrode AUE′ may be arranged on the substrate SUB in the peripheral area NDA. For example, the auxiliary electrode AUE′ may arranged on the fourth insulating layer IL4 in the peripheral area NDA. The auxiliary electrode AUE′ may contact the second bottom conductive layer BML2. The auxiliary electrode AUE′ may be spaced apart from the first electrode E1. The second power voltage (ELVSS, refer to FIG. 2) may be applied to the auxiliary electrode AUE′.

The auxiliary connection electrode CCE′ may be arranged on the auxiliary electrode AUE′. For example, the auxiliary connection electrode CCE′ may be arranged on the fifth insulating layer IL5 in the peripheral area NDA. The auxiliary connection electrode CCE′ may be electrically connected to the auxiliary electrode AUE′. For example, the auxiliary connection electrode CCE′ may contact the auxiliary electrode AUE′ through a contact hole CNT that penetrates the fifth insulating layer IL5. Accordingly, a position of an auxiliary electrode connection portion CA may correspond to a position of the contact hole CNT. In an embodiment, the auxiliary connection electrode CCE′ may have a single-layer structure or a multi-layer structure in which multiple conductive layers are stacked each other.

The sixth insulating layer IL6 may partially cover the auxiliary connection electrode CCE′ and may be arranged on the fifth insulating layer IL5. The sixth insulating layer IL6 may define a first sub-opening SO1′ that exposes at least a portion of the auxiliary connection electrode CCE′.

The pixel defining layer PDL may be arranged on the substrate SUB and may define a pixel opening that exposes the first electrode E1. For example, the pixel defining layer PDL may be arranged on the sixth insulating layer IL6 and the first electrode E1, and may define the pixel opening that exposes at least a portion of the first electrode E1. The emission area EA may be defined by the pixel opening.

The pixel defining layer PDL may further define a second sub-opening SO2′ corresponding to the first sub-opening SO1′ of the sixth insulating layer IL6. The second sub-opening SO2′ may overlap the first sub-opening SO1′ in a plan view, and the first sub-opening SO1′ and the second sub-opening SO2′ may be spatially connected to each other. For example, the first sub-opening SO1′ and the second sub-opening SO2′ may be connected to define a sub-opening OP′. The sub-opening OP′ may expose at least a portion of the auxiliary connection electrode CCE′ in the peripheral area NDA.

The organic film pattern OGP may be arranged on the pixel defining layer PDL in the peripheral area NDA. Although not illustrated, the organic film pattern OGP may be arranged on the pixel defining layer PDL in the display area DA. The organic film pattern OGP may be arranged between the pixel defining layer PDL and the separator SPR. In an embodiment, an upper surface of the organic film pattern OGP may be a curved surface that is convex upwardly. The organic film pattern OGP may include an organic material.

The connection pattern CNP′ may be arranged on the pixel defining layer PDL. For example, the connection pattern CNP′ may be arranged between the pixel defining layer PDL and the separator SPR. The connection pattern CNP′ may be electrically connected to the auxiliary connection electrode CCE′ through the dummy electrode DME described below. In an embodiment, the connection pattern CNP′ may be arranged along the profiles of the pixel defining layer PDL and the organic film pattern OGP, and the connection pattern CNP′ may cover the organic film pattern OGP. However, the disclosure is not limited thereto. In an embodiment, the organic film pattern OGP may be arranged on the connection pattern CNP′. A first portion SPP1 of the separator SPR may contact the organic film pattern OGP and may cover the organic film pattern OGP. A first side surface and a second side surface opposite to the first side surface of the first portion SPP1 of the separator SPR may contact the connection pattern CNP′.

The separator SPR may be arranged on the pixel defining layer PDL and the connection pattern CNP″. The separator SPR may overlap the connection pattern CNP′ in a plan view. For example, the separator SPR may cover a portion of the connection pattern CNP′.

A side surface of the separator SPR connecting an upper surface of the separator SPR and a lower surface of the separator SPR may have a reverse tapered slope. In other words, a cross-section of at least a portion of the separator SPR may be an inverted trapezoid. In an embodiment, as illustrated in FIG. 15, the side surface of the separator SPR may have multiple reverse tapered slopes.

In an embodiment, as illustrated in FIG. 15, the cross-sectional shape of the separator SPR may be symmetrical in the peripheral area NDA. For example, both the first side surface and the second side surface opposite to the first side surface of the separator SPR may contact the connection pattern CNP′ in the peripheral area NDA. Both the first side surface and the second side surface of the separator SPR may have multiple reverse tapered slopes. As the first side surface and the second side surface of the separator SPR have multiple reverse tapered slopes, the intermediate layer ML and the electrode layer E2L may be separated (or disconnected) in the display area DA and in the peripheral area NDA.

The separator SPR may include the first portion SPP1 and a second portion SPP2 spaced apart from the first portion SPP1. The first portion SPP1 of the separator SPR may overlap the organic film pattern OGP in a plan view, and the second portion SPP2 of the separator SPR may be spaced apart from the organic film pattern OGP in a plan view. In other words, the second portion SPP2 of the separator SPR may not overlap the organic film pattern OGP in a plan view. In an embodiment, the first portion SPP1 of the separator SPR may cover a portion of the connection pattern CNP″, and the first side surface and the second side surface opposite to the first side surface of the first portion SPP1 of the separator SPR may contact the connection pattern CNP′.

As the organic film pattern OGP is arranged between the pixel defining layer PDL and the first portion SPP1 of the separator SPR, an upper surface of the first portion SPP1 of the separator SPR may be a curved surface that is convex upwardly. In an embodiment, a level of the upper surface of the first portion SPP1 of the separator SPR may be higher than a level of an upper surface of the second portion SPP2 of the separator SPR. Accordingly, a mask used in the process of forming the intermediate layer ML may contact the first portion SPP1 of the separator SPR and may not contact the second portion SPP2 of the separator SPR. As a result, the phenomenon of being stamped by the mask, which may occur in case that an area of the separator SPR contacting the mask is large, may be suppressed.

The intermediate layer ML may be arranged on the first electrode E1, the pixel defining layer PDL, and the connection pattern CNP″. A portion of the intermediate layer ML may be arranged in the pixel opening of the pixel defining layer PDL.

A shadow area where it is difficult to deposit the intermediate layer ML may exist around the separator SPR having the reverse tapered slope. Accordingly, in the shadow area and/or around the shadow area, the intermediate layer ML may be separated (or disconnected) by the separator SPR. As the intermediate layer ML is separated (or disconnected), the intermediate layer ML may expose a portion of the connection pattern CNP′ at a position adjacent to or overlapping the separator SPR. Accordingly, the second electrode E2 of the light emitting element LD and the dummy electrode DME may contact the connection pattern CNP′.

The electrode layer E2L may be arranged on the auxiliary connection electrode CCE′, the pixel defining layer PDL, and the intermediate layer ML. In an embodiment, the electrode layer E2L may have a single-layer structure. However, the disclosure is not limited thereto, and in another embodiment, the electrode layer E2L may have a multi-layer structure in which multiple conductive layers are stacked each other. For example, the electrode layer E2L may have a two-layer structure including a first sub-electrode layer including a metal and a second sub-electrode layer arranged on the first sub-electrode layer and including a transparent conductive oxide.

The shadow area where it is difficult to deposit the electrode layer E2L may exist around the separator SPR having the reverse tapered slope. In the shadow area and/or around the shadow area, the electrode layer E2L may be separated (or disconnected) by the separator SPR. For example, the electrode layer E2L may be separated (or disconnected) into the second electrode E2 arranged in the display area DA and the dummy electrode DME arranged in the peripheral area NDA.

The dummy electrode DME may be connected to the auxiliary connection electrode CCE′. For example, the dummy electrode DME may contact the auxiliary connection electrode CCE′ in the peripheral area NDA. Accordingly, the dummy electrode DME may be electrically connected to the auxiliary electrode AUE′ through the auxiliary connection electrode CCE′.

As illustrated in FIG. 15, the second electrode E2 may contact the connection pattern CNP″. For example, the second electrode E2 may contact the connection pattern CNP′ at a position adjacent to or overlapping a first side surface of the separator SPR that is adjacent to the display area DA. In other words, the second electrode E2 may contact the connection pattern CNP′ in an area overlapping the first side surface of the separator SPR in a plan view.

The dummy electrode DME may be connected to the connection pattern CNP′. For example, the dummy electrode DME may contact the connection pattern CNP′ at a positioned adjacent to or overlapping a second side surface opposite to the first side surface of the separator SPR. In other words, the dummy electrode DME may contact the connection pattern CNP′ in an area overlapping the second side surface of the separator SPR in a plan view.

For example, in case that a deposition angle of a deposition process for forming the electrode layer E2L is greater than a deposition angle of a deposition process for forming the intermediate layer ML, the second electrode E2 and the dummy electrode DME may be formed to cover a side portion of the disconnected intermediate layer ML and to contact the connection pattern CNP″. As a result, the second electrode E2 may be electrically connected to the auxiliary electrode AUE′ through the connection pattern CNP″, the dummy electrode DME, and the auxiliary connection electrode CCE′. Accordingly, the second electrode E2 may receive the second power voltage (ELVSS, refer to FIG. 2) from the auxiliary electrode AUE′.

According to embodiments, in the display device DD2, the second electrode E2 (e.g., a cathode) may be readily electrically connected to the auxiliary electrode AUE′ arranged in the peripheral area NDA through the connection pattern CNP″, the dummy electrode DME, and the auxiliary connection electrode CCE′. For example, the auxiliary electrode AUE′ and the auxiliary connection electrode CCE′ for providing the second power voltage may not be arranged in the display area DA. As a result, the degree of freedom in the design of the display area DA (for example, the emission area EA) may be improved, and a size of the emission area EA (i.e., an aperture ratio) may be further increased.

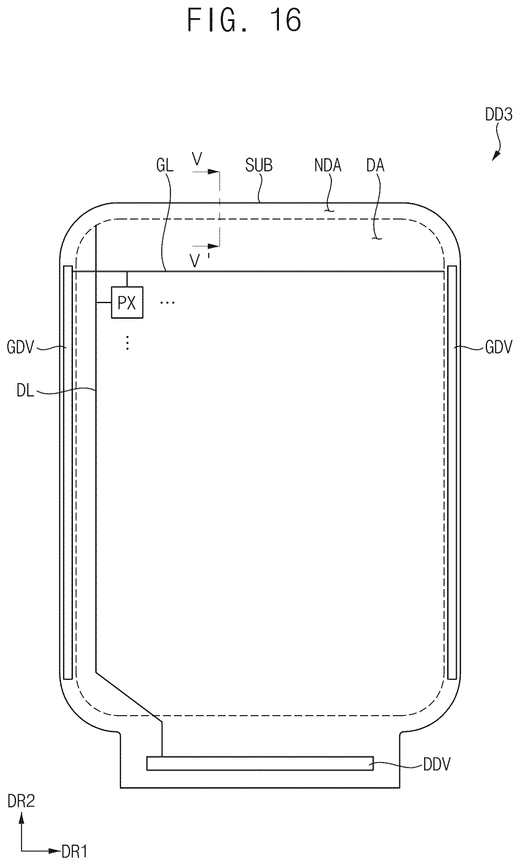

FIG. 16 is a plan view illustrating a display device according to an embodiment of the disclosure.

Referring to FIG. 16, a display device DD3 may be a device activated according to an electrical signal. For example, as illustrated in FIG. 16, the display device DD3 may be a small-sized display device used in a small-sized electronic device such as a smart phone, a mobile phone, a smart watch, a game console, a camera, or the like. However, the disclosure is not limited thereto, and in another embodiment, the display device DD3 may be a medium and large-sized display device used in medium and large-sized electronic devices such as a laptop, a tablet PC, a television, a computer monitor, a vehicle monitor, an external billboard, or the like. Hereinafter, redundant descriptions of the display device DD1 (or DD1a) described above with reference to FIGS. 1A and 1B may be omitted or may be summarized.

The display device DD3 may include a display area DA and a peripheral area NDA. The display area DA may be an area that displays an image by generating light or controlling a transmittance of light provided from an external light source. The peripheral area NDA may be located adjacent to the display area DA. For example, the peripheral area NDA may surround at least a portion of the display area DA. In an embodiment, the peripheral area NDA may be an area that does not display an image.

The display device DD3 may include a substrate SUB, pixels PX, gate lines GL, data lines DL, a data driver DDV, and a gate driver GDV.

The pixels PX may be arranged in the display area DA on the substrate SUB. The pixels PX may be electrically connected to the gate lines GL and the data lines DL. For example, the pixels PX may be arranged in a matrix form in the first direction DR1 and the second direction DR2. Each of the pixels PX may include a pixel driving circuit and a light emitting element.

The data driver DDV may be arranged in the peripheral area NDA on the substrate SUB. The data driver DDV may generate a data voltage. The data driver DDV may output the data voltage to the data lines DL. The data voltage may be applied to the pixels PX through the data lines DL.

The gate driver GDV may be arranged in the peripheral area NDA on the substrate SUB. The gate driver GDV may generate a gate signal. The gate driver GDV may output the gate signal to the gate lines GL. The gate signal may be applied to the pixels PX through the gate lines GL.

In an embodiment, although not illustrated, an emission driver generating an emission control signal may be further arranged in the peripheral area NDA. The emission control signal may be applied to the pixels PX through emission control lines.

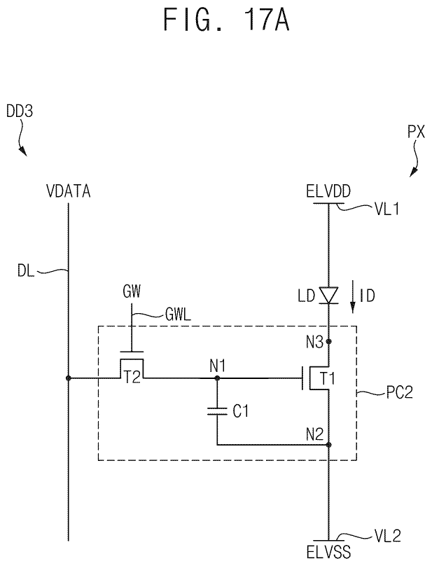

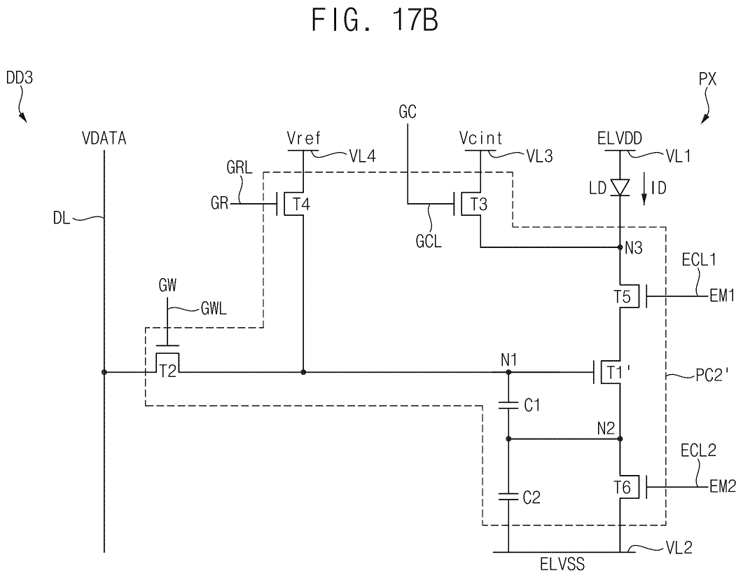

FIG. 17A is a schematic diagram illustrating an embodiment of a circuit structure of a pixel included in the display device of FIG. 16.

Referring to FIG. 17A, in an embodiment, the pixel PX may include a light emitting element LD and a pixel driving circuit PC2 connected to the light emitting element LD. In an embodiment, the pixel driving circuit PC2 may include a first transistor T1, a second transistor T2, and a first capacitor C1. In FIG. 17A, both the first transistor T1 and the second transistor T2 are illustrated as n-type transistors. However, the disclosure is not limited thereto, and some of the first transistor T1 and the second transistor T2 may be an n-type transistor, and others may be a p-type transistor. For example, the first transistor T1 may be an n-type transistor, and the second transistor T2 may be a p-type transistor.

In case that the pixel PX includes an n-type transistor and a p-type transistor, an active pattern of the n-type transistor may include an oxide semiconductor material, and an active pattern of the p-type transistor may include a silicon semiconductor material. However, the disclosure is not limited thereto, and in another embodiment, both the active pattern of the n-type transistor and the active pattern of the p-type transistor may include a silicon semiconductor material.

The pixel driving circuit PC2 may be connected to a first gate line GWL, the data line DL, a first voltage line VL1, and a second voltage line VL2. The first gate line GWL may transfer a first gate signal GW. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level.

The first transistor T1 may include a gate terminal, a first terminal, and a second terminal. In an embodiment, the first terminal of the first transistor T1 may be a source, and the second terminal of the first transistor T1 may be a drain. The gate terminal of the first transistor T1 may be connected to a first node N1. The first terminal of the first transistor T1 may be connected to a second node N2. The second terminal of the first transistor T1 may be connected to a third node N3. The second terminal of the first transistor T1 may be connected to the light emitting element LD. The first transistor T1 may control a driving current ID supplied to the light emitting element LD.

The second transistor T2 may include a gate terminal, a first terminal, and a second terminal. In an embodiment, the first terminal of the second transistor T2 may be a source, and the second terminal of the second transistor T2 may be a drain. However, the disclosure is not limited thereto, and in another embodiment, the first terminal of the second transistor T2 may be a drain, and the second terminal of the second transistor T2 may be a source. The gate terminal of the second transistor T2 may receive the first gate signal GW through the first gate line GWL. The first terminal of the second transistor T2 may receive the data voltage VDATA through the data line DL. The second terminal of the second transistor T2 may be connected to the first node N1.

The second transistor T2 may be turned on or off in response to the first gate signal GW. For example, in case that the second transistor T2 is an n-type transistor, the second transistor T2 may be turned off in case that the first gate signal GW has a negative voltage level, and the second transistor T2 may be turned on in case that the first gate signal GW has a positive voltage level. In case that the second transistor T2 is a p-type transistor, the second transistor T2 may be turned off in case that the first gate signal GW has a positive voltage level, and the second transistor T2 may be turned on in case that the first gate signal GW has a negative voltage level. While the second transistor T2 is turned on, the second terminal of the second transistor T2 may provide the data voltage VDATA to the first node N1. Accordingly, the second transistor T2 may drive the first transistor T1.

The first capacitor C1 may include a first terminal and a second terminal. The first terminal of the first capacitor C1 may be connected to the first node N1. The second terminal of the first capacitor C1 may be connected to the second node N2. Current may be charged in or discharged from the first capacitor C1 according to the data voltage VDATA transferred to the first node N1.

The light emitting element LD may include an anode and a cathode. The anode of the light emitting element LD may be connected to the first voltage line VL1. The cathode of the light emitting element LD may be connected to the third node N3. For example, the cathode of the light emitting element LD may be connected to the second terminal of the first transistor T1.

FIG. 17B is a schematic diagram illustrating another embodiment of a circuit structure of a pixel included in the display device of FIG. 16.

Compared to the embodiment of the circuit structure of the pixel PX described above with reference to FIG. 17A, a pixel driving circuit PC2′ according to an embodiment of the circuit structure of the pixel PX described below with reference to FIG. 17B may further include third to sixth transistors T3, T4, T5, and T6 and a second capacitor C2. Therefore, redundant descriptions of some components may be omitted or simplified.

Referring to FIG. 17B, in an embodiment, the pixel PX may include a light emitting element LD and a pixel driving circuit PC2′ connected to the light emitting element LD. In an embodiment, the pixel driving circuit PC2′ may include first to sixth transistors T1′, T2, T3, T4, T5, and T6, a first capacitor C1, and a second capacitor C2. In FIG. 17B, all of the first to sixth transistors T1′, T2, T3, T4, T5, and T6 are illustrated as n-type transistors. However, the disclosure is not limited thereto, and in another embodiment, some of the first to sixth transistors T1′, T2, T3, T4, T5, and T6 may be n-type transistors, and others may be p-type transistors. For example, the first transistor T1′ may be an n-type transistor, some of the second to sixth transistors T2, T3, T4, T5, and T6 may be n-type transistors, and others may be p-type transistors.

In case that the pixel PX includes an n-type transistor and a p-type transistor, an active pattern of the n-type transistor may include an oxide semiconductor material, and an active pattern of the p-type transistor may include a silicon semiconductor material. However, the disclosure is not limited thereto, and both the active pattern of the n-type transistor and the active pattern of the p-type transistor may include a silicon semiconductor material.

The pixel driving circuit PC2′ may be connected to first to third gate lines GWL, GCL, and GRL, the data line DL, first to fourth voltage lines VL1, VL2, VL3, and VL4, a first emission control line ECL1, and a second emission control line ECL2. The first gate line GWL may transfer a first gate signal GW. The second gate line GCL may transfer a second gate signal GC. The third gate line GRL may transfer a third gate signal GR. The data line DL may transfer a data voltage VDATA. The first voltage line VL1 may transfer a first power voltage ELVDD having a relatively high voltage level. The second voltage line VL2 may transfer a second power voltage ELVSS having a relatively low voltage level. The third voltage line VL3 may transfer a cathode initialization voltage Vcint. The fourth voltage line VL4 may transfer a reference voltage Vref. The reference voltage Vref may have a voltage level lower than a voltage level of the first power voltage ELVDD.

The first transistor T1′ of FIG. 17B may be substantially the same as the first transistor T1 described above with reference to FIG. 17A, except that the first terminal is connected to the second voltage line VL2 through the six transistor T6 and the second terminal is connected to the light emitting element LD through the fifth transistor T5. Therefore, redundant descriptions may be omitted or simplified. For example, the first transistor T1′ of the pixel driving circuit PC2′ may be connected to the light emitting element LD through the fifth transistor T5 and may control the driving current ID provided to the light emitting element LD through the fifth transistor T5.

The second transistor T2 of FIG. 17B may be substantially the same as the second transistor T2 described above with reference to FIG. 17A. Accordingly, the description of the second transistor T2 of FIG. 17A may be substantially equally applied to the second transistor T2 of FIG. 17B. For example, the second transistor T2 may drive the first transistor T1′ while the second transistor T2 is turned on.

The third transistor T3 may include a gate terminal, a first terminal, and a second terminal. In an embodiment, the first terminal of the third transistor T3 may be a source, and the second terminal of the third transistor T3 may be a drain. However, the disclosure is not limited thereto, and in another embodiment, the first terminal of the third transistor T3 may be a drain, and the second terminal of the third transistor T3 may be a source. The gate terminal of the third transistor T3 may receive the second gate signal GC through the second gate line GCL. The first terminal of the third transistor T3 may be connected to the third node N3. The second terminal of the third transistor T3 may receive the cathode initialization voltage Vcint through the third voltage line VL3.

The third transistor T3 may be turned on or off in response to the second gate signal GC. For example, in case that the third transistor T3 is an n-type transistor, the third transistor T3 may be turned off in case that the second gate signal GC has a negative voltage level, and the third transistor T3 may be turned on in case that the second gate signal GC has a positive voltage level. In case that the third transistor T3 is a p-type transistor, the third transistor T3 may be turned off in case that the second gate signal GC has a positive voltage level, and the third transistor T3 may be turned on in case that the second gate signal GC has a negative voltage level. While the third transistor T3 is turned on, the third transistor T3 may provide the cathode initialization voltage Vcint to the third node N3. For example, the third transistor T3 may provide the cathode initialization voltage Vcint to a cathode of the light emitting element LD to initialize a voltage of the cathode.

The fourth transistor T4 may include a gate terminal, a first terminal, and a second terminal. In an embodiment, the first terminal of the fourth transistor T4 may be a source, and the second terminal of the fourth transistor T4 may be a drain. However, the disclosure is not limited thereto, and in another embodiment, the first terminal of the fourth transistor T4 may be a drain, and the second terminal of the fourth transistor T4 may be a source. The gate terminal of the fourth transistor T4 may receive the third gate signal GR through the third gate line GRL. The first terminal of the fourth transistor T4 may be connected to the first node N1. The second terminal of the fourth transistor T4 may receive the reference voltage Vref through the fourth voltage line VL4.

The fourth transistor T4 may be turned on or off in response to the third gate signal GR. For example, in case that the fourth transistor T4 is an n-type transistor, the fourth transistor T4 may be turned off in case that the third gate signal GR has a negative voltage level, and the fourth transistor T4 may be turned on in case that the third gate signal GR has a positive voltage level. In case that the fourth transistor T4 is a p-type transistor, the fourth transistor T4 may be turned off in case that the third gate signal GR has a positive voltage level, and the fourth transistor T4 may be turned on in case that the third gate signal GR has a negative voltage level. While the fourth transistor T4 is turned on, the fourth transistor T4 may provide the reference voltage Vref to the first node N1.

The fifth transistor T5 may include a gate terminal, a first terminal, and a second terminal. In an embodiment, the first terminal of the fifth transistor T5 may be a source, and the second terminal of the fifth transistor T5 may be a drain. However, the disclosure is not limited thereto, and in another embodiment, the first terminal of the fifth transistor T5 may be a drain, and the second terminal of the fifth transistor T5 may be a source. The gate terminal of the fifth transistor T5 may receive the first emission control signal EM1 through the first emission control line ECL1. The first terminal of the fifth transistor T5 may be connected to the second terminal of the first transistor T1′. The second terminal of the fifth transistor T5 may be connected to the third node N3. The second terminal of the fifth transistor T5 may be connected to the light emitting element LD.

The fifth transistor T5 may be turned on or off in response to the first emission control signal EM1. For example, in case that the fifth transistor T5 is an n-type transistor, the fifth transistor T5 may be turned off in case that the first emission control signal EM1 has a negative voltage level, and the fifth transistor T5 may be turned on in case that the first emission control signal EM1 has a positive voltage level. In case that the fifth transistor T5 is a p-type transistor, the fifth transistor T5 may be turned off in case that the first emission control signal EM1 has a positive voltage level, and the fifth transistor T5 may be turned on in case that the first emission control signal EM1 has a negative voltage level. While the fifth transistor T5 is turned on, the fifth transistor T5 may electrically connect the first transistor T1′ and the light emitting element LD. For example, the fifth transistor T5 may electrically connect the second terminal of the first transistor T1′ and the cathode of the light emitting element LD in response to the first emission control signal EM1.

The sixth transistor T6 may include a gate terminal, a first terminal, and a second terminal. In an embodiment, the first terminal of the sixth transistor T6 may be a source, and the second terminal of the sixth transistor T6 may be a drain. However, the disclosure is not limited thereto, and in another embodiment, the first terminal of the sixth transistor T6 may be a drain, and the second terminal of the sixth transistor T6 may be a source. The gate terminal of the sixth transistor T6 may receive the second emission control signal EM2 through the second emission control line ECL2. The first terminal of the sixth transistor T6 may receive the second power voltage ELVSS through the second voltage line VL2. The second terminal of the sixth transistor T6 may be connected to the second node N2.

The sixth transistor T6 may be turned on or off in response to the second emission control signal EM2. For example, in case that the sixth transistor T6 is an n-type transistor, the sixth transistor T6 may be turned off in case that the second emission control signal EM2 has a negative voltage level, and the sixth transistor T6 may be turned on in case that the second emission control signal EM2 has a positive voltage level. In case that the sixth transistor T6 is a p-type transistor, the sixth transistor T6 may be turned off in case that the second emission control signal EM2 has a positive voltage level, and the sixth transistor T6 may be turned on in case that the second emission control signal EM2 has a negative voltage level. While the sixth transistor T6 is turned on, the sixth transistor T6 may provide the second power voltage ELVSS to the second node N2.

Although FIG. 17B illustrates that the fifth transistor T5 and the sixth transistor T6 are independently driven by different emission control signals, the disclosure is not limited thereto. In another embodiment, the first emission control signal EM1 and the second emission control signal EM2 may be provided as a substantially single emission control signal, the fifth transistor T5 and the sixth transistor T6 may be simultaneously turned on or off, and the first emission control line ECL1 and the second emission control line ECL2 may be provided as a substantially single emission control line.

The first capacitor C1 of FIG. 17B may be substantially the same as the first capacitor C1 described above with reference to FIG. 17A. Accordingly, the description of the first capacitor C1 of FIG. 17A may be substantially equally applied to the first capacitor C1 of FIG. 17B. For example, current may be charged in or discharged from the first capacitor C1 according to the data voltage VDATA transferred to the first node N1.

The second capacitor C2 may include a first terminal and a second terminal. The first terminal of the second capacitor C2 may be connected to the second node N2. The second terminal of the second capacitor C2 may be connected to the second voltage line VL2. For example, the second capacitor C2 may be connected in series to the first capacitor C1. The data voltage VDATA may be transferred to the first node N1 and may be voltage-divided due to the serial connection between the first capacitor C1 and the second capacitor C2 so that the divided data voltage VDATA may be transferred to the second node N2. Since the first transistor T1′ generates the driving current ID based on a voltage of the first node N1 and a voltage of the second node N2, a data range may be extended.

The light emitting element LD of FIG. 17B may be substantially the same as the light emitting element LD described above with reference to FIG. 17A, except that the cathode is connected to the first terminal of the third transistor T3 and is connected to the second terminal of the first transistor T1′ through the fifth transistor T5. Therefore, redundant descriptions may be omitted or simplified. For example, the cathode of the light emitting element LD may be connected to the second terminal of the first transistor T1′ through the fifth transistor T5. The cathode of the light emitting element LD may receive the cathode initialization voltage Vcint through the third transistor T3.

As illustrated in FIGS. 17A and 17B, according to embodiments, the anode of the light emitting element LD may receive the first power voltage ELVDD through the first voltage line VL1, and the cathode of the light emitting element LD may be connected to the second terminal of the first transistor T1 (or T1′). For example, a potential of the cathode of the light emitting element LD may be controlled by being electrically connected to the first transistor T1 (or T1′).

Since the first voltage line VL1 provides the first power voltage ELVDD having a relatively high voltage level and the second voltage line VL2 provides the second power voltage ELVSS having a relatively low voltage level, in case that the first transistor T1 (or T1′) is an n-type transistor, the second terminal of the first transistor T1 (or T1′) may be a drain. According to embodiments, the cathode of the light emitting element LD may be connected to the drain of the first transistor T1 (or T1′).

In case that the first transistor T1 (or T1′) is an n-type transistor, if the anode of the light emitting element LD is connected to the source of first transistor T1 (or T1′), a source voltage of the first transistor T1 (or T1′) may shift due to deterioration of the light emitting element LD and a gate-source voltage (Vgs) of the first transistor T1 (or T1′) may change. As a result, a range of change in the driving current ID may increase, an after-image defect may occur, and a lifespan of the display device may be reduced.

According to embodiments, the anode of the light emitting element LD may receive the first power voltage ELVDD, and the cathode of the light emitting element LD may be connected to the drain of the first transistor T1 (or T1′). Accordingly, even in case that the light emitting element LD deteriorates, the gate-source voltage (Vgs) of the first transistor T1 (or T1′) may not change. Accordingly, the range of change in the driving current ID due to the deterioration of the light emitting element LD may be reduced. Therefore, the after-image defect of the display device DD3 depending on an increase in the time of use may be reduced, and the lifespan of the display device DD3 may be improved.

The circuit structures of the pixels PX (e.g., the number or arrangement of the transistors, the number or arrangement of the capacitors) illustrated in FIGS. 17A and 17B are only examples and may be variously changed according to embodiments.

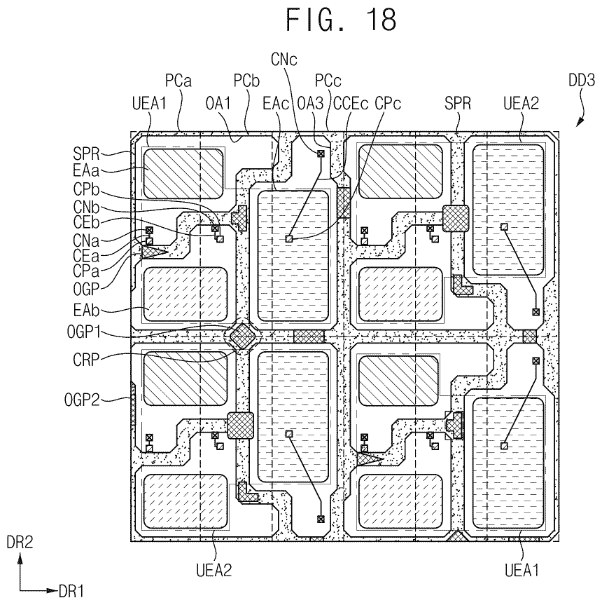

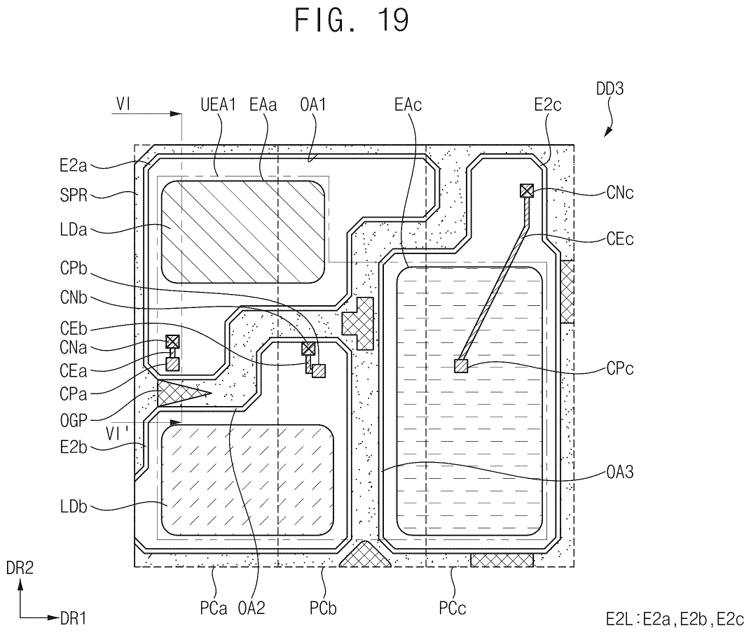

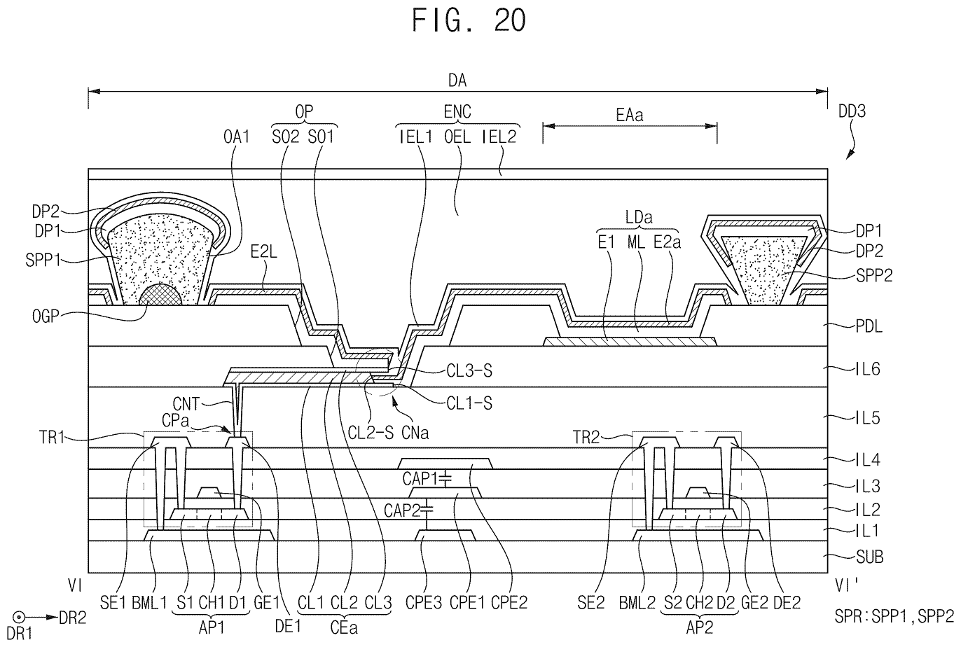

FIG. 18 is a plan view illustrating a portion of an area of the display device of FIG. 16. FIG. 19 is an enlarged plan view illustrating one unit emission area among the unit emission areas of FIG. 18. FIG. 20 is a schematic cross-sectional view taken along line VI-VI′ of FIG. 19.

For example, FIG. 18 schematically illustrates an area in which four unit emission areas UEA1 and UEA2 forming a matrix of two rows and two columns are arranged, and FIG. 19 schematically illustrates an enlarged view of a first unit emission area UEA1 among the unit emission areas UEA1 and UEA2. For convenience of description, some of components illustrated in FIG. 20 are omitted or emphasized in FIGS. 18 and 19. For example, in FIG. 18, second electrodes E2a, E2b, E2c among components illustrated in FIG. 19 are omitted.

Referring to FIGS. 18 and 19, the display device DD3 may include first to third pixel driving circuits PCa, PCb, and PCc, first to third light emitting elements LDa, LDb, and LDc, first to third connection electrodes CEa, CEb, and CEc, a separator SPR, and multiple organic film patterns OGP.

Each of the first to third pixel driving circuits PCa, PCb, and PCc may correspond to at least one of the pixel driving circuits PC2, PC2′ described above with reference to FIGS. 17A and 17B. For example, each of the first to third pixel driving circuits PCa, PCb, and PCc may include at least one transistor and at least one capacitor. For example, each of the first to third pixel driving circuits PCa, PCb, and PCc may include a first transistor TR1, a second transistor TR2, a first capacitor CAP1, and a second capacitor CAP2 illustrated in FIG. 20.

The first transistor TR1 of FIG. 20 may be a transistor connected to the light emitting element through the connection electrode. For example, in case that each of the first to third pixel driving circuits PCa, PCb, and PCc is the pixel driving circuit PC2 of FIG. 17A, the first transistor TR1 may be the first transistor T1 of FIG. 17A, and the second transistor TR2 may be the second transistor T2 of FIG. 17A. In case that each of the first to third pixel driving circuits PCa, PCb, and PCc is the pixel driving circuit PC2′ of FIG. 17B, the first transistor TR1 may be the fifth transistor T5 of FIG. 17B, and the second transistor TR2 may be one of the first, second, third, fourth, and sixth transistors T1′, T2, T3, T4, and T6 of FIG. 17B.

In an embodiment, the first capacitor CAP1 of FIG. 20 may correspond to the first capacitor C1 of FIGS. 17A and 17B, and the second capacitor CAP2 of FIG. 20 may correspond to the second capacitor C2 of FIG. 17B. For example, in case that each of the first to third pixel driving circuits PCa, PCb, and PCc is the pixel driving circuit PC2 of FIG. 17A, the second capacitor CAP2 may be omitted. However, the disclosure is not limited thereto, and in an embodiment, the first capacitor CAP1 of FIG. 20 may correspond to the second capacitor C2 of FIG. 17B, and the second capacitor CAP2 of FIG. 20 may correspond to the first capacitor C1 of FIGS. 17A and 17B. In case that each of the first to third pixel driving circuits PCa, PCb, and PCc is the pixel driving circuit PC2 of FIG. 17A, the first capacitor CAP1 may be omitted. The first transistor TR1, the second transistor TR2, the first capacitor CAP1, and the second capacitor CAP2 will be described below in more detail with reference to FIG. 20.

FIGS. 18 and 19 schematically illustrate that the first to third pixel driving circuits PCa, PCb, and PCc each has a rectangular shape in a plan view and are sequentially arranged along the first direction DR1. However, the disclosure is not limited thereto, and the shape and arrangement of the first to third pixel driving circuits PCa, PCb, and PCc may be variously changed according to embodiments.

Each of the first to third light emitting elements LDa, LDb, and LDc may correspond to the light emitting element LD described above with reference to FIGS. 17A and 17B. For example, the first to third light emitting elements LDa, LDb, and LDc may include a first electrode (E1, refer to FIG. 20), an intermediate layer (ML, refer to FIG. 20) arranged on the first electrode, and an electrode layer E2L (refer to FIG. 20) arranged on the intermediate layer. In an embodiment, the first electrode may function as the anode of FIGS. 17A and 17B, and the electrode layer E2L may function as the cathode of FIGS. 17A and 17B.

In an embodiment, the electrode layer E2L may be separated (or disconnected) into multiple second electrodes E2a, E2b, and E2c that are spaced apart from each other by the separator SPR. For example, the electrode layer E2L may be separated (or disconnected) into a second electrode E2a of the first light emitting element LDa, a second electrode E2b of the second light emitting element LDb, and a second electrode E2c of the third light emitting element LDc. This will be described below in more detail.

The first to third light emitting elements LDa, LDb, and LDc may be connected to the first to third pixel driving circuits PCa, PCb, and PCc, respectively. For example, the first light emitting element LDa may be connected to the first pixel driving circuit PCa, the second light emitting element LDb may be connected to the second pixel driving circuit PCb, and the third light emitting element LDc may be connected to the third pixel driving circuit PCc. Accordingly, the first pixel driving circuit PCa and the first light emitting element LDa may form one pixel, the second pixel driving circuit PCb and the second light emitting element LDb may form one pixel, and the third pixel driving circuit PCc and the third light emitting element LDc may form one pixel.

The first to third light emitting elements LDa, LDb, and LDc may emit light of different colors. For example, the first light emitting element LDa may emit red light, the second light emitting element LDb may emit green light, and the third light emitting element LDc may emit blue light. However, the disclosure is not limited thereto.

In an embodiment, as illustrated in FIG. 18, the display device DD3 may include the first unit emission area UEA1 and the second unit emission area UEA2. The first unit emission area UEA1 and the second unit emission area UEA2 may be arranged in a matrix form in the first direction DR1 and the second direction DR2. Although FIG. 18 illustrates only four unit emission areas, the disclosure is not limited thereto, and multiple unit emission areas may be arranged in a matrix form along the first direction DR1 and the second direction DR2 in the entire display area (DA, refer to FIG. 16).

The first to third light emitting elements LDa, LDb, and LDc adjacent to each other may be arranged in each of the first unit emission area UEA1 and the second unit emission area UEA2. For example, first to third emission areas EAa, EAb, and EAc adjacent to each other may be defined in each of the first unit emission area UEA1 and the second unit emission area UEA2, and the first to third light emitting elements LDa, LDb, and LDc may be arranged in the first to third emission areas EAa, EAb, and EAc, respectively.

The first to third emission areas EAa, EAb, and EAc may be defined by pixel openings of a pixel defining layer (PDL, refer to FIG. 20) described below. For example, each of the first to third emission areas EAa, EAb, and EAc may be an area where light is emitted from the light emitting element. For example, the first light emitting element LDa may be arranged in the first emission area EAa, and the first emission area EAa may be an area where light is emitted from the first light emitting element LDa. The second light emitting element LDb may be arranged in the second emission area EAb, and the second emission area EAb may be an area where light is emitted from the second light emitting element LDb. The third light emitting element LDc may be arranged in the third emission area EAc, and the third emission area EAc may be an area where light is emitted from the third light emitting element LDc.

In an embodiment, the first unit emission area UEA1 and the second unit emission area UEA2 may be distinguished based on the arrangement relationship between the first to third light emitting elements LDa, LDb, and LDc (or the arrangement relationship between the first to third emission areas EAa, EAb, and EAc). For example, the arrangement relationship between the first to third light emitting elements LDa, LDb, and LDc (or the first to third emission areas EAa, EAb, and EAc) may be the same for each first unit emission area UEA1, and the arrangement relationship between the first to third light emitting elements LDa, LDb, and LDc (or the first to third emission areas EAa, EAb, and EAc) may be the same for each second unit emission area UEA2.

In an embodiment, as illustrated in FIG. 18, the first unit emission areas UEA1 and the second unit emission areas UEA2 may be alternately arranged along the first direction DR1 (i.e., a row direction) and the second direction DR2 (i.e., a column direction). However, the disclosure is not limited thereto, and the number of different unit emission areas included in the display device DD3 or the arrangement relationship between the unit emission areas may be variously changed according to embodiments.

FIGS. 18 and 19 schematically illustrate that the first to third emission areas EAa, EAb, and EAc are arranged in an S-stripe structure. However, the disclosure is not limited thereto, and the arrangement of the first to third emission areas EAa, EAb, and EAc may be variously changed according to embodiments.

The separator SPR may be arranged between the first to third emission areas EAa, EAb, and EAc in a plan view. For example, the separator SPR may be arranged between the first emission area EAa and the second emission area EAb, between the second emission area EAb and the third emission area EAc, and between the first emission area EAa and the third emission area EAc in a plan view. In an embodiment, the separator SPR may entirely surround each of the first to third emission areas EAa, EAb, and EAc in a plan view.

In an embodiment, the separator SPR may include an organic insulating material. For example, the separator SPR may include a photosensitive resin (e.g., a photoresist), but the disclosure is not limited thereto.

The separator SPR may separate (or disconnect) the electrode layer E2L into the second electrode E2a of the first light emitting element LDa, the second electrode E2b of the second light emitting element LDb, and the second electrode E2c of the third light emitting element LDc in the display area. Accordingly, the second electrodes E2a, E2b, and E2c may be spaced apart from each other. The second electrodes E2a, E2b, and E2c may be electrically independent of each other.

The organic film patterns OGP may overlap at least a portion of the separator SPR in a plan view. The organic film patterns OGP may be arranged in a portion of an area where the separator SPR is arranged in a plan view. In other words, a portion of the separator SPR (e.g., a first portion SPP1 of the separator SPR of FIG. 20) may overlap the organic film pattern OGP in a plan view, and another portion of the separator SPR (e.g., a second portion SPP2 of the separator SPR of FIG. 20) may not overlap the organic film pattern OGP in a plan view. The organic film pattern OGP may include an organic material.

In an embodiment, the organic film patterns OGP may have various planar shapes. For example, as illustrated in FIG. 18, each of the organic film patterns OGP may have at least one of a triangular planar shape, a rectangular planar shape, a square planar shape, a cross planar shape, a rhombus planar shape, or the like in a plan view. However, the disclosure is not limited thereto, and the organic film patterns OGP may have a same planar shape as each other.

In an embodiment, the organic film patterns OGP may have different sizes (or areas) from each other. However, the disclosure is not limited thereto, and the organic film patterns OGP may have a same size as each other.

In an embodiment, the organic film patterns OGP may overlap an intersection portion CRP of the separator SPR in a plan view. Here, the intersection portion CRP of the separator SPR may be a portion where a first extension portion of the separator SPR extending in the first direction DR1 and a second extension portion of the separator SPR extending in the second direction DR2 meet. For example, as illustrated in FIG. 18, a first organic film pattern OGP1 among the organic film patterns OGP may overlap the intersection portion CRP of the separator SPR in a plan view. Compared to the first extension portion of the separator SPR and the second extension portion of the separator SPR, the intersection portion CRP of the separator SPR may provide a relatively large space to cover the organic film pattern OGP. However, the disclosure is not limited thereto, and in another embodiment, the organic film patterns OGP may overlap the first extension portion of the separator SPR and the second extension portion of the separator SPR in a plan view. For example, as illustrated in FIG. 18, a second organic film pattern OGP2 among the organic film patterns OGP may overlap the first extension portion of the separator SPR or the second extension portion of the separator SPR in a plan view.

In an embodiment, the organic film pattern OGP may be arranged in an area where the separator SPR is arranged in a plan view, and the separator SPR may cover the organic film pattern OGP in a plan view and may contact the pixel defining layer (PDL, refer to FIG. 20). However, the disclosure is not limited thereto. For example, as illustrated in FIG. 18, some of the organic film patterns OGP may be arranged in the area where the separator SPR is arranged in a plan view, and others of the organic film patterns OGP may overlap both the area where the separator SPR is arranged and an area where the separator SPR is not arranged in a plan view.

Hereinafter, a connection relationship between the first to third light emitting elements LDa, LDb, and LDc and the first to third pixel driving circuits PCa, PCb, and PCc will be described in more detail, focusing on the first unit emission area UEA1 of FIG. 19. The following description of the connection relationship between the first to third light emitting elements LDa, LDb, and LDc and the first to third pixel driving circuits PCa, PCb, and PCc may be substantially equally applied to all unit emission areas.

As described above, the display device DD3 may include the first to third connection electrodes CEa, CEb, and CEc. The first connection electrode CEa may electrically connect the first light emitting element LDa and the first pixel driving circuit PCa. The second connection electrode CEb may electrically connect the second light emitting element LDb and the second pixel driving circuit PCb. The third connection electrode CEc may electrically connect the third light emitting element LDc and the third pixel driving circuit PCc.

The first to third connection electrodes CEa, CEb, and CEc may include a conductive material such as a metal, an alloy, a conductive metal oxide, a conductive metal nitride, a transparent conductive oxide, or the like. In an embodiment, the first to third connection electrodes CEa, CEb, and CEc may have a multi-layer structure in which multiple conductive layers are stacked each other. A detailed description thereof will be described below with reference to FIG. 20.

The first connection electrode CEa may include a first circuit connection portion CPa and a first light emitting connection portion CNa.

The first circuit connection portion CPa may be a portion, which is connected to the first pixel driving circuit PCa, of the first connection electrode CEa. For example, the first circuit connection portion CPa may be a portion, which is connected to the first transistor (TR1, refer to FIG. 20) of the first pixel driving circuit PCa, of the first connection electrode CEa. Accordingly, a position of the first circuit connection portion CPa may correspond to a position of the first transistor of the first pixel driving circuit PCa. For example, the position of the first circuit connection portion CPa may correspond to a position of a contact hole (CNT, refer to FIG. 20) that exposes the first transistor of the first pixel driving circuit PCa and penetrates a fifth insulating layer (IL5, refer to FIG. 20).

The first light emitting connection portion CNa may be a portion, which is connected to the second electrode E2a of the first light emitting element LDa, of the first connection electrode CEa. For example, the first light emitting connection portion CNa may be a portion, which is exposed by a sixth insulating layer (IL6, refer to FIG. 20) and the pixel defining layer (PDL, refer to FIG. 20) for being connected to the second electrode E2a, of the first connection electrode CEa. Accordingly, a position of the first light emitting connection portion CNa may correspond to a position of a sub-opening (OP, refer to FIG. 20) that exposes the first connection electrode CEa and penetrates the pixel defining layer and the sixth insulating layer.

The second electrode E2a of the first light emitting element LDa may be connected to the first connection electrode CEa. For example, the second electrode E2a of the first light emitting element LDa may contact the first connection electrode CEa. As a result, the second electrode E2a of the first light emitting element LDa may be electrically connected to the first pixel driving circuit PCa through the first connection electrode CEa.

In an embodiment, the first light emitting connection portion CNa may be arranged at a position that does not overlap the first emission area EAa in a plan view. For example, in a plan view, the first light emitting connection portion CNa may be arranged between the first emission area EAa and the separator SPR. For example, the second electrode E2a of the first light emitting element LDa may have a protruding portion that protrudes from the first emission area EAa to a position that does not overlap the first emission area EAa in a plan view, and the second electrode E2a of the first light emitting element LDa may contact the first connection electrode CEa at a position that does not overlap the first emission area EAa. Accordingly, the second electrode E2a of the first light emitting element LDa and the first pixel driving circuit PCa may be electrically connected to each other through the first connection electrode CEa without reducing the size of the first emission area EAa.

The second connection electrode CEb may include a second circuit connection portion CPb and a second light emitting connection portion CNb.

The second circuit connection portion CPb may be a portion, which is connected to the second pixel driving circuit PCb, of the second connection electrode CEb. For example, the second circuit connection portion CPb may be a portion, which is connected to the first transistor (TR1, refer to FIG. 20) of the second pixel driving circuit PCb, of the second connection electrode CEb. Accordingly, a position of the second circuit connection portion CPb may correspond to a position of the first transistor of the second pixel driving circuit PCb. For example, the position of the second circuit connection portion CPb may correspond to a position of a contact hole that exposes the first transistor of the second pixel driving circuit PCb and penetrates the fifth insulating layer (IL5, refer to FIG. 20).

The second light emitting connection portion CNb may be a portion, which is connected to the second electrode E2b of the second light emitting element LDb, of the second connection electrode CEb. For example, the second light emitting connection portion CNb may be a portion, which is exposed by the sixth insulating layer (IL6, refer to FIG. 20) and the pixel defining layer (PDL, refer to FIG. 20) for being connected to the second electrode E2b, of the second connection electrode CEb. Accordingly, a position of the second light emitting connection portion CNb may correspond to a position of a sub-opening that exposes the second connection electrode CEb and penetrates the pixel defining layer and the sixth insulating layer.

In an embodiment, the second connection electrode CEb may be spaced apart from the first connection electrode CEa in a plan view. In other words, the first connection electrode CEa and the second connection electrode CEb may be electrodes that are distinct from each other.

The second electrode E2b of the second light emitting element LDb may be connected to the second connection electrode CEb. For example, the second electrode E2b of the second light emitting element LDb may contact the second connection electrode CEb. As a result, the second electrode E2b of the second light emitting element LDb may be electrically connected to the second pixel driving circuit PCb through the second connection electrode CEb.

In an embodiment, the second light emitting connection portion CNb may be arranged at a position that does not overlap the second emission area EAb in a plan view. For example, in a plan view, the second light emitting connection portion CNb may be arranged between the second emission area EAb and the separator SPR. For example, the second electrode E2b of the second light emitting element LDb may have a protruding portion that protrudes from the second emission area EAb to a position that does not overlap the second emission area EAb in a plan view, and the second electrode E2b of the second light emitting element LDb may contact the second connection electrode CEb at a position that does not overlap the second emission area EAb. Accordingly, the second electrode E2b of the second light emitting element LDb and the second pixel driving circuit PCb may be electrically connected to each other through the second connection electrode CEb without reducing the size of the second emission area EAb.

The third connection electrode CEc may include a third circuit connection portion CPc and a third light emitting connection portion CNc.

The third circuit connection portion CPc may be a portion, which is connected to the third pixel driving circuit PCc, of the third connection electrode CEc. For example, the third circuit connection portion CPc may be a portion, which is connected to the first transistor (TR1, refer to FIG. 20) of the third pixel driving circuit PCc, of the third connection electrode CEc. Accordingly, a position of the third circuit connection portion CPc may correspond to a position of the first transistor of the third pixel driving circuit PCc. Specifically, the position of the third circuit connection portion CPc may correspond to a position of a contact hole that exposes the first transistor of the third pixel driving circuit PCc and penetrates the fifth insulating layer (IL5, refer to FIG. 20).

The third light emitting connection portion CNc may be a portion, which is connected to the second electrode E2c of the third light emitting element LDc, of the third connection electrode CEc. For example, the third light emitting connection portion CNc may be a portion, which is exposed by the sixth insulating layer (IL6, refer to FIG. 20) and the pixel defining layer (PDL, refer to FIG. 20) for being connected to the second electrode E2c, of the third connection electrode CEc. Accordingly, a position of the third light emitting connection portion CNc may correspond to a position of a sub-opening that exposes the third connection electrode CEc and penetrates the pixel defining layer and the sixth insulating layer.

In an embodiment, the third connection electrode CEc may be spaced apart from the first connection electrode CEa and the second connection electrode CEb in a plan view. In other words, the first connection electrode CEa, the second connection electrode CEb, and the third connection electrode CEc may be electrodes that are distinct from each other.

The second electrode E2c of the third light emitting element LDc may be connected to the third connection electrode CEc. For example, the second electrode E2c of the third light emitting element LDc may contact the third connection electrode CEc. As a result, the second electrode E2c of the third light emitting element LDc may be electrically connected to the third pixel driving circuit PCc through the third connection electrode CEc.

In an embodiment, the third light emitting connection portion CNc may be arranged at a position that does not overlap the third emission area EAc in a plan view. For example, in a plan view, the third light emitting connection portion CNc may be arranged between the third emission area EAc and the separator SPR. For example, the second electrode E2c of the third light emitting element LDc may have a protruding portion that protrudes from the third emission area EAc to a position that does not overlap the third emission area EAc in a plan view, and the second electrode E2c of the third light emitting element LDc may contact the third connection electrode CEc at a position that does not overlap the third emission area EAc. Accordingly, the second electrode E2c of the third light emitting element LDc and the third pixel driving circuit PCc may be electrically connected to each other through the third connection electrode CEc without reducing the size of the third emission area EAc.

According to embodiments, the second electrodes E2a, E2b, and E2c may contact the first to third connection electrodes CEa, CEb, and CEc, respectively, at positions where the second electrodes E2a, E2b, and E2c do not overlap the first to third emission areas EAa, EAb, and EAc in a plan view, respectively. Accordingly, the second electrodes E2a, E2b, and E2c may contact the first to third connection electrodes CEa, CEb, and CEc, respectively, without reducing the size of each of the first to third emission areas EAa, EAb, and EAc.

According to embodiments, the second electrodes E2a, E2b, and E2c may be electrically connected to the first to third pixel driving circuits PCa, PCb, and PCc through the first to third connection electrodes CEa, CEb, and CEc, respectively. Accordingly, a limitation of the design of each of the first to third pixel driving circuits PCa, PCb, and PCc due to the positions, shapes, and sizes of the first to third emission areas EAa, EAb, and EAc may be reduced. For example, even if at least some of the first to third circuit connection portions CPa, CPb, and CPc overlap the first to third emission areas EAa, EAb, and EAc in a plan view, the second electrodes E2a, E2b, and E2c may be readily electrically connected to the first to third pixel driving circuits PCa, PCb, and PCc through the first to third connection electrodes CEa, CEb, and CEc, respectively. Accordingly, shapes, arrangements, or the like, of the first to third pixel driving circuits PCa, PCb, and PCc may be designed independently of the positions, shapes, and sizes of the first to third emission areas EAa, EAb, and EAc. Accordingly, a degree of design freedom of each of the first to third pixel driving circuits PCa, PCb, and PCc may be improved.

In an embodiment, the first to third pixel driving circuits PCa, PCb, and PCc may be designed to be the same as each other regardless of the positions, shapes, and sizes of the first to third emission areas EAa, EAb, and EAc. As described above, the position of the first circuit connection portion CPa may correspond to the position of the first transistor of the first pixel driving circuit PCa, the position of the second circuit connection portion CPb may correspond to the position of the first transistor of the second pixel driving circuit PCb, and the position of the third circuit connection portion CPc may correspond to the position of the first transistor of the third pixel driving circuit PCc. Accordingly, in case that the first to third pixel driving circuits PCa, PCb, and PCc are formed to have substantially the same size and to be arranged along the first direction DR1, the position of the first circuit connection portion CPa, the position of the second circuit connection portion CPb, and the position of the third circuit connection portion CPc may be arranged along the first direction DR1.

As illustrated in FIG. 18, the shape or arrangement of each of the first to third connection electrodes CEa, CEb, and CEc and the arrangement relationship between the first to third connection electrodes CEa, CEb, and CEc may be the same for each first unit emission area UEA1. The shape or arrangement of each of the first to third connection electrodes CEa, CEb, and CEc and the arrangement relationship between the first to third connection electrodes CEa, CEb, and CEc may be the same for each second unit emission area UEA2.

As described above, the display device DD3 may include the separator SPR. The electrode layer E2L may be separated (or disconnected) into the second electrodes E2a, E2b, and E2c by the separator SPR. For example, the second electrode E2a of the first light emitting element LDa, the second electrode E2b of the second light emitting element LDb, and the second electrode E2c of the third light emitting element LDc may be electrically independent of each other by the separator SPR.

The separator SPR may define first to third open areas OA1, OA2, and OA3 respectively corresponding to the second electrodes E2a, E2b, and E2c. For example, the separator SPR may have a mesh structure surrounding the second electrodes E2a, E2b, and E2c in a plan view. The second electrode E2a of the first light emitting element LDa may be arranged in the first open area OA1 of the separator SPR, the second electrode E2b of the second light emitting element LDb may be arranged in the second open area OA2 of the separator SPR, and the second electrode E2c of the third light emitting element LDc may be arranged in the third open area OA3 of the separator SPR.

In an embodiment, in a plan view, a shape of the first open area OA1 may be substantially the same as a shape of the second electrode E2a of the first light emitting element LDa, a shape of the second open area OA2 may be substantially the same as a shape of the second electrode E2b of the second light emitting element LDb, and a shape of the third open area OA3 may be substantially the same as a shape of the second electrode E2c of the third light emitting element LDc.

Hereinafter, a cross-sectional structure of the display device DD3 will be described in more detail with further reference to FIG. 20, focusing on the first emission area EAa. The following description of the cross-sectional structure of the display device DD3 may be substantially equally applied to all emission areas. Redundant descriptions of the cross-sectional structure of the display device DD1 described above with reference to FIG. 5 may be omitted or may be summarized.

Referring further to FIG. 20, the display device DD3 may include the substrate SUB, a first bottom conductive layer BML1, a second bottom conductive layer BML2, the first transistor TR1, the second transistor TR2, the first capacitor CAP1, the second capacitor CAP2, the first connection electrode CEa, first to six insulating layers IL1, IL2, IL3, IL4, IL5, and IL6, the pixel defining layer PDL, the first light emitting element LDa, the organic film pattern OGP, the separator SPR, a first dummy layer DP1, a second dummy layer DP2, and an encapsulation layer ENC. The separator SPR may include a first portion SPP1 and a second portion SPP2 spaced apart from the first portion SPP1.

The first transistor TR1 may include a first active pattern AP1, a first gate electrode GE1, a first contact electrode SE1, and a second contact electrode DE1. The second transistor TR2 may include a second active pattern AP2, a second gate electrode GE2, a third contact electrode SE2, and a fourth contact electrode DE2. The first capacitor CAP1 may include a first capacitor electrode CPE1 and a second capacitor electrode CPE2. The second capacitor CAP2 may include the first capacitor electrode CPE1 and a third capacitor electrode CPE3. The first light emitting element LDa may include the first electrode E1, the intermediate layer ML, and the second electrode E2a.

As described above, the first transistor TR1, the second transistor TR2, the first capacitor CAP1, and the second capacitor CAP2 may be components included in the first pixel driving circuit PCa.

The first bottom conductive layer BML1, the second bottom conductive layer BML2, and the third capacitor electrode CPE3 may be arranged on the substrate SUB. Each of the first bottom conductive layer BML1, the second bottom conductive layer BML2, and the third capacitor electrode CPE3 may include a conductive material such as a metal, an alloy, a conductive metal oxide, a conductive metal nitride, a transparent conductive oxide, or the like.

The first insulating layer IL1 may cover the first bottom conductive layer BML1, the second bottom conductive layer BML2, and the third capacitor electrode CPE3 and may be arranged on the substrate SUB. The first insulating layer IL1 may prevent or reduce metal atoms or impurities from diffusing from the substrate SUB to the first active pattern AP1 and/or the second active pattern AP2.

The first active pattern AP1 may be arranged on the first insulating layer IL1. In an embodiment, the first active pattern AP1 may overlap the first bottom conductive layer BML1. The first active pattern AP1 may include an oxide semiconductor material, a silicon semiconductor material, and/or an organic semiconductor material. The first active pattern AP1 may include a first contact area S1, a second contact area D1, and a first channel area CH1 between the first contact area S1 and the second contact area D1.

The second active pattern AP2 may be arranged on the first insulating layer IL1. In an embodiment, the second active pattern AP2 may overlap the second bottom conductive layer BML2. The second active pattern AP2 may include an oxide semiconductor material, a silicon semiconductor material, and/or an organic semiconductor material. The second active pattern AP2 may include a third contact area S2, a fourth contact area D2, and a second channel area CH2 between the third contact area S2 and the fourth contact area D2.

In an embodiment, the first active pattern AP1 and the second active pattern AP2 may include an oxide semiconductor material. However, the disclosure is not limited thereto, and the first active pattern AP1 and the second active pattern AP2 may include different materials. For example, one of the first active pattern AP1 and the second active pattern AP2 may include an oxide semiconductor material, and another one of the first active pattern AP1 and the second active pattern AP2 may include a silicon semiconductor material.

FIG. 20 schematically illustrates that the first active pattern AP1 and the second active pattern AP2 are arranged in the same layer. However, the disclosure is not limited thereto, and in another embodiment the first active pattern AP1 and the second active pattern AP2 may be arranged in different layers.

The second insulating layer IL2 may cover the first active pattern AP1 and the second active pattern AP2 and may be arranged on the first insulating layer IL1.

The first gate electrode GE1 may be arranged on the second insulating layer IL2. The first gate electrode GE1 may overlap the first channel area CH1 of the first active pattern AP1 in a plan view. The first gate electrode GE1 may include a conductive material such as a metal, an alloy, a conductive metal oxide, a conductive metal nitride, a transparent conductive oxide, or the like. Although not illustrated, in an embodiment, the first gate electrode GE1 may contact the first bottom conductive layer BML1.

The second gate electrode GE2 may be arranged on the second insulating layer IL2. The second gate electrode GE2 may overlap the second channel area CH2 of the second active pattern AP2 in a plan view. The second gate electrode GE2 may include a conductive material such as a metal, an alloy, a conductive metal oxide, a conductive metal nitride, a transparent conductive oxide, or the like. Although not illustrated, in an embodiment, the second gate electrode GE2 may contact the second bottom conductive layer BML2.

The third insulating layer IL3 may cover the first gate electrode GE1, the second gate electrode GE2, and the first capacitor electrode CPE1 and may be arranged on the second insulating layer IL2.

The fourth insulating layer IL4 may cover the second capacitor electrode CPE2 and may be arranged on the third insulating layer IL3.

The first to fourth contact electrodes SE1, DE1, SE2, and DE2 may be arranged on the fourth insulating layer IL4. The first contact electrode SE1 may contact the first contact area S1 of the first active pattern AP1, and the second contact electrode DE1 may contact the second contact area D1 of the first active pattern AP1. The third contact electrode SE2 may contact the third contact area S2 of the second active pattern AP2, and the fourth contact electrode DE2 may contact the fourth contact area D2 of the second active pattern AP2. The first to fourth contact electrodes SE1, DE1, SE2, and DE2 may include a conductive material such as a metal, an alloy, a conductive metal oxide, a conductive metal nitride, a transparent conductive oxide, or the like.

In an embodiment, the first contact electrode SE1 may contact the first bottom conductive layer BML1, and the third contact electrode SE2 may contact the second bottom conductive layer BML2. However, the disclosure is not limited thereto. For example, in case that the first gate electrode GE1 contacts the first bottom conductive layer BML1, the first contact electrode SE1 may not contact the first bottom conductive layer BML1. In case that the second gate electrode GE2 contacts the second bottom conductive layer BML2, the third contact electrode SE2 may not contact the second bottom conductive layer BML2.

Accordingly, the first transistor TR1 including the first active pattern AP1, the first gate electrode GE1, the first contact electrode SE1, and the second contact electrode DE1 may be formed. As described above, the first transistor TR1 may be a transistor that is connected to the light emitting element through the connection electrode. For example, in case that the first pixel driving circuit PCa is the pixel driving circuit PC2 of FIG. 17A, the first transistor TR1 may be the first transistor T1 of FIG. 17A. In case that the first pixel driving circuit PCa is the pixel driving circuit PC2′ of FIG. 17B, the first transistor TR1 may be the fifth transistor T5 of FIG. 17B.

The second transistor TR2 including the second active pattern AP2, the second gate electrode GE2, the third contact electrode SE2, and the fourth contact electrode DE2 may be formed. For example, in case that the first pixel driving circuit PCa is the pixel driving circuit PC2 of FIG. 17A, the second transistor TR2 may be the second transistor T2 of FIG. 17A. In case that the first pixel driving circuit PCa is the pixel driving circuit PC2′ of FIG. 17B, the second transistor TR2 may be one of the first to fourth transistors T1′, T2, T3, and T4 and the sixth transistor T6 of FIG. 17B.

The fifth insulating layer IL5 may cover the first to fourth contact electrodes SE1, DE1, SE2, and DE2 and may be arranged on the fourth insulating layer IL4.

The first connection electrode CEa may be arranged on the substrate SUB in the display area DA. For example, the first connection electrode CEa may be arranged on the fifth insulating layer IL5 in the display area DA. The first connection electrode CEa may be spaced apart from the first electrode E1. As described above, the first connection electrode CEa may be connected to the first transistor TR1. For example, the first connection electrode CEa may contact the first transistor TR1 through a contact hole CNT that penetrates the fifth insulating layer IL5. Accordingly, the position of the first circuit connection portion CPa may correspond to a position of the contact hole CNT.

The first connection electrode CEa may include a conductive material such as a metal, an alloy, a conductive metal oxide, a conductive metal nitride, a transparent conductive oxide, or the like. In an embodiment, the first connection electrode CEa may have a multi-layer structure in which multiple conductive layers are stacked each other. For example, the first connection electrode CEa may include a first conductive layer CL1, a second conductive layer CL2, and a third conductive layer CL3 that are sequentially stacked.

In an embodiment, the first conductive layer CL1 may include a metal and/or a transparent conductive oxide. Examples of the metal that may be used as the first conductive layer CL1 may include titanium (Ti), molybdenum (Mo), or the like. Examples of the transparent conductive oxide that may be used as the first conductive layer CL1 may include indium tin oxide (ITO), indium zinc oxide (IZO), zinc oxide (ZnO), indium oxide (InOₓ), indium gallium oxide (IGO), aluminum zinc oxide (AZO), or the like. The first conductive layer CL1 may have a thickness less than a thickness of the second conductive layer CL2.

The second conductive layer CL2 and the first conductive layer CL1 may include different materials. For example, the second conductive layer CL2 and the first conductive layer CL1 may include different metals. For example, the second conductive layer CL2 may include aluminum (Al), copper (Cu), or the like. The second conductive layer CL2 may have a thickness greater than a thickness of the first conductive layer CL1.

The third conductive layer CL3 and the second conductive layer CL2 may include different materials. For example, the third conductive layer CL3 may include a metal and/or a transparent conductive oxide different from the second conductive layer CL2. Examples of the metal that may be used as the third conductive layer CL3 may include titanium (Ti), molybdenum (Mo), or the like. Examples of the transparent conductive oxide that may be used as the third conductive layer CL3 may include indium tin oxide (ITO), indium zinc oxide (IZO), zinc oxide (ZnO), indium oxide (InOₓ), indium gallium oxide (IGO), aluminum zinc oxide (AZO), or the like. The third conductive layer CL3 may have a thickness less than a thickness of the second conductive layer CL2.

In an embodiment, the first conductive layer CL1 and the third conductive layer CL3 may include a same material. However, the disclosure is not limited thereto.

A side surface CL2-S of the second conductive layer CL2 may be more depressed toward a center of the first connection electrode CEa than a side surface CL1-S of the first conductive layer CL1 and a side surface CL3-S of the third conductive layer CL3. In other words, the side surface CL1-S of the first conductive layer CL1 and the side surface CL3-S of the third conductive layer CL3 may protrude outward more than the side surface CL2-S of the second conductive layer CL2. Accordingly, the first connection electrode CEa may have a tip structure due to a protruding portion of the third conductive layer CL3 compared to the second conductive layer CL2. For example, in case that the second conductive layer CL2 is etched using an etching material having a higher etching rate for the second conductive layer CL2 than for the first conductive layer CL1 and the third conductive layer CL3, the first connection electrode CEa may be formed to have the tip structure.

In FIG. 20, the first connection electrode CEa is illustrated as having a three-layer structure in which the first to third conductive layers CL1, CL2, and CL3 are stacked. However, the disclosure is not limited thereto, and in another embodiment, the first connection electrode CEa may have a two-layer structure in which the second conductive layer CL2 and the third conductive layer CL3 are stacked. In another embodiment, the first conductive layer CL1 may be omitted.

The sixth insulating layer IL6 may partially cover the first connection electrode CEa and may be arranged on the fifth insulating layer IL5. The sixth insulating layer IL6 may define a first sub-opening SO1 that exposes at least a portion of the first connection electrode CEa. For example, the first sub-opening SO1 may expose the tip structure of the first connection electrode CEa.

The first electrode E1 may be arranged in the display area DA on the substrate SUB. For example, the first electrode E1 may be arranged on the sixth insulating layer IL6 in the display area DA. The first electrode E1 may include a conductive material such as a metal, an alloy, a conductive metal oxide, a conductive metal nitride, a transparent conductive oxide, or the like. As described above, the first electrode E1 may function as the anode of FIGS. 17A and 17B.

The pixel defining layer PDL may be arranged on the substrate SUB and may define a pixel opening that exposes the first electrode E1. For example, the pixel defining layer PDL may be arranged on the sixth insulating layer IL6 and the first electrode E1 and may define the pixel opening that exposes at least a portion of the first electrode E1. The first emission area EAa may be defined by the pixel opening.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. For example, the first sub-opening SO1 and the second sub-opening SO2 may be connected to define a sub-opening OP, and the sub-opening OP may expose at least a portion of the first connection electrode CEa. For example, the sub-opening OP may expose the tip structure of the first connection electrode CEa.

The organic film pattern OGP may be arranged on the pixel defining layer PDL in the display area DA. For example, the organic film pattern OGP may be arranged between the pixel defining layer PDL and the separator SPR in the display area DA. In an embodiment, an upper surface of the organic film pattern OGP may be a curved surface that is convex upward. The organic film pattern OGP may include an organic material. In an embodiment, the organic film pattern OGP and the pixel defining layer PDL may include different materials.

The separator SPR may be arranged on the pixel defining layer PDL. A side surface of the separator SPR connecting an upper surface of the separator SPR and a lower surface of the separator SPR may have a reverse tapered slope. In other words, the separator SPR may have a cross-sectional shape of an inverted trapezoid.

In FIG. 20, the side surface of the separator SPR is illustrated as having a single reverse tapered slope. However, the disclosure is not limited thereto, and in another embodiment, the side surface of the separator SPR may have multiple reverse tapered slopes. For example, the separator SPR may have a double reverse tapered structure.

The separator SPR may include the first portion SPP1 and the second portion SPP2 spaced apart from the first portion SPP1. The first portion SPP1 of the separator SPR may overlap the organic film pattern OGP in a plan view, and the second portion SPP2 of the separator SPR may be spaced apart from the organic film pattern OGP in a plan view. In other words, the second portion SPP2 of the separator SPR may not overlap the organic film pattern OGP in a plan view.

As the organic film pattern OGP is arranged between the pixel defining layer PDL and the first portion SPP1 of the separator SPR, an upper surface of the first portion SPP1 of the separator SPR may be a curved surface that is convex upward. In an embodiment, a level of the upper surface of the first portion SPP1 of the separator SPR may be higher than a level of an upper surface of the second portion SPP2 of the separator SPR. Here, the level of the upper surface of the separator SPR may be a level of the highest portion of the upper surface of the separator SPR.

The intermediate layer ML may be arranged on the first electrode E1 and the pixel defining layer PDL. A portion of the intermediate layer ML may be arranged in the pixel opening of the pixel defining layer PDL. In an embodiment, the intermediate layer ML may include a first functional layer including an organic material, a light emitting layer arranged on the first functional layer and including a light emitting material, and a second functional layer arranged on the light emitting layer and including an organic material. For example, the first functional layer may include a hole injection layer, a hole transport layer, or the like, and the second functional layer may include an electron transport layer, an electron injection layer, or the like.

A shadow area where it is difficult to deposit the intermediate layer ML may exist around the separator SPR having the reverse tapered slope. Accordingly, in the shadow area and/or around the shadow area, the intermediate layer ML may be separated (or disconnected) by the separator SPR.

The intermediate layer ML may also be separated (or disconnected) by the tip structure of the first connection electrode CEa. As the intermediate layer ML is separated (or disconnected) by the tip structure of the first connection electrode CEa, the intermediate layer ML may expose at least a portion of the side surface CL2-S of the second conductive layer CL2. Accordingly, the second electrode E2a of the first light emitting element LDa may contact the side surface CL2-S of the second conductive layer CL2.

The first dummy layer DP1 may be arranged on the separator SPR. The first dummy layer DP1 may be formed because the intermediate layer ML is separated (or disconnected) by the separator SPR. For example, the first dummy layer DP1 and the intermediate layer ML may be formed in a same process. In an embodiment, the first dummy layer DP1 may be omitted.

The electrode layer E2L (i.e., the second electrodes E2a, E2b, and E2c) may be arranged on the intermediate layer ML. In an embodiment, the electrode layer E2L (i.e., the second electrodes E2a, E2b, and E2c) may have a single-layer structure. However, the disclosure is not limited thereto, and in another embodiment, the electrode layer E2L (i.e., the second electrodes E2a, E2b, and E2c) may have a multi-layer structure in which multiple conductive layers are stacked each other. For example, the electrode layer E2L (i.e., the second electrodes E2a, E2b, and E2c) may have a two-layer structure including a first sub-electrode layer including a metal and a second sub-electrode layer arranged on the first sub-electrode layer and including a transparent conductive oxide.

The shadow area where it is difficult to deposit the electrode layer E2L may exist around the separator SPR having the reverse tapered slope. In the shadow area and/or around the shadow area, the electrode layer E2L may be separated (or disconnected) by the separator SPR. For example, as illustrated in FIG. 19, the electrode layer E2L may be separated (or disconnected) into the second electrode E2a of the first light emitting element LDa arranged in the first open area OA1 of the separator SPR, the second electrode E2b of the second light emitting element LDb arranged in the second open area OA2 of the separator SPR, and the second electrode E2c of the third light emitting element LDc arranged in the third open area OA3 of the separator SPR. For example, the second electrodes E2a, E2b, and E2c may be electrically independent of each other.

As illustrated in FIG. 20, the electrode layer E2L (for example, the second electrode E2a) may be electrically connected to the first connection electrode CEa. Specifically, the electrode layer E2L (for example, the second electrode E2a) may contact the side surface CL2-S of the second conductive layer CL2. For example, in case that a deposition angle of a deposition process for forming the electrode layer E2L is greater than a deposition angle of a deposition process for forming the intermediate layer ML, the electrode layer E2L (for example, the second electrode E2a) may be formed to contact the side surface CL2-S of the second conductive layer CL2 while covering the intermediate layer ML disconnected by the tip structure. As a result, the second electrode E2a may be electrically connected to the first transistor TR1 through the first connection electrode CEa.

In an embodiment, the electrode layer E2L (for example, the second electrode E2a) may be separated (or disconnected) by the tip structure of the first connection electrode CEa. However, the disclosure is not limited thereto, and in another embodiment, the electrode layer E2L (for example, the second electrode E2a) may be formed to extend without being disconnected by the tip structure.

The second dummy layer DP2 may be arranged on the separator SPR. For example, the second dummy layer DP2 may be arranged on the first dummy layer DP1. The second dummy layer DP2 may be formed because the electrode layer E2L is separated (or disconnected) by the separator SPR. For example, the second dummy layer DP2 and the electrode layer E2L may be formed in a same process. In an embodiment, the second dummy layer DP2 may be omitted.

The encapsulation layer ENC may be arranged on the electrode layer E2L. The encapsulation layer ENC may entirely cover the electrode layer E2L, the separator SPR, the first dummy layer DP1, and the second dummy layer DP2. In an embodiment, the encapsulation layer ENC may include a first inorganic encapsulation layer IEL1 including an inorganic insulating material, an organic encapsulation layer OEL arranged on the first inorganic encapsulation layer IEL1 and including an organic insulating material, and a second inorganic encapsulation layer IEL2 arranged on the organic encapsulation layer OEL and including an inorganic insulating material.

According to embodiments, the display device DD3 may include the connection electrodes CEa, CEb, and CEc and the separator SPR. Accordingly, the electrode layer E2L (e.g., the cathode) arranged on the first electrode E1 (e.g., the anode) may be readily electrically connected to the pixel driving circuits PCa, PCb, and PCc. For example, the electrode layer E2L arranged on the first electrode E1 may be connected to a drain of the driving transistor (e.g., the first transistor T1 (or T1′) of FIGS. 17A and 17B) of each of the pixel driving circuits PCa, PCb, and PCc through the connection electrodes CEa, CEb, and CEc. Accordingly, even in case that the light emitting element deteriorates, the gate-source voltage (Vgs) of the driving transistor may not change. Accordingly, the range of change in the driving current due to the deterioration of the light emitting element may be reduced. Therefore, the after-image defect of the display device DD3 depending on an increase in the time of use may be reduced, and the lifespan of the display device DD3 may be improved.

As described above, the level of the upper surface of the first portion SPP1 of the separator SPR may be higher than the level of the upper surface of the second portion SPP2 of the separator SPR. Accordingly, a mask used in the process of forming the intermediate layer ML may contact the first portion SPP1 of the separator SPR and may not contact the second portion SPP2 of the separator SPR. In other words, an area of the separator SPR contacting the mask may be relatively reduced. As a result, the phenomenon of being stamped by the mask, which may occur in case that the area of the separator SPR contacting the mask is large, may be suppressed.

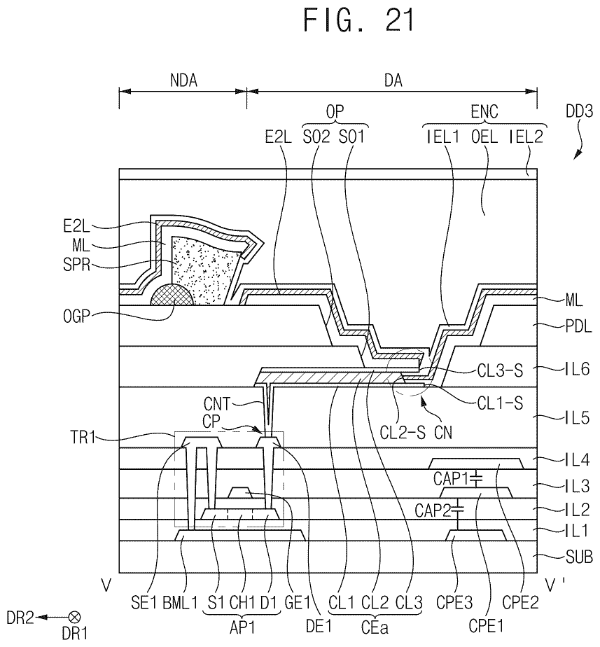

FIG. 21 is a schematic cross-sectional view taken along line V-V′ of FIG. 16.

Referring to FIG. 21, the display device DD3 according to an embodiment of the disclosure may include the substrate SUB, the first bottom conductive layer BML1, the first transistor TR1, the first capacitor CAP1, the second capacitor CAP2, the first connection electrode CEa, the first to six insulating layers IL1, IL2, IL3, IL4, IL5, and IL6, the pixel defining layer PDL, the intermediate layer ML, the electrode layer E2L, the organic film pattern OGP, the separator SPR, and the encapsulation layer ENC. Hereinafter, redundant descriptions of the cross-sectional structure of the display device DD3 described above with reference to FIG. 20 may be omitted or may be summarized.

The organic film pattern OGP may be arranged on the pixel defining layer PDL in the peripheral area NDA. For example, the organic film pattern OGP may be arranged between the pixel defining layer PDL and the separator SPR in the peripheral area NDA. In an embodiment, an upper surface of the organic film pattern OGP may be a curved surface that is convex upward. The organic film pattern OGP may include an organic material. In an embodiment, the organic film pattern OGP and the pixel defining layer PDL may include different materials.

The separator SPR may be arranged on the pixel defining layer PDL. The separator SPR may contact the organic film pattern OGP and the pixel defining layer PDL in the peripheral area NDA. In an embodiment, the organic film pattern OGP may overlap a portion of the separator SPR in a plan view in the peripheral area NDA. For example, the organic film pattern OGP may overlap a first side surface of the separator SPR in a plan view in the peripheral area NDA. As the upper surface of the organic film pattern OGP includes a curved surface that is convex upwardly, an upper surface of the separator SPR may be a curved surface that is convex upwardly.

In an embodiment, as illustrated in FIG. 21, the cross-sectional shape of a portion of the separator SPR may be asymmetrical in the peripheral area NDA. For example, a first side surface of the portion of the separator SPR may contact the organic film pattern OGP in the peripheral area NDA, and a second side surface opposite to the first side surface may contact the pixel defining layer PDL without contacting the organic film pattern OGP. Accordingly, in the process of forming the separator SPR, a difference in the degree of inclination of the first side surface and the second side surface may be caused due to a difference in the characteristics between the organic film pattern OGP and the pixel defining layer PDL.

The second side surface of the separator SPR may have a reverse tapered slope. As the second side surface of the separator SPR has a reverse tapered slope, the intermediate layer ML and the electrode layer E2L may be separated (or disconnected) in the display area DA.

In contrast, the first side surface of the separator SPR may not have a reverse tapered slope. For example, by forming the organic film pattern OGP that overlaps the first side surface of the separator SPR in a plan view in the peripheral area NDA, the first side surface of the separator SPR may not have a reverse tapered slope. As the first side surface of the separator SPR does not have a reverse tapered slope, the intermediate layer ML and the electrode layer E2L may be formed to extend without being disconnected in the peripheral area NDA.

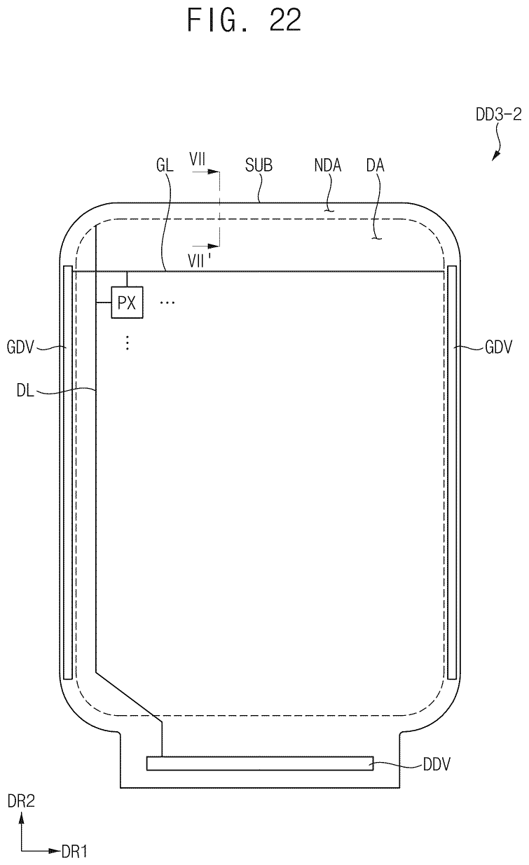

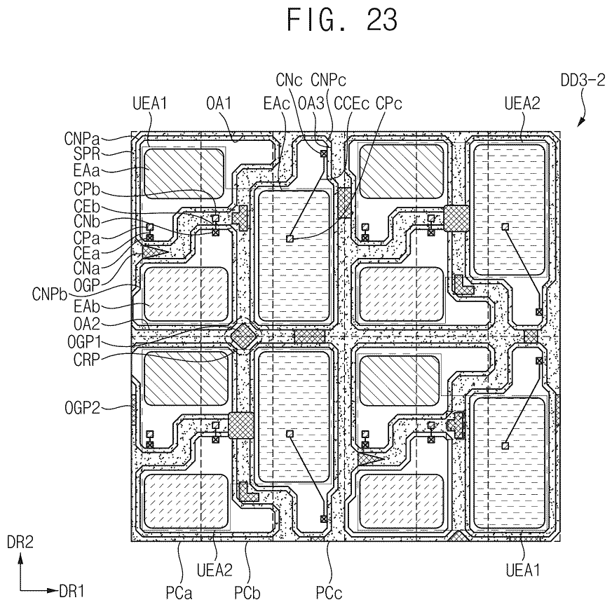

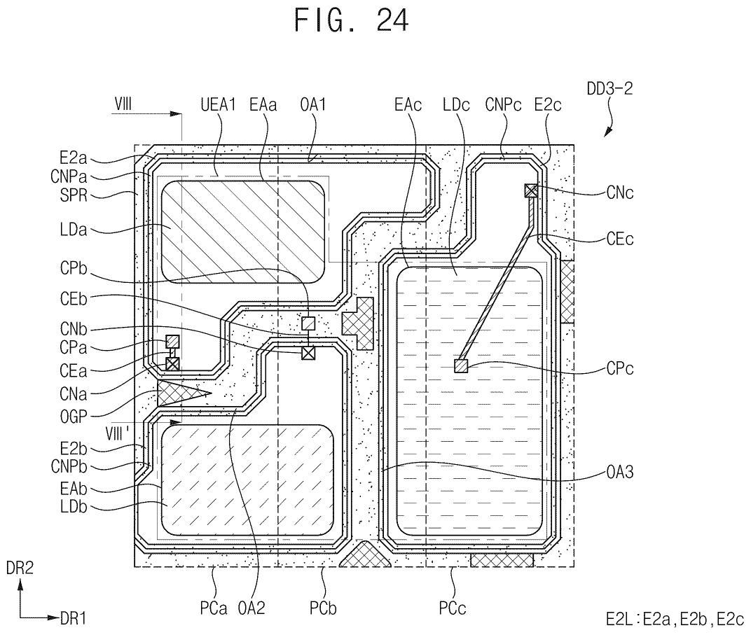

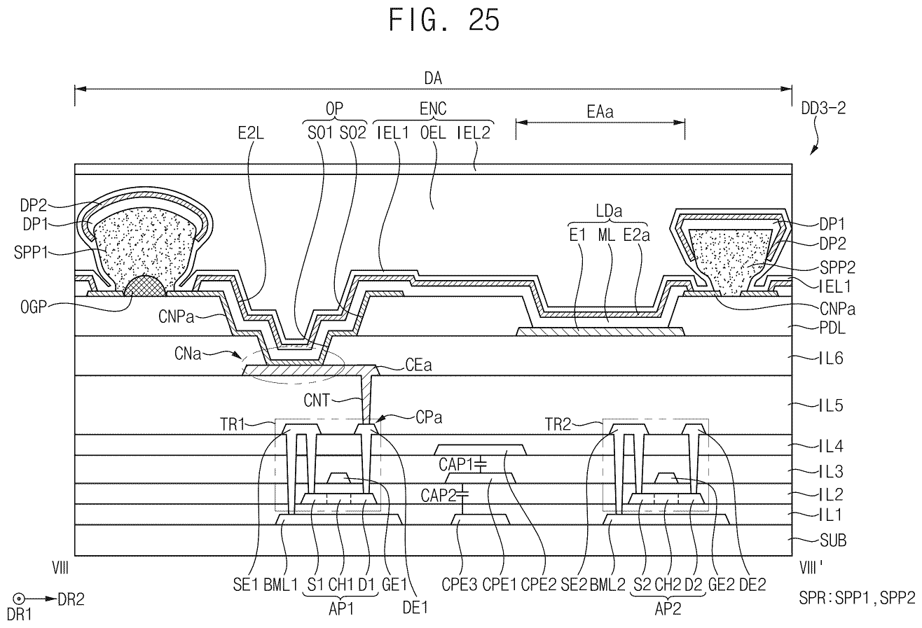

FIG. 22 is a plan view illustrating a display device according to an embodiment of the disclosure. FIG. 23 is a plan view illustrating a portion of an area of the display device of FIG. 22. FIG. 24 is an enlarged plan view illustrating one unit emission area among the unit emission areas of FIG. 23. FIG. 25 is a schematic cross-sectional view taken along line VIII-VIII′ of FIG. 24.

For example, FIG. 23 schematically illustrates an area in which four unit emission areas UEA1 and UEA2 forming a matrix of two rows and two columns are arranged, and FIG. 24 schematically illustrates an enlarged view of a first unit emission area UEA1 among the unit emission areas UEA1 and UEA2. For convenience of description, some of components illustrated in FIG. 25 are omitted or emphasized in FIGS. 23 and 24. For example, in FIG. 23, second electrodes E2a, E2b, and E2c among the components illustrated in FIG. 24 are omitted.

Referring to FIGS. 22, 23, 24, and 25, a display device DD3-2 may be a device activated according to an electrical signal. For example, as illustrated in FIG. 22, the display device DD3-2 may be a small-sized display device used in a small-sized electronic device such as a smart phone, a mobile phone, a smart watch, a game console, a camera, or the like. However, the disclosure is not limited thereto, and in another embodiment, the display device DD3-2 may be a medium and large-sized display device used in medium and large-sized electronic devices such as a laptop, a tablet PC, a television, a computer monitor, a vehicle monitor, an external billboard, or the like.

Compared to the display device DD3 described above with reference to FIGS. 16, 17A, 17B, 18, 19, and 20, the display device DD3-2 may further include a connection pattern (e.g., a first connection pattern CNPa of FIG. 25) that electrically connects a connection electrode (e.g., a first connection electrode CEa of FIG. 25) and a second electrode (e.g., a second electrode E2a of FIG. 25). Hereinafter, redundant descriptions of the display device DD3 described with reference to FIGS. 16, 17A, 17B, 18, 19, and 20 may be omitted or may be summarized.

As illustrated in FIGS. 23 and 24, the display device DD3-2 may include first to third pixel driving circuits PCa, PCb, and PCc, first to third light emitting elements LDa, LDb, and LDc, first to third connection electrodes CEa, CEb, and CEc, first to third connection patterns CNPa, CNPb, and CNPc, a separator SPR, and multiple organic film patterns OGP.

Each of the first to third pixel driving circuits PCa, PCb, and PCc may correspond to one of the pixel driving circuits PC2 and PC2′ described above with reference to FIGS. 17A and 17B. For example, each of the first to third pixel driving circuits PCa, PCb, and PCc may include at least one transistor and at least one capacitor. For example, each of the first to third pixel driving circuits PCa, PCb, and PCc may include a first transistor TR1, a second transistor TR2, a first capacitor CAP1, and a second capacitor CAP2 illustrated in FIG. 25.

The first transistor TR1 of FIG. 25 may be a transistor that is connected to the light emitting element through the connection electrode and the connection pattern. For example, in case that the first to third pixel driving circuits PCa, PCb, and PCc are the pixel driving circuit PC2 of FIG. 17A, the first transistor TR1 may be the first transistor T1 of FIG. 17A. In case that the first to third pixel driving circuits PCa, PCb, and PCc are the pixel driving circuit PC2′ of FIG. 17B, the first transistor TR1 may be the fifth transistor T5 of FIG. 17B.

Each of the first to third light emitting elements LDa, LDb, and LDc may correspond to the light emitting element LD described above with reference to FIGS. 17A and 17B. For example, each of the first to third light emitting elements LDa, LDb, and LDc may include a first electrode (E1, refer to FIG. 25), an intermediate layer (ML, refer to FIG. 25) arranged on the first electrode, and an electrode layer E2L arranged on the intermediate layer. In an embodiment, the first electrode may function as the anode of FIGS. 17A and 17B, and the electrode layer E2L may function as the cathode of FIGS. 17A and 17B.

In an embodiment, the electrode layer E2L may be separated (or disconnected) into multiple second electrodes E2a, E2b, and E2c that are spaced apart from each other by the separator SPR. For example, the electrode layer E2L may be separated (or disconnected) into a second electrode E2a of the first light emitting element LDa, a second electrode E2b of the second light emitting element LDb, and a second electrode E2c of the third light emitting element LDc.

The first to third light emitting elements LDa, LDb, and LDc may be connected to the first to third pixel driving circuits PCa, PCb, and PCc, respectively. For example, the first light emitting element LDa may be connected to the first pixel driving circuit PCa, the second light emitting element LDb may be connected to the second pixel driving circuit PCb, and the third light emitting element LDc may be connected to the third pixel driving circuit PCc.

The separator SPR may be arranged between first to third emission areas EAa, EAb, and EAc in a plan view. For example, the separator SPR may be arranged between the first emission area EAa and the second emission area EAb, between the second emission area EAb and the third emission area EAc, and between the first emission area EAa and the third emission area EAc in a plan view. In an embodiment, the separator SPR may entirely surround each of the first to third emission areas EAa, EAb, and EAc in a plan view. In an embodiment, the separator SPR may include an organic insulating material.

The separator SPR may separate (or disconnect) the electrode layer E2L into the second electrode E2a of the first light emitting element LDa, the second electrode E2b of the second light emitting element LDb, and the second electrode E2c of the third light emitting element LDc in the display area DA. Accordingly, the second electrodes E2a, E2b, and E2c may be spaced apart from each other. The second electrodes E2a, E2b, and E2c may be electrically independent of each other.

The organic film patterns OGP may overlap at least a portion of the separator SPR in a plan view. The organic film patterns OGP may be arranged in a portion of an area where the separator SPR is arranged in a plan view. In other words, a portion of the separator SPR (e.g., a first portion SPP1 of the separator SPR of FIG. 25) may overlap the organic film pattern OGP in a plan view, and another portion of the separator SPR (e.g., a second portion SPP2 of the separator SPR of FIG. 25) may not overlap the organic film pattern OGP in a plan view. The organic film pattern OGP may include an organic material.

In an embodiment, the organic film patterns OGP may overlap an intersection portion CRP of the separator SPR in a plan view. The intersection portion CRP of the separator SPR may be a portion where a first extension portion of the separator SPR extending in the first direction DR1 and a second extension portion of the separator SPR extending in the second direction DR2 meet. For example, as illustrated in FIG. 23, a first organic film pattern OGP1 among the organic film patterns OGP may overlap the intersection portion CRP of the separator SPR in a plan view. However, the disclosure is not limited thereto, and in another embodiment the organic film patterns OGP may overlap the first extension portion of the separator SPR and the second extension portion of the separator SPR in a plan view. For example, as illustrated in FIG. 23, a second organic film pattern OGP2 among the organic film patterns OGP may overlap the first extension portion of the separator SPR or the second extension portion of the separator SPR in a plan view.

In an embodiment, the organic film pattern OGP may be arranged in an area where the separator SPR is arranged in a plan view. However, the disclosure is not limited thereto, and in another embodiment some of the organic film patterns OGP may be arranged inside the area where the separator SPR is arranged in a plan view, and others of the organic film patterns OGP may overlap both the area where the separator SPR is arranged and an area where the separator SPR is not arranged in a plan view.

Hereinafter, a connection relationship between the first to third light emitting elements LDa, LDb, and LDc and the first to third pixel driving circuits PCa, PCb, and PCc will be described in more detail, focusing on the first unit emission area UEA1 of FIG. 24. The following description of the connection relationship between the first to third light emitting elements LDa, LDb, and LDc and the first to third pixel driving circuits PCa, PCb, and PCc may be substantially equally applied to all unit emission areas.

As described above, the display device DD3-2 may include the first to third connection electrodes CEa, CEb, and CEc and the first to third connection patterns CNPa, CNPb, and CNPc. The first connection electrode CEa and the first connection pattern CNPa may electrically connect the first light emitting element LDa and the first pixel driving circuit PCa. The second connection electrode CEb and the second connection pattern CNPb may electrically connect the second light emitting element LDb and the second pixel driving circuit PCb. The third connection electrode CEc and the third connection pattern CNPc may electrically connect the third light emitting element LDc and the third pixel driving circuit PCc.

The first to third connection electrodes CEa, CEb, and CEc may include a conductive material such as a metal, an alloy, a conductive metal oxide, a conductive metal nitride, a transparent conductive oxide, or the like. In an embodiment, the first to third connection electrodes CEa, CEb, and CEc may have a single-layer structure or a multi-layer structure in which multiple conductive layers are stacked each other.

In an embodiment, the first to third connection patterns CNPa, CNPb, and CNPc may include a transparent conductive oxide. For example, the first to third connection patterns CNPa, CNPb, and CNPc may include indium gallium zinc oxide (IGZO), indium tin zinc oxide (ITZO), indium tin oxide (ITO), indium zinc oxide (IZO), indium gallium oxide (IGO), zinc oxide (ZnO), indium oxide (InOₓ), tin oxide (SnOₓ), gallium oxide (GaOₓ), aluminum zinc oxide (AZO), or the like. These may be used alone or in combination with each other. However, the disclosure is not limited thereto, and in another embodiment, the first to third connection patterns CNPa, CNPb, and CNPc may include a conductive material such as a metal, an alloy, a conductive metal nitride, or the like. In an embodiment, the first to third connection patterns CNPa, CNPb, and CNPc may have a single-layer structure or a multi-layer structure in which multiple conductive layers are stacked each other.

The first connection electrode CEa may include a first circuit connection portion CPa and a first light emitting connection portion CNa.

The first circuit connection portion CPa may be a portion, which is connected to the first pixel driving circuit PCa, of the first connection electrode CEa. For example, a position of the first circuit connection portion CPa may correspond to a position of a contact hole (CNT, refer to FIG. 25) that exposes the first transistor (TR1, refer to FIG. 25) of the first pixel driving circuit PCa and penetrates a fifth insulating layer (IL5, refer to FIG. 25).

The first light emitting connection portion CNa may be a portion, which is connected to the first connection pattern CNPa, of the first connection electrode CEa. For example, the first light emitting connection portion CNa may be a portion, which is exposed by a sixth insulating layer (IL6, refer to FIG. 25) and a pixel defining layer (PDL, refer to FIG. 25) for being connected to the first connection pattern CNPa, of the first connection electrode CEa. Accordingly, a position of the first light emitting connection portion CNa may correspond to a position of a sub-opening (OP, refer to FIG. 25) that exposes the first connection electrode CEa and penetrates the pixel defining layer PDL and the sixth insulating layer IL6. In a plan view, the first light emitting connection portion CNa may not overlap the first emission area EAa. For example, in a plan view, the first light emitting connection portion CNa may be arranged between the first emission area EAa and the separator SPR.

The first connection pattern CNPa may be connected to the first connection electrode CEa. For example, the first connection pattern CNPa may contact the first light emitting connection portion CNa of the first connection electrode CEa. However, the disclosure is not limited thereto, and in another embodiment, the first connection pattern CNPa may not directly contact the first connection electrode CEa. For example, the first connection pattern CNPa may contact a capping layer that contacts the first light emitting connection portion CNa of the first connection electrode CEa, and may be electrically connected to the first light emitting connection portion CNa of the first connection electrode CEa through the capping layer. The capping layer may include a conductive material. For example, the capping layer and the first electrode E1 may be substantially simultaneously formed and may include a same material.

The first connection pattern CNPa may not overlap the first emission area EAa in a plan view. In an embodiment, the first connection pattern CNPa may surround at least a portion of the first emission area EAa in a plan view. For example, the first connection pattern CNPa may have a closed ring shape that entirely surrounds the first emission area EAa in a plan view. However, the disclosure is not limited thereto.

The second electrode E2a of the first light emitting element LDa may be connected to the first connection pattern CNPa. For example, the second electrode E2a of the first light emitting element LDa may contact the first connection pattern CNPa. Accordingly, the first connection pattern CNPa may electrically connect the first connection electrode CEa and the second electrode E2a of the first light emitting element LDa. As a result, the second electrode E2a of the first light emitting element LDa may be electrically connected to the first pixel driving circuit PCa through the first connection electrode CEa and the first connection pattern CNPa.

In an embodiment, in a plan view, a profile of an area where the second electrode E2a of the first light emitting element LDa and the first connection pattern CNPa contact each other may be substantially the same as or similar to a profile of an edge of the first connection pattern CNPa. For example, in case that the first connection pattern CNPa has a closed ring shape that entirely surrounds the first emission area EAa in a plan view, the area where the second electrode E2a of the first light emitting element LDa and the first connection pattern CNPa contact each other may have a closed ring shape in a plan view. For example, the second electrode E2a of the first light emitting element LDa and the first connection pattern CNPa may contact each other at a position not overlapping the first emission area EAa in a plan view. Accordingly, the second electrode E2a of the first light emitting element LDa and the first pixel driving circuit PCa may be electrically connected to each other through the first connection pattern CNPa and the first connection electrode CEa without reducing the size of the first emission area EAa.

The second connection electrode CEb may include a second circuit connection portion CPb and a second light emitting connection portion CNb.

The second circuit connection portion CPb may be a portion, which is connected to the second pixel driving circuit PCb, of the second connection electrode CEb. For example, a position of the second circuit connection portion CPb may correspond to a position of a contact hole that exposes the first transistor of the second pixel driving circuit PCb and penetrates the fifth insulating layer IL5.

The second light emitting connection portion CNb may be a portion, which is connected to the second connection pattern CNPb, of the second connection electrode CEb. For example, the second light emitting connection portion CNb may be a portion, which is exposed by the sixth insulating layer IL6 and the pixel defining layer PDL for being connected to the second connection pattern CNPb, of the second connection electrode CEb. Accordingly, a position of the second light emitting connection portion CNb may correspond to a position of a sub-opening that exposes the second connection electrode CEb and penetrates the pixel defining layer PDL and the sixth insulating layer IL6. In a plan view, the second light emitting connection portion CNb may not overlap the second emission area EAb. For example, in a plan view, the second light emitting connection portion CNb may be arranged between the second emission area EAb and the separator SPR.

In an embodiment, the second connection electrode CEb may be spaced apart from the first connection electrode CEa in a plan view. In other words, the first connection electrode CEa and the second connection electrode CEb may be electrodes that are distinct from each other.

The second connection pattern CNPb may be connected to the second connection electrode CEb. For example, the second connection pattern CNPb may contact the second light emitting connection portion CNb of the second connection electrode CEb. However, the disclosure is not limited thereto, and in another embodiment, the second connection pattern CNPb may not directly contact the second connection electrode CEb. For example, the second connection pattern CNPb may contact a capping layer that contacts the second light emitting connection portion CNb of the second connection electrode CEb, and may be electrically connected to the second light emitting connection portion CNb of the second connection electrode CEb through the capping layer. The capping layer may include a conductive material. For example, the capping layer and the first electrode E1 may be substantially simultaneously formed and may include a same material.

The second connection pattern CNPb may not overlap the second emission area EAb in a plan view. In an embodiment, the second connection pattern CNPb may surround at least a portion of the second emission area EAb in a plan view. For example, the second connection pattern CNPb may have a closed ring shape that entirely surrounds the second emission area EAb in a plan view. However, the disclosure is not limited thereto.

In an embodiment, the second connection pattern CNPb may be spaced apart from the first connection pattern CNPa. In other words, the first connection pattern CNPa and the second connection pattern CNPb may be patterns that are distinct from each other.

The second electrode E2b of the second light emitting element LDb may be connected to the second connection pattern CNPb. For example, the second electrode E2b of the second light emitting element LDb may contact the second connection pattern CNPb. Accordingly, the second connection pattern CNPb may electrically connect the second connection electrode CEb and the second electrode E2b of the second light emitting element LDb. As a result, the second electrode E2b of the second light emitting element LDb may be electrically connected to the second pixel driving circuit PCb through the second connection electrode CEb and the second connection pattern CNPb.

In an embodiment, in a plan view, a profile of an area where the second electrode E2b of the second light emitting element LDb and the second connection pattern CNPb contact each other may be substantially the same as or similar to a profile of an edge of the second connection pattern CNPb. For example, in case that the second connection pattern CNPb has a closed ring shape that entirely surrounds the second emission area EAb in a plan view, the area where the second electrode E2b of the second light emitting element LDb and the second connection pattern CNPb contact each other may have a closed ring shape in a plan view. For example, the second electrode E2b of the second light emitting element LDb and the second connection pattern CNPb may contact each other at a position not overlapping the second emission area EAb in a plan view. Accordingly, the second electrode E2b of the second light emitting element LDb and the second pixel driving circuit PCb may be electrically connected to each other through the second connection pattern CNPb and the second connection electrode CEb without reducing the size of the second emission area EAb.

The third connection electrode CEc may include a third circuit connection portion CPc and a third light emitting connection portion CNc.

The third circuit connection portion CPc may be a portion, which is connected to the third pixel driving circuit PCc, of the third connection electrode CEc. For example, a position of the third circuit connection portion CPc may correspond to a position of a contact hole that exposes the first transistor of the third pixel driving circuit PCc and penetrates the fifth insulating layer IL5.

The third light emitting connection portion CNc may be a portion, which is connected to the third connection pattern CNPc, of the third connection electrode CEc. For example, the third light emitting connection portion CNc may be a portion, which is exposed by the sixth insulating layer IL6 and the pixel defining layer PDL for being connected to the third connection pattern CNPc, of the third connection electrode CEc. Accordingly, a position of the third light emitting connection portion CNc may correspond to a position of a sub-opening that exposes the third connection electrode CEc and penetrates the pixel defining layer PDL and the sixth insulating layer IL6. In a plan view, the third light emitting connection portion CNc may not overlap the third emission area EAc. For example, in a plan view, the third light emitting connection portion CNc may be arranged between the third emission area EAc and the separator SPR.

In an embodiment, the third connection electrode CEc may be spaced apart from the first connection electrode CEa and the second connection electrode CEb in a plan view. In other words, the first connection electrode CEa, the second connection electrode CEb, and the third connection electrode CEc may be electrodes that are distinct from each other.

The third connection pattern CNPc may be connected to the third connection electrode CEc. For example, the third connection pattern CNPc may contact the third light emitting connection portion CNc of the third connection electrode CEc. However, the disclosure is not limited thereto, and in another embodiment, the third connection pattern CNPc may not directly contact the third connection electrode CEc. For example, the third connection pattern CNPc may contact a capping layer that contacts the third light emitting connection portion CNc of the third connection electrode CEc, and may be electrically connected to the third light emitting connection portion CNc of the third connection electrode CEc through the capping layer. The capping layer may include a conductive material. For example, the capping layer and the first electrode E1 may be substantially simultaneously formed and may include a same material.

The third connection pattern CNPc may not overlap the third emission area EAc in a plan view. In an embodiment, the third connection pattern CNPc may surround at least a portion of the third emission area EAc in a plan view. For example, the third connection pattern CNPc may have a closed ring shape that entirely surrounds the third emission area EAc in a plan view. However, the disclosure is not limited thereto.

In an embodiment, the third connection pattern CNPc may be spaced apart from the first connection pattern CNPa and the second connection pattern CNPb. In other words, the first connection pattern CNPa, the second connection pattern CNPb, and the third connection pattern CNPc may be patterns that are distinct from each other.

The second electrode E2c of the third light emitting element LDc may be connected to the third connection pattern CNPc. For example, the second electrode E2c of the third light emitting element LDc may contact the third connection pattern CNPc. Accordingly, the third connection pattern CNPc may electrically connect the third connection electrode CEc and the second electrode E2c of the third light emitting element LDc. As a result, the second electrode E2c of the third light emitting element LDc may be electrically connected to the third pixel driving circuit PCc through the third connection electrode CEc and the third connection pattern CNPc.

In an embodiment, in a plan view, a profile of an area where the second electrode E2c of the third light emitting element LDc and the third connection pattern CNPc contact each other may be substantially the same as or similar to a profile of an edge of the third connection pattern CNPc. For example, in case that the third connection pattern CNPc has a closed ring shape that entirely surrounds the third emission area EAc in a plan view, the area where the second electrode E2c of the third light emitting element LDc and the third connection pattern CNPc contact each other may have a closed ring shape in a plan view. For example, the second electrode E2c of the third light emitting element LDc and the third connection pattern CNPc may contact each other at a position not overlapping the third emission area EAc in a plan view. Accordingly, the second electrode E2c of the third light emitting element LDc and the third pixel driving circuit PCc may be electrically connected to each other through the third connection pattern CNPc and the third connection electrode CEc without reducing the size of the third emission area EAc.

According to embodiments, the second electrodes E2a, E2b, and E2c may contact the first to third connection patterns CNPa, CNPb, and CNPc, respectively, at positions where the second electrodes E2a, E2b, and E2c do not overlap the first to third emission areas EAa, EAb, and EAc in a plan view, respectively. Accordingly, the second electrodes E2a, E2b, and E2c may contact the first to third connection patterns CNPa, CNPb, and CNPc, respectively, without reducing the size of each of the first to third emission areas EAa, EAb, and EAc.

According to embodiments, the second electrodes E2a, E2b, and E2c may be electrically connected to the first to third pixel driving circuits PCa, PCb, and PCc through the first to third connection electrodes CEa, CEb, and CEc and the first to third connection patterns CNPa, CNPb, and CNPc, respectively. Accordingly, a limitation of the design of each of the first to third pixel driving circuits PCa, PCb, and PCc due to the positions, shapes, and sizes of the first to third emission areas EAa, EAb, and EAc may be reduced. For example, even if at least some of the first to third circuit connection portions CPa, CPb, and CPc overlap the first to third emission areas EAa, EAb, and EAc, the second electrodes E2a, E2b, and E2c may be readily electrically connected to the first to third pixel driving circuits PCa, PCb, and PCc through the first to third connection electrodes CEa, CEb, and CEc and the first to third connection patterns CNPa, CNPb, and CNPc, respectively. Accordingly, shapes, arrangements, or the like, of the first to third pixel driving circuits PCa, PCb, and PCc may be designed independently of the positions, shapes, and sizes of the first to third emission areas EAa, EAb, and EAc. Accordingly, a degree of design freedom of each of the first to third pixel driving circuits PCa, PCb, and PCc may be improved.

As illustrated in FIG. 23, the shape or arrangement of each of the first to third connection electrodes CEa, CEb, and CEc and the arrangement relationship between the first to third connection electrodes CEa, CEb, and CEc may be the same for each first unit emission area UEA1. The shape or arrangement of each of the first to third connection electrodes CEa, CEb, and CEc and the arrangement relationship between the first to third connection electrodes CEa, CEb, and CEc may be the same for each second unit emission area UEA2.

The shape or arrangement of each of the first to third connection patterns CNPa, CNPb, and CNPc and the arrangement relationship between the first to third connection patterns CNPa, CNPb, and CNPc may be the same for each first unit emission area UEA1. The shape or arrangement of each of the first to third connection patterns CNPa, CNPb, and CNPc and the arrangement relationship between the first to third connection patterns CNPa, CNPb, and CNPc may be the same for each second unit emission area UEA2.

As described above, the display device DD3-2 may include the separator SPR. The separator SPR may be arranged on the pixel defining layer PDL and the first to third connection patterns CNPa, CNPb, and CNPc. The separator SPR may overlap the first to third connection patterns CNPa, CNPb, and CNPc in a plan view. For example, the separator SPR may cover a portion of each of the first to third connection patterns CNPa, CNPb, and CNPc. For example, at least a portion of the separator SPR may extend along an edge of each of the first to third connection patterns CNPa, CNPb, and CNPc. Accordingly, areas where the second electrodes E2a, E2b, and E2c and the first to third connection patterns CNPa, CNPb, and CNPc contact each other may be adjacent to or overlap the separator SPR in a plan view.

The separator SPR may define first to third open areas OA1, OA2, and OA3 respectively corresponding to the second electrodes E2a, E2b, and E2c. For example, the separator SPR may have a mesh structure surrounding the second electrodes E2a, E2b, and E2c in a plan view. In an embodiment, in a plan view, a shape of the first open area OA1 may be substantially the same as a shape of the second electrode E2a of the first light emitting element LDa, a shape of the second open area OA2 may be substantially the same as a shape of the second electrode E2b of the second light emitting element LDb, and a shape of the third open area OA3 may be substantially the same as a shape of the second electrode E2c of the third light emitting element LDc.

The first to third open areas OA1, OA2, and OA3 of the separator SPR may correspond to the first to third connection patterns CNPa, CNPb, and CNPc, respectively. For example, in a plan view, the first connection pattern CNPa may overlap the first open area OA1, the second connection pattern CNPb may overlap the second open area OA2, and the third connection pattern CNPc may overlap the third open area OA3.

Hereinafter, a cross-sectional structure of the display device DD3-2 will be described in more detail focusing on the first emission area EAa. The following description of the cross-sectional structure of the display device DD3-2 may be substantially equally applied to all emission areas.

As illustrated in FIG. 25, the display device DD3-2 may include a substrate SUB, a first bottom conductive layer BML1, a second bottom conductive layer BML2, the first transistor TR1, the second transistor TR2, the first capacitor CAP1, the second capacitor CAP2, the first connection electrode CEa, first to six insulating layers IL1, IL2, IL3, IL4, IL5, and IL6, the pixel defining layer PDL, the first light emitting element LDa, the organic film pattern OGP, the first connection pattern CNPa, the separator SPR, a first dummy layer DP1, a second dummy layer DP2, and an encapsulation layer ENC. The first light emitting element LDa may include the first electrode E1, the intermediate layer ML, and the second electrode E2a. Hereinafter, redundant descriptions of the display device DD3 described above with reference to FIG. 20 may be omitted or may be summarized.

The first transistor TR1 including a first active pattern AP1, a first gate electrode GE1, a first contact electrode SE1, and a second contact electrode DE1 may be formed on the substrate SUB. The first transistor TR1 may be a transistor that is connected to the light emitting element through the connection electrode and the connection pattern. For example, in case that the first pixel driving circuit PCa is the pixel driving circuit PC2 of FIG. 17A, the first transistor TR1 may be the first transistor T1 of FIG. 17A. In case that the first pixel driving circuit PCa is the pixel driving circuit PC2′ of FIG. 17B, the first transistor TR1 may be the fifth transistor T5 of FIG. 17B.

The first connection electrode CEa may be arranged on the fifth insulating layer IL5. The first connection electrode CEa may be connected to the first transistor TR1. For example, the first connection electrode CEa may contact the first transistor TR1 through a contact hole CNT that penetrates the fifth insulating layer IL5. Accordingly, the position of the first circuit connection portion CPa may correspond to a position of the contact hole CNT.

The first connection electrode CEa may include a conductive material such as a metal, an alloy, a conductive metal oxide, a conductive metal nitride, a transparent conductive oxide, or the like. In an embodiment, the first connection electrode CEa may have a single-layer structure or a multi-layer structure in which multiple conductive layers are stacked each other.

The sixth insulating layer IL6 may partially cover the first connection electrode CEa and may be arranged on the fifth insulating layer IL5. The sixth insulating layer IL6 may define a first sub-opening SO1 that exposes at least a portion of the first connection electrode CEa.

The pixel defining layer PDL may be arranged on the sixth insulating layer IL6 and the first electrode E1. The pixel defining layer PDL may define a pixel opening that exposes at least a portion of the first electrode E1. The first emission area EAa may be defined by the pixel opening.

The pixel defining layer PDL may further define a second sub-opening SO2 corresponding to the first sub-opening SO1 of the sixth insulating layer IL6. The second sub-opening SO2 may overlap the first sub-opening SO1 in a plan view, and the first sub-opening SO1 and the second sub-opening SO2 may be spatially connected to each other. For example, the first sub-opening SO1 and the second sub-opening SO2 may be connected to define a sub-opening OP, and the sub-opening OP may expose at least a portion of the first connection electrode CEa.

The organic film pattern OGP may be arranged on the pixel defining layer PDL in the display area DA. For example, the organic film pattern OGP may be arranged between the pixel defining layer PDL and the separator SPR in the display area DA. In an embodiment, an upper surface of the organic film pattern OGP may be a curved surface that is convex upward. The organic film pattern OGP may include an organic material. In an embodiment, the organic film pattern OGP and the pixel defining layer PDL may include different materials.

The first connection pattern CNPa may be arranged on the first connection electrode CEa, the sixth insulating layer IL6, and the pixel defining layer PDL. As described above, the first connection pattern CNPa may be connected to the first connection electrode CEa. For example, the first connection pattern CNPa may be connected to the first connection electrode CEa through the sub-opening OP that penetrates the sixth insulating layer IL6 and the pixel defining layer PDL. Accordingly, the position of the first light emitting connection portion CNa may correspond to a position of the sub-opening OP.

In an embodiment, the first connection pattern CNPa may include a transparent conductive oxide. However, the disclosure is not limited thereto, and in another embodiment, the first connection pattern CNPa may include a conductive material such as a metal, an alloy, a conductive metal nitride, or the like. In an embodiment, the first connection pattern CNPa may have a single-layer structure or a multi-layer structure in which multiple conductive layers are stacked each other.

In an embodiment, the first connection pattern CNPa may expose at least a portion of the organic film pattern OGP in the display area DA. For example, the first connection pattern CNPa may not cover at least a portion of the organic film pattern OGP in the display area DA. For example, as illustrated in FIG. 25, the first connection pattern CNPa may not be arranged on the upper surface of the organic film pattern OGP in the display area DA. However, the disclosure is not limited thereto.

The separator SPR may be arranged on the pixel defining layer PDL and the first connection pattern CNPa. The separator SPR may overlap the first connection pattern CNPa in a plan view. For example, the separator SPR may cover a portion of the first connection pattern CNPa.

A side surface of the separator SPR connecting an upper surface of the separator SPR and a lower surface of the separator SPR may have a reverse tapered slope. In other words, a cross-section of at least a portion of the separator SPR may be an inverted trapezoid.

In an embodiment, as illustrated in FIG. 25, the side surface of the separator SPR may have multiple reverse tapered slopes. For example, the separator SPR may have a double reverse tapered structure. Thus, the separation (or disconnection) of the electrode layer E2L by the separator SPR may be more readily implemented.

The separator SPR may include a first portion SPP1 and a second portion SPP2 spaced apart from the first portion SPP1. The first portion SPP1 of the separator SPR may overlap the organic film pattern OGP in a plan view, and the second portion SPP2 of the separator SPR may be spaced apart from the organic film pattern OGP in a plan view. In other words, the second portion SPP2 of the separator SPR may not overlap the organic film pattern OGP in a plan view. In an embodiment, the first portion SPP1 of the separator SPR may cover the organic film pattern OGP exposed by the first connection pattern CNPa, and a first side surface and a second side surface opposite to the first side surface of the first portion SPP1 of the separator SPR may contact the first connection pattern CNPa.

As the organic film pattern OGP is arranged between the pixel defining layer PDL and the first portion SPP1 of the separator SPR, an upper surface of the first portion SPP1 of the separator SPR may be a curved surface that is convex upward. In an embodiment, a level of the upper surface of the first portion SPP1 of the separator SPR may be higher than a level of an upper surface of the second portion SPP2 of the separator SPR. Accordingly, a mask used in the process of forming the intermediate layer ML may contact the first portion SPP1 of the separator SPR and may not contact the second portion SPP2 of the separator SPR. As a result, the phenomenon of being stamped by the mask, which may occur in case that an area of the separator SPR contacting the mask is large, may be suppressed.

The intermediate layer ML may be arranged on the first electrode E1, the pixel defining layer PDL, and the first connection pattern CNPa. A portion of the intermediate layer ML may be arranged in the pixel opening of the pixel defining layer PDL.

A shadow area where it is difficult to deposit the intermediate layer ML may exist around the separator SPR having the reverse tapered slope. Accordingly, in the shadow area and/or around the shadow area, the intermediate layer ML may be separated (or disconnected) by the separator SPR. As the intermediate layer ML is separated (or disconnected), the intermediate layer ML may expose a portion of the first connection pattern CNPa at a position adjacent to or overlapping the separator SPR. Accordingly, the second electrode E2a of the first light emitting element LDa may contact the first connection pattern CNPa.

The electrode layer E2L (i.e., the second electrodes E2a, E2b, and E2c) may be arranged on the intermediate layer ML. In an embodiment, the electrode layer E2L (i.e., the second electrodes E2a, E2b, and E2c) may have a single-layer structure. However, the disclosure is not limited thereto, and in another embodiment, the electrode layer E2L (i.e., the second electrodes E2a, E2b, and E2c) may have a multi-layer structure in which multiple conductive layers are stacked each other. For example, the electrode layer E2L (i.e., the second electrodes E2a, E2b, and E2c) may have a two-layer structure including a first sub-electrode layer including a metal and a second sub-electrode layer arranged on the first sub-electrode layer and including a transparent conductive oxide.

The shadow area where it is difficult to deposit the electrode layer E2L may exist around the separator SPR having the reverse tapered slope. In the shadow area and/or around the shadow area, the electrode layer E2L may be separated (or disconnected) by the separator SPR. For example, as illustrated in FIG. 24, the electrode layer E2L may be separated (or disconnected) into the second electrode E2a of the first light emitting element LDa arranged in the first open area OA1 of the separator SPR, the second electrode E2b of the second light emitting element LDb arranged in the second open area OA2 of the separator SPR, and the second electrode E2c of the third light emitting element LDc arranged in the third open area OA3 of the separator SPR. For example, the second electrodes E2a, E2b, and E2c may be electrically independent of each other.

As illustrated in FIG. 25, the electrode layer E2L (for example, the second electrode E2a) may contact the first connection pattern CNPa. For example, the electrode layer E2L (for example, the second electrode E2a) may contact the first connection pattern CNPa at a position adjacent to or overlapping the separator SPR. For example, in case that a deposition angle of a deposition process for forming the electrode layer E2L is greater than a deposition angle of a deposition process for forming the intermediate layer ML, the electrode layer E2L (for example, the second electrode E2a) may be formed to cover a side portion of the disconnected intermediate layer ML and to contact the first connection pattern CNPa. As a result, the second electrode E2a may be electrically connected to the first transistor TR1 through the first connection pattern CNPa and the first connection electrode CEa.

The encapsulation layer ENC may be arranged on the electrode layer E2L. The encapsulation layer ENC may entirely cover the electrode layer E2L, the connection patterns CNPa, CNPb, and CNPc, the separator SPR, the first dummy layer DP1, and the second dummy layer DP2.

According to embodiments, the display device DD3-2 may include the connection electrodes CEa, CEb, and CEc, the connection patterns CNPa, CNPb, and CNPc, and the separator SPR. Accordingly, the electrode layer E2L (e.g., the cathode) arranged on the first electrode E1 (e.g., the anode) may be readily electrically connected to the pixel driving circuits PCa, PCb, and PCc. For example, the electrode layer E2L arranged on the first electrode E1 may be electrically connected to a drain of the driving transistor (e.g., the first transistor T1 (or T1′) of FIGS. 17A and 17B) of each of the pixel driving circuits PCa, PCb, and PCc through the connection electrodes CEa, CEb, and CEc and the connection patterns CNPa, CNPb, and CNPc. Accordingly, even in case that the light emitting element deteriorates, the gate-source voltage (Vgs) of the driving transistor may not change. Accordingly, the range of change in the driving current due to the deterioration of the light emitting element may be reduced. Therefore, the after-image defect of the display device DD3-2 depending on an increase in the time of use may be reduced, and the lifespan of the display device DD3-2 may be improved.

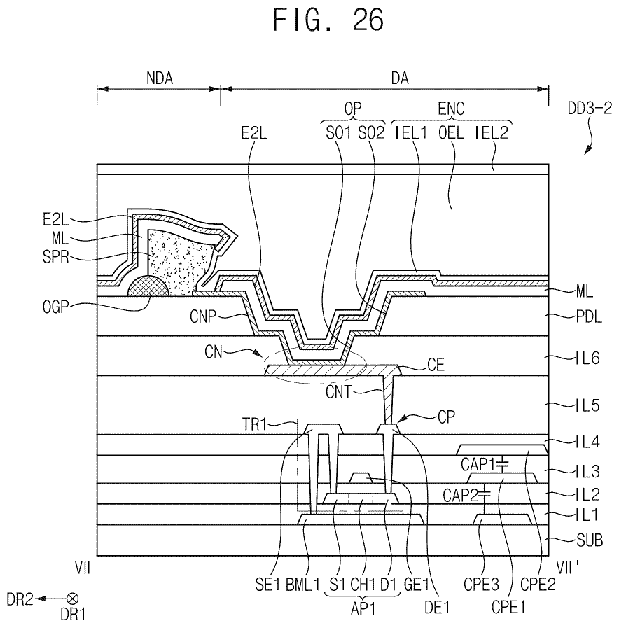

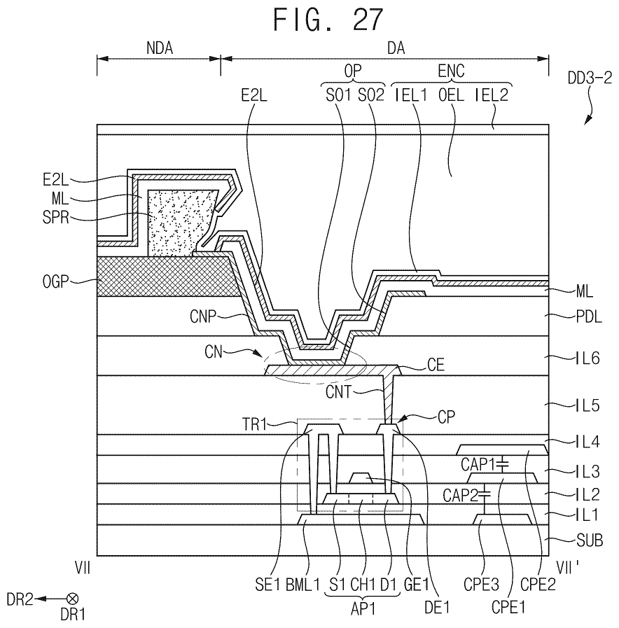

FIG. 26 is a schematic cross-sectional view taken along line VII-VII′ of FIG. 22 according to an embodiment. FIG. 27 is a schematic cross-sectional view taken along line VII-VII′ of FIG. 22 according to an embodiment.

Referring to FIGS. 26 and 27, the display device DD3-2 according to an embodiment of the disclosure may include the substrate SUB, the first bottom conductive layer BML1, the first transistor TR1, the first capacitor CAP1, the second capacitor CAP2, the connection electrode CE, the first to six insulating layers IL1, IL2, IL3, IL4, IL5, and IL6, the pixel defining layer PDL, the connection pattern CNP, the intermediate layer ML, the electrode layer E2L, the organic film pattern OGP, the separator SPR, and the encapsulation layer ENC. Hereinafter, redundant descriptions of the cross-sectional structure of the display device DD3-2 described above with reference to FIG. 25 may be omitted or may be summarized.

The organic film pattern OGP may be arranged on the pixel defining layer PDL in the peripheral area NDA. For example, the organic film pattern OGP may be arranged between the pixel defining layer PDL and the separator SPR in the peripheral area NDA. In an embodiment, as illustrated in FIG. 26, an upper surface of the organic film pattern OGP may be a curved surface that is convex upwardly. However, the disclosure is not limited thereto, and as illustrated in FIG. 27, the organic film pattern OGP may have a substantially flat upper surface. The organic film pattern OGP may include an organic material.

The connection pattern CNP may be arranged on the pixel defining layer PDL in the peripheral area NDA. In an embodiment, as illustrated in FIG. 26, the connection pattern CNP may be spaced apart from the organic film pattern OGP in the peripheral area NDA and may contact an upper surface of the pixel defining layer PDL. However, the disclosure is not limited thereto, and as illustrated in FIG. 27, the connection pattern CNP may be arranged on the organic film pattern OGP and may contact the upper surface of the organic film pattern OGP.

The separator SPR may be arranged on the pixel defining layer PDL. The separator SPR may contact the organic film pattern OGP and the connection pattern CNP in the peripheral area NDA. In an embodiment, as illustrated in FIG. 26, the organic film pattern OGP may overlap a portion of the separator SPR in a plan view in the peripheral area NDA. For example, the organic film pattern OGP may overlap a first side surface of the separator SPR in a plan view in the peripheral area NDA. In case that the upper surface of the organic film pattern OGP is a curved surface that is convex upwardly, an upper surface of the separator SPR may be a curved surface that is convex upwardly. However, the disclosure is not limited thereto. In an embodiment, as illustrated in FIG. 27, the organic film pattern OGP may overlap an entirety of the separator SPR in a plan view in the peripheral area NDA. In case that the organic film pattern OGP has a substantially flat upper surface, the separator SPR may have a substantially flat upper surface.

In an embodiment, as illustrated in FIGS. 26 and 27, the cross-sectional shape of a portion of the separator SPR may be asymmetrical in the peripheral area NDA. For example, a first side surface of the portion of the separator SPR may contact the organic film pattern OGP in the peripheral area NDA, and a second side surface opposite to the first side surface may contact the connection pattern CNP. Thus, in the process of forming the separator SPR, a difference in the degree of inclination of the first side surface and the second side surface may be caused due to a difference in the characteristics between the organic film pattern OGP and the connection pattern CNP.

The second side surface of the separator SPR may have a reverse tapered slope. For example, the second side surface of the separator SPR may have multiple reverse tapered slopes. As the second side surface of the separator SPR has the reverse tapered slopes, the intermediate layer ML and the electrode layer E2L may be separated (or disconnected) in the display area DA.

In contrast, the first side surface of the separator SPR may not have a reversed tapered slope.

As illustrated in FIG. 26, by forming the organic film pattern OGP that overlaps the first side surface of the separator SPR in a plan view in the peripheral area NDA, the first side surface of the separator SPR may not have a reverse tapered slope.

As illustrated in FIG. 27, in case that the first side surface of the separator SPR contacts the organic film pattern OGP having a substantially flat upper surface, the first side surface of the separator SPR may not have a reverse tapered slope. The organic film pattern OGP and the pixel defining layer PDL may include different materials. For example, the organic film pattern OGP may include a polystyrene-based resin and/or a polyimide-based resin. However, the disclosure is not limited thereto.

As the first side surface of the separator SPR does not have a reverse tapered slope, the intermediate layer ML and the electrode layer E2L may be formed to extend without being disconnected in the peripheral area NDA.

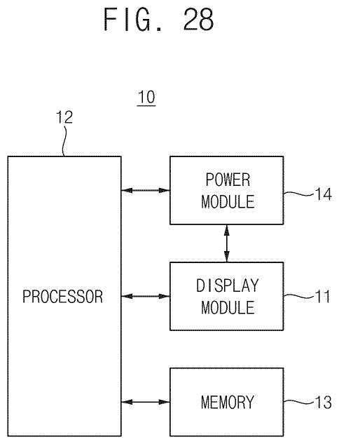

FIG. 28 is a schematic block diagram of an electronic device according to an embodiment of the disclosure.

Referring to FIG. 28, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. In case that the processor 12 executes an application stored in the memory 13, an image data signal and/or a input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. For example, the power module 14 may provide power to the display device according to the embodiments described above.

At least one of the components of the electronic device 10 described above may be included in the display device according to the embodiments described above. Some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

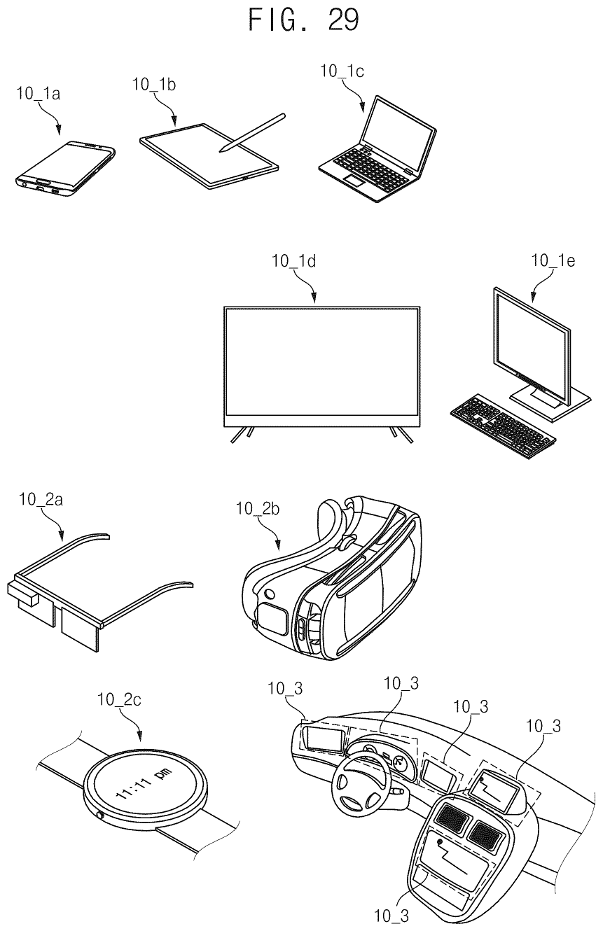

FIG. 29 is a schematic diagram of an electronic device according to various embodiments.

Referring to FIG. 29, various electronic devices to which a display device according to the embodiments is applied may include image display electronic devices such as a smartphones 10_1a, a tablet PC 10_1b, a laptop 10_1c, a television 10_1d, a desk monitor 10_1e, etc., wearable electronic devices including display modules such as a smart glasses 10_2a, a head-mounted display 10_2b, and a smart watch 10_2c, etc., and vehicle electronic devices (103) including display modules such as a center information display (CID) which may be disposed on a instrument panel, a center fascia, and a dashboard of an automobile and a room mirror display, etc.

The disclosure may be applied to various display devices. For example, the disclosure may be applicable to various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate comprising a display area and a peripheral area adjacent to the display area;
a first electrode arranged in the display area on the substrate;
an auxiliary electrode arranged in the display area on the substrate and spaced apart from the first electrode;
a pixel defining layer arranged on the substrate and defining an opening which exposes the first electrode;
an electrode layer arranged on the first electrode and electrically connected to the auxiliary electrode;
a separator arranged on the pixel defining layer and separating the electrode layer into a plurality of second electrodes spaced apart from each other in the display area; and
an organic film pattern arranged between the pixel defining layer and the separator in the display area and in the peripheral area and overlapping at least a portion of the separator in a plan view in the display area and in the peripheral area.

2. The display device of claim 1, wherein the separator comprises:
a first portion overlapping the organic film pattern in the plan view; and
a second portion which is spaced apart from the first portion and does not overlap the organic film pattern in the plan view.

3. The display device of claim 2, wherein a level of an upper surface of the first portion of the separator is higher than a level of an upper surface of the second portion of the separator.

4. The display device of claim 2, wherein
the first portion of the separator covers the organic film pattern in the display area, and
a first side surface and a second side surface opposite to the first side surface of the first portion of the separator contact the pixel defining layer in the display area.

5. The display device of claim 1, wherein
the separator comprises:
a first extension portion extending in a first direction;
a second extension portion extending in a second direction intersecting the first direction; and
an intersection portion where the first extension portion and the second extension portion meet, and
the organic film pattern overlaps the intersection portion of the separator in the plan view.

6. The display device of claim 1, wherein the organic film pattern and the pixel defining layer comprise different materials.

7. The display device of claim 1, wherein a cross-sectional shape of a portion of the separator is asymmetrical in the peripheral area.

8. The display device of claim 7, wherein the organic film pattern overlaps a first side surface of the portion of the separator in the plan view in the peripheral area,
the first side surface of the portion of the separator contacts the organic film pattern in the peripheral area, and
a second side surface opposite to the first side surface of the portion of the separator contacts the pixel defining layer in the peripheral area.

9. The display device of claim 1, further comprising:
a connection pattern arranged on the auxiliary electrode and the pixel defining layer and electrically connected to the auxiliary electrode,
wherein the separator overlaps the connection pattern in the plan view.

10. The display device of claim 9, wherein a portion of the connection pattern is arranged along profiles of the pixel defining layer and the organic film pattern in the display area.

11. The display device of claim 9, wherein
the connection pattern is arranged on the pixel defining layer in the peripheral area,
a cross-sectional shape of a portion of the separator is asymmetrical in the peripheral area,
a first side surface of the portion of the separator contacts the organic film pattern in the peripheral area, and
a second side surface opposite to the first side surface of the portion of the separator contacts the connection pattern in the peripheral area.

12. The display device of claim 11, wherein the organic film pattern overlaps an entire area of the separator in the plan view in the peripheral area.

13. A display device comprising:
a substrate comprising a display area and a peripheral area adjacent to the display area;
a first electrode arranged in the display area on the substrate;
an auxiliary electrode arranged in the peripheral area on the substrate;
a pixel defining layer arranged on the substrate and defining an opening which exposes the first electrode;
an electrode layer arranged on the first electrode and electrically connected to the auxiliary electrode;
a separator arranged on the pixel defining layer and separating the electrode layer into a second electrode arranged in the display area and a dummy electrode which is electrically connected to the auxiliary electrode and is arranged in the peripheral area;
a connection pattern arranged between the pixel defining layer and the separator and electrically connecting the second electrode and the dummy electrode; and
an organic film pattern arranged between the pixel defining layer and the connection pattern and overlapping at least a portion of the separator in a plan view.

14. The display device of claim 13, wherein the separator comprises:
a first portion overlapping the organic film pattern in the plan view; and
a second portion which is spaced apart from the first portion and does not overlap the organic film pattern in the plan view.

15. The display device of claim 14, wherein a level of an upper surface of the first portion of the separator is higher than a level of an upper surface of the second portion of the separator.

16. The display device of claim 13, wherein a first side surface and a second side surface opposite to the first side surface of the separator contact the connection pattern.

17. The display device of claim 13, wherein a portion of the connection pattern is arranged along profiles of the pixel defining layer and the organic film pattern.

18. The display device of claim 13, wherein each of the second electrode and the dummy electrode contacts the connection pattern in an area overlapping the separator in the plan view.

19. The display device of claim 13, further comprising:
an auxiliary connection electrode arranged in the peripheral area on the auxiliary electrode and electrically connected to the auxiliary electrode,
wherein the auxiliary connection electrode contacts the dummy electrode in the peripheral area.

20. An electronic device comprising:
a display device comprising a pixel; and
a processor which transmits an image data signal and an input control signal to the display device and is communicationally connected to the display device,
wherein the display device comprises:
a substrate comprising a display area and a peripheral area adjacent to the display area;
a first electrode arranged in the display area on the substrate;
an auxiliary electrode arranged in the display area on the substrate and spaced apart from the first electrode;
a pixel defining layer arranged on the substrate and defining an opening which exposes the first electrode;
an electrode layer arranged on the first electrode and electrically connected to the auxiliary electrode;
a separator arranged on the pixel defining layer and separating the electrode layer into a plurality of second electrodes spaced apart from each other in the display area; and
an organic film pattern arranged between the pixel defining layer and the separator in the display area and in the peripheral area and overlapping at least a portion of the separator in a plan view in the display area and in the peripheral area.
